(19) United States
(12) Patent Application Publication
(10) Pub. No.: US 2025/0044246 A1
(43) Pub. Date: Feb. 6, 2025

(54) NUCLEAR MAGNETIC RESONANCE METHODS OF DETERMINING HOMEOSTATIC PERTURBATIONS

(71) Applicant: The United States of America, as represented by the Secretary, Department of Health and Human, Bethesda, MD (US)

(72) Inventors: Rea Ravin, Rockville, MD (US); Nathan H. Williamson, Potomac, MD (US); Teddy X. Cai, Bethesda, MD (US); Peter J. Basser, Washington, DC (US)

(73) Assignee: The United States of America, as represented by the Secretary, Department of Health and Human, Bethesda, MD (US)

(21) Appl. No.: 18/697,168

(22) PCT Filed: Nov. 10, 2022
(86) PCT No.: PCT/US2022/049542

§ 371 Date: Mar. 29, 2024

Related U.S. Application Data
(60) Provisional application No. 63/277,881, filed on Nov. 10, 2021.

(51) Int. Cl. G01N 24/08; G01R 33/36; G01R 33/465; G01R 33/563

(52) U.S. Cl. CPC G01N 24/088; G01R 33/465; G01R 33/56341; G01R 33/3614

(57) ABSTRACT

Disclosed are methods to determine a homeostatic steady-state of a biological entity. Also disclosed are methods to quantify an exchange rate between at least two compartments in a biological system, to use Nuclear Magnetic Resonance (NMR) to characterize physiological water transport, and methods for non-invasively measuring transmembrane exchange rates of endogenous water in a biological system under steady-state or non-steady-state conditions in near-real time.

This patent application claims the benefit of co-pending U.S. Provisional Patent Application No. 63/277,881, filed Nov. 10, 2021, the disclosure of which is incorporated by reference in its entirety herein.

### STATEMENT REGARDING FEDERALLY SPONSORED RESEARCH OR DEVELOPMENT

This invention was made with Government support under project number 1ZIAHD008972 by the National Institutes of Health, Eunice Kennedy Shriver National Institute of Child Health & Human Development. The Government has certain rights in this invention.

### BACKGROUND

Biological homeostasis is a state of steady internal, physical, and chemical conditions maintained by a living organism that can be observed at the cellular level. Biological homeostasis can vary in order to alter the cellular physical and chemical conditions, thus acting as a mechanism to define the physiological state of cellular activity, for instance resting states or active states (e.g., intensive physical or mental activity or intensive physical or mental stimulation). Deviations or perturbations from biological homeostasis, even at the cellular level, can be caused by pathological conditions such as diseases within the organism. Such deviations result in physical and chemical conditions that can feedback to prolong pathological states as part of an injury or disease. In the extreme case, cell death can be characterized by a complete loss of homeostasis. In these ways, states of biological homeostasis are linked to physiological and pathological activities occurring at various levels of the organism (e.g., organelle, cell, tissue, organ). States of biological homeostasis can be difficult to detect using conventional analytical techniques.

In one particular example, diseases that affect the state of the Central Nervous System (CNS) are difficult to assess due to the difficulty in taking accurate measurements of the CNS. The CNS undergoes changes occurring in disease, development, aging, and trauma. Due to the difficulty in taking accurate measurements of the CNS, diagnosing and understanding these CNS changes presents a problem.

Diseases ranging from stroke, brain aneurysm, traumatic brain injury, and migraine aura often involve an abnormal CNS state such as Spreading Depolarization (SD) of the cells' transmembrane electrochemical potential. SD is a wave of electrophysiological hyperactivity followed by a wave of inhibition and is characterized by a rapid and near-complete loss of transmembrane potential (i.e., silencing of CNS activity). SD affects large populations of cells propagating like a wave, primarily through brain grey matter, and depressing neuronal activity. Due to the significance of damage to the CNS and the common diseases associated with SD, techniques to measure SD are needed.

One such avenue for measuring SD is with Magnetic Resonance (MR) techniques, such as diffusion Magnetic Resonance Imaging (dMRI). Diffusion MRI uses diffusion of water molecules in the CNS to generate contrast in MR images. However, diffusion MRI is not ideal in that it reports an aggregate water diffusion measurement obtained from many different water pools within the tissue, without indicating a specific biophysical mechanism underlying the signal changes. Moreover, when used as a functional MRI method, it is used only to measure relative signal changes as they are occurring and, as such, can only measure SD while it is progressing from a normal state to a depressed state. Once the CNS is in a steady state of SD, diffusion MRI cannot detect the pathology. Another such MRI technique is to use contrast agents to aide in measuring water exchange. However, contrast agents are difficult to use in CNS measurements as they often do not pass through the blood brain barrier. Further, certain contrast agents may also be toxic to a patient and may cause environmental harm.

Other more invasive techniques for measuring SD exists. For instance, electrocorticography (ECoG) is a type of electrophysiological monitoring that uses electrodes placed directly on an exposed surface of the brain to record electrical activity. While accurate, this technique is extremely invasive and requires a patient to undergo major surgery to implement.

Another technique to measure SD, similar to ECoG, is electroencephalography (EEG). EEG is an electrophysiological monitoring method use to record electrical activity on the scalp that has been shown to represent the macroscopic activity of the surface layer of the brain underneath. It is non-invasive in that the electrodes are placed along the scalp rather than directly on the surface of the brain. Unfortunately, this measurement technique is not very accurate in fully diagnosing SD in that it generally only detects electrical activity at the surface of the brain.

In view of the above described drawbacks of SD measurement techniques, new measurement techniques for SD are needed. The discussion above regarding the CNS and specifically SD are provided to illustrate a common problem in diagnosing and understanding disease in biological systems. Accordingly, while the drawbacks of SD measurement techniques were discussed above, it should be noted that deviations in cellular homeostasis of a living organism can be the origin of many similar diseases beyond those related to SD, even those outside of the CNS. Accordingly, new analytical techniques to measure and determine deviations from normal cellular homeostasis are needed. Further, to be effective and useful, these measurement techniques need to be fast, accurate, quantitative, and non-invasive.

### BRIEF SUMMARY OF THE INVENTION

An aspect of the invention provides methods to determine a homeostatic steady-state of a biological entity.

A further aspect of the invention provides methods to determine a homeostatic steady-state of a biological entity, the method comprising a magnetic resonance (MR) system, the MR system comprising: a. a means to create a static or pulsed magnetic field gradient; b. a means to create a constant magnetic field; c. a means to hold a biological entity within the constant magnetic field and the static or pulsed magnetic field gradient; d. a radiofrequency transmitter; e. a radiofrequency receiver that measures radiofrequency electromagnetic fields; f. a radiofrequency transmit amplifier; g. a MR radiofrequency pulse sequence generator that sends signals to the radiofrequency transmit amplifier to acquire Diffusion Exchange Spectroscopy (DEXSY) data; h. a recording device to sample and store a MR magnetization signal detected by the radiofrequency receiver; and i. a mathematical modeling framework to transform the recorded magnetization signal DEXSY data, wherein interpretation of the DEXSY data provides a homeostatic steady-state of a biological entity.

Another aspect of the invention provides methods to quantify an exchange rate between at least two compartments in a biological system.

A further aspect of the invention provides Nuclear Magnetic Resonance (NMR) method to characterize physiological water transport.

An aspect of the invention provides methods for non-invasively measuring transmembrane exchange rates of endogenous water in a biological system under steady-state or non-steady-state conditions in near-real time.

### BRIEF DESCRIPTION OF THE SEVERAL VIEWS OF THE DRAWING(S)

FIG. 1A depicts a box and violin plot showing that temperature dependence reveals active, steady-state water exchange. Exchange rates, k, for fixed spinal cords were measured at different temperatures. Box and violin plots include all k measurements (three measurements per sample) and are discussed in Example 1. Connected dots show the mean k at each temperature and are shaded differently for each sample.

FIG. 1B depicts a box and violin plot showing that temperature dependence reveals active, steady-state water exchange. Exchange rates, k, for live spinal cords were measured at different temperatures. Box and violin plots include all k measurements (three measurements per sample) and are discussed in Example 1. Connected dots show the mean k at each temperature and are shaded differently for each sample.

FIG. 1C depicts an Arrhenius plot of the dependence of k on T⁻¹ (the inverse of the absolute temperature) for fixed (bottom line) and live (top line) spinal cords. Mean values (symbols) and standard deviations (whiskers) for all fixed and live samples at each temperature condition are presented. Data points for the 1^{st}, 2^{nd}, and 3^{rd} 25° C. conditions are shown separately. Lines show the mean of Arrhenius model fits. Slopes of the lines are proportional to Ea.

FIG. 1D depicts boxplots comparing activation energies (Fa) between fixed and live spinal cords. Dots show the values of Ea for each sample. Ea=21±8 KJ mol (mean±SD) for fixed samples, similar to Ea=18 found for water self-diffusion in artificial cerebrospinal fluid (aCSF, solid line, see also FIG. 2). Ea=36±7 KJ mol for live spinal cords and is significantly greater than Fa for fixed spinal cords (p=0.005). Therefore, active exchange exists.

FIG. 2A depicts a box and violin plot showing apparent diffusion coefficients of fixed spinal cords at the different temperatures.

FIG. 2B depicts a box and violin plot showing apparent diffusion coefficients of live spinal cords at the different temperatures. FIGS. 2A and 2B illustrate the temperature dependence of ADC.

FIG. 2C depicts an Arrhenius plot of ADCy at each temperature condition for fixed (middle line) and live (top line) spinal cords, as well as free diffusion coefficients of pure aCSF (top line).

FIG. 2D depicts boxplots showing activation energies (Ea) of water diffusion for fixed and live spinal cords (boxplots) and aCSF (solid line). Dots show Ea values for each sample. For aCSF, Ea=18 KJ mol, similar to values reported for pure water over the same temperature range Ea=18-20 KJ mol (Mills, Journal of Physical Chemistry, 77 (5): 685-688 (1973)). Ea of ADCy is not significantly different between live (Ea=8.3:1.5 kJ mol), and fixed spinal cords (Ea=7.0:2.1 kJ mol), (p=0.21).

FIG. 3A depicts a graph showing real-time exchange rate in apparent diffusion on live spinal cords under normal condition (left) and after (right) addition of 100 μM ouabain at 25° C. Mean values (circles) and standard deviations (whiskers) from n=3 samples are presented. The top line shows the average exchange rate value from all normal conditions (k=140 s-1). The bottom line shows the mean value after ouabain addition (k=36 s⁻¹). (See FIG. 10 for associated f and R_{1 DW} data.)

FIG. 3B depicts a graph showing real-time percentage change in apparent diffusion coefficient (ADC) from baseline measurements on live spinal cords under normal condition (left) and after (right) addition of 100 μM ouabain at 25° C. Mean values (circles) and standard deviations (whiskers) from n=3 samples are presented. FIGS. 3A and 3B show that exchange rates drop by 71% after inhibiting the sodium-potassium pump with ouabain.

FIG. 4A depicts a plot showing time series averages showing means (symbols) and standard deviations (whiskers) of n=8 samples for 40 minute OGD and of n=9 for 70 minute OGD. Recordings of R₁, ADCy, and k while switching from normal media bubbled with 95% pO₂ to glucose-free media bubbled with 1% pO₂ and washing back to normal after 40 minutes (left column) or 70 minutes (right column), at 25° C.

FIG. 4B depicts another plot showing time series averages showing means (symbols) and standard deviations (whiskers) of n=8 samples for n=9 for 70 minute OGD.

FIG. 4C depicts another plot showing time series averages showing means (symbols) and standard deviations (whiskers) of n=8 samples for 40 minute OGD.

FIG. 4D depicts another plot showing time series averages showing means (symbols) and standard deviations (whiskers) of n=8 samples for n=9 for 70 minute OGD.

FIG. 4E depicts another plot showing time series averages showing means (symbols) and standard deviations (whiskers) of n=8 samples for 40 minute OGD.

FIG. 4F depicts another plot showing time series averages showing means (symbols) and standard deviations (whiskers) of n=8 samples for n=9 for 70 minute OGD.

FIG. 4G depicts a plot showing time series for representative samples, with R₁ (squares) and ADCy (triangles) values associated with the right-hand y-axis and exchange rate (circles) values associated with the left-hand y-axis.

FIG. 4H depicts another plot that depicts time series for representative samples, with R₁ (squares) and ADCy (triangles) values associated with the right-hand y-axis and exchange rate (circles) values associated with the left-hand y-axis.

FIG. 4I depicts a histogram of how long the exchange rate response lags behind ADCy, calculated from cross-correlation analysis on the ten samples for which ADCy and exchange rate are significantly correlated.

FIG. 4J depicts a box and violin plot comparing the exchange rate values during recovery from 40 min OGD and 70 min OGD (averaged over the period 40-70 min after switching back to normal aCSF). Time series and Pearson correlations for all samples are shown in FIG. 14. FIGS. 4A-4J show that exchange rates are highly regulated until viability is compromised during oxygen and glucose deprivation.

FIG. 5 depicts a bar graph depicting the mean across all measurements (bar height), 95% CI of the mean (whiskers), and mean values from each sample (open circles). Exchange rates were compiled from the 1^{st} 25° C. condition in FIG. 1, and from FIGS. 3 and 4. The exchange rate of live spinal cords (mean±SD k=140±16 s⁻¹, n=27) is significantly greater than fixed (k=87±10 s⁻¹, n=6), ouabain-treated (k=36±11 s⁻¹, n=3), and spinal cords after 70 minutes of OGD (45±7 s⁻¹, n=9) (p<0.001). Further, the exchange rate of ouabain-treated spinal cords is significantly less than fixed spinal cords (p<0.001). However, exchange rates are not significantly different between ouabain-treated spinal cords and spinal cords after 70 min OGD (p=0.056). Associated data and fits are compared in FIG. 16. FIG. 5 shows comparisons between fixed, live (untreated), ouabain-treated, and post-70 min OGD which reveal how treatments affect passive and active exchange.

FIG. 6 depicts a 3D technical drawing (top) of the test chamber in accordance with an aspect of the invention. aCSF inlet/outlets and temperature probes were omitted for simplicity. FIG. 6 also depicts an image of the solenoid RF coil containing a mouse spinal cord (top right). The bottom of FIG. 6 depicts another technical drawing of the experimental setup in accordance with an aspect of the invention. Vectors B₁, g and B₀ point in the x, y, and z directions, respectively.

FIG. 7 depicts a representative log of sample temperature during an aspect of the invention. Specifically, this log shows an experimental protocol with temperatures from 25-7-25-35-25°. Temperature was recorded in the chamber using a fiber optic sensor (see Example 1).

FIG. 8A depicts a series of graphs depicting diffusion signal intensity from measurements on n=6 fixed (circles) and n=7 live (squares) spinal cords, and aCSF (circles) performed at 25° C. In FIGS. 8A-8E, means (symbols) and standard deviations (shaded bands) are presented. The three columns (left, middle, right) show the same data plotted differently. Graphs in column 1 (left) are plotted as a function of b×D₀. On this scale, freely diffusing water decays exponentially. Column 2 (middle) graphs zoom in on the initial signal attenuation, corresponding to a region shaded in the column 1 figures. The straight dotted, solid, and dashed lines are best fits of the initial decay, where the slopes correspond to ADCy. Graphs in column 3 (right) are plotted as a function of (b×D₀)^{1/3}. On this scale, restricted water decays roughly exponentially. The straight dotted and solid lines are fits of the final decay at long τ (large b^{1/3}) (points 12-22). Lines extrapolate back to b^{1/3}=0, corresponding to the restricted volume fraction f. In FIGS. 8A-8E, the mean (dotted line) and ±standard deviation (dashed lines) of the fixed samples from the first 25° C. experiments are re-plotted to show how the signals collapse with the non-dimensionalization and to show how well the signals recover when returning back to 25°. The variable b is non-dimensionalized by the measured diffusion coefficients of aCSF at 7° 25°, and 35° C., D₀=1.35, 2.16 and 2.74 ms/μm².

FIG. 8B depicts a series of graphs depicting Diffusion signal intensity from measurements on n=6 fixed (circles) and n=7 live (squares) spinal cords, and aCSF (circles) performed at 7° C.

FIG. 8C depicts a series of graphs depicting Diffusion signal intensity from measurements on n=6 fixed (circles) and n=7 live (squares) spinal cords, and aCSF (circles) performed at 25° C.

FIG. 8D depicts a series of graphs depicting Diffusion signal intensity from measurements on n=6 fixed (circles) and n=7 live (squares) spinal cords, and aCSF (circles) performed at 35° C.

FIG. 8E depicts a series of graphs depicting Diffusion signal intensity from measurements on n=6 fixed (circles) and n=7 live (squares) spinal cords, and aCSF (circles) performed at 25° C.

FIG. 9A depicts a box and violin plot showing diffusion-weighted spin lattice relaxation rate R₁ of fixed spinal cords at each temperature condition.

FIG. 9B depicts a box and violin plot showing diffusion-weighted spin lattice relaxation rate R₁ of live spinal cords at each temperature condition.

FIG. 9C depicts an Arrhenius plot of R₁⁻¹ (≈T₁) for fixed and live spinal cords.

FIG. 9D depicts a box and violin plot comparing activation energies between fixed and live samples. 95% CI of median values indicate that the activation energy of R₁⁻¹ is similar between live and fixed spinal cord. t tests indicate activation energy of R₁⁻¹ is significantly greater for live spinal cords (M=7.5 kJ mol, SD=1.2 kJ mol) compared to fixed spinal cords (M=6.0 kJ mol, SD=0.86 kJ mol), t=2.7, p=0.02. Activation energy values for R₁-1 and ADCy (FIG. 2D) are similar. This indicated that R₁ and ADCy are similarly affected by tissue microstructure.

FIG. 10A is a graph that depicts real-time exchange rate on live spinal cords under normal condition (left of center line) and after (right of center line) addition of 100 μM ouabain. Mean values (circles) and standard deviations (whiskers) from n=3 samples are presented. R_{1 DW} decreased by 8±3%. f increased by 22±6%.

FIG. 10B is a graph that depicts diffusion weighted spin-lattice relaxation rate on live spinal cords under normal condition (left of center line) and after (right of center line) addition of 100 μM ouabain. Mean values (circles) and standard deviations (whiskers) from n=3 samples are presented. R_{1 DW} decreased by 8±3%. f increased by 22±6%.

FIG. 10C is a graph that depicts apparent diffusion coefficient on live spinal cords under normal condition (left of center line) and after (right of center line) addition of 100 μM ouabain. Mean values (circles) and standard deviations (whiskers) from n=3 samples are presented. R_{1 DW} decreased by 8±3%. f increased by 22±6%.

FIG. 10D depicts is a graph that depicts restricted volume fraction measurements on live spinal cords under normal condition (left of center line) and after (right of center line) addition of 100 μM ouabain. Mean values (circles) and standard deviations (whiskers) from n=3 samples are presented. R_{1 DW} decreased by 8±3%. f increased by 22±6%. FIGS. 10A-10D together show the effect of 100 μM ouabain on NMR properties.

FIG. 11A depicts a box and violin plot showing diffusion weighted R₁ for n=2 fixed samples during osmolarity perturbation with sucrose.

FIG. 11B depicts a box and violin plot showing diffusion weighted R₁ for n=3 live samples during osmolarity perturbation with sucrose.

FIG. 11C depicts a graph showing plots of R₁ as a function of osmolarity.

FIG. 11D depicts a graph showing the slopes from FIG. 11C for each sample. Slopes are positive and similar for live and fixed, indicating that sucrose penetrates into the tissue similarly for live and fixed samples.

FIG. 12A depicts a box and violin plot showing measurements of restricted fraction (f) during osmotic perturbations from normal aCSF to aCSF+300 mM sucrose and back on n=3 live spinal cords.

FIG. 12B depicts a box and violin plot showing measurements of exchange rate (k) during osmotic perturbations from normal aCSF to aCSF+300 mM sucrose and back on n=3 live spinal cords.

FIG. 12C depicts a graph showing values of f⁻¹ and k acquired from the same set are plotted for each sample and show positive correlations (p=0.019, 0.0001, and 0.039 with correlation coefficients 0.66, 0.83, and 0.63). A correlation is expected through the linear dependence of k on the membrane surface-to-volume (SV) ratio. This result is consistent with DEXSY measuring water exchange between the intra- and extracellular space. FIGS. 12A-12C together show the correction between f⁻¹ and k.

FIG. 13A depicts a box and violin plot showing percent change in ADCy for fixed samples during osmolarity perturbation with sucrose.

FIG. 13B depicts a box and violin plot showing percent change in ADCy for live samples during osmolarity perturbation with sucrose.

FIG. 13C depicts a graph showing plots of ADCy as a function of osmolarity.

FIG. 13D depicts a graph showing the slopes from FIG. 13C for each sample. FIGS. 13A-13D together show the osmolarity dependence of ADCy. FIGS. 13A-13D show that +300 mM sucrose increases ADCy significantly in live samples, consistent with water re-partitioning from the intracellular space to the extracellular space, increasing the fraction of more mobile extracellular water, decreasing the fraction of less mobile intracellular water ADCy increases negligibly in fixed samples, consistent with sucrose penetrating through pores in cell membranes opened during fixation and hence having no osmotic effect. In live samples, ADCy decreases below baseline when washing back to normal media with +0 mM sucrose, perhaps due to cellular swelling.

FIG. 14A depicts a box and violin plot showing the restricted fraction from n=2 fixed samples undergoing perturbations from normal aCSF to aCSF with 300 mM sucrose back to normal.

FIG. 14B depicts a box and violin plot showing depicts a box and violin plot showing the exchange rate from n=2 fixed samples undergoing perturbations from normal aCSF to aCSF with 300 mM sucrose back to normal. Unlike for live samples, the change in restricted fraction is insignificant between normal and +300 mM sucrose, indicating that sucrose does not act as an osmolyte on fixed samples; membranes become permeable to sucrose during fixation. There is no change in k between normal and +300 mM sucrose because the volume and permeability are unaffected in this perturbation on fixed samples. FIGS. 14A and 14B together show the osmolarity dependence off and k in fixed spinal cords.

FIG. 15A depicts a series of graphs showing the timecourse of exchange rate, apparent diffusion coefficient, and spin lattice relaxation rate for all samples undergoing 40 min (n=9) of oxygen glucose deprivation (OGD, 1% pO₂, 0 mM glucose). Exchange rate (solid circles) values can be read from the left-hand y-axis. Diffusion coefficients (open triangles) and spin-lattice relaxation rates R₁ from saturation recovery measurements (open squares) are presented as percent change from the initial baseline and values can be read from the right-hand y-axes. Postnatal day of spinal cord dissection (P1, p2, p3 or p4) is shown in the bottom left-hand corner of each plot. Pearson correlation coefficients (cc) and associated p values for the comparison between exchange rate and diffusion timeseries were calculated. Of all 18 samples, 8 samples did not show a significant correlation between diffusion and exchange (p>0.05 and cc<0.2). The backgrounds for the plots of these samples are shaded lighter. The backgrounds are shaded darker and cc values are presented in the upper left corner for each plot of the 10 samples which did have a significant correlation (p<0.05). These samples had a (mean±SD) cc=0.58±0.12.

FIG. 15B depicts a series of graphs showing the timecourse of exchange rate, apparent diffusion coefficient, and spin lattice relaxation rate for all samples undergoing 70 min (n=9) of oxygen glucose deprivation (OGD, 1% pO₂, 0 mM glucose). Exchange rate (solid circles) values can be read from the left-hand y-axis. Diffusion coefficients (open triangles) and spin-lattice relaxation rates R₁ from saturation recovery measurements (open squares) are presented as percent change from the initial baseline and values can be read from the right-hand y-axes. Postnatal day of spinal cord dissection (p1, p2, p3 or p4) is shown in the bottom left-hand corner of each plot. Pearson correlation coefficients (cc) and associated p values for the comparison between exchange rate and diffusion timeseries were calculated. Of all 18 samples, 8 samples did not show a significant correlation between diffusion and exchange (p>0.05 and cc<0.2). The backgrounds for the plots of these samples are shaded lighter. The backgrounds are shaded darker and cc values are presented in the upper left corner for each plot of the 10 samples which did have a significant correlation (p<0.05). These samples had a (mean±SD) cc=0.58±0.12.

FIG. 16A depicts a graph showing mean (symbols) and standard deviations (shaded bands) of exchange signals, and mean (dotted lines) and standard deviations (dashed lines) of exchange rate model fits (fixed). Data was compiled from the 1^{st} 25° C. condition in FIG. 1 and from FIGS. 3 and 4. Exchange rates are compared in FIG. 5.

FIG. 16B depicts a graph showing mean (symbols) and standard deviations (shaded bands) of exchange signals, and mean (dotted lines) and standard deviations (dashed lines) of exchange rate model fits (live, normal). Data was compiled from the 1^{st} 25° C. condition in FIG. 1 and from FIGS. 3 and 4. Exchange rates are compared in FIG. 5.

FIG. 16C depicts a graph showing mean (symbols) and standard deviations (shaded bands) of exchange signals, and mean (dotted lines) and standard deviations (dashed lines) of exchange rate model fits (ouabain-treated). Data was compiled from the 1^{st} 25° C. condition in FIG. 1 and from FIGS. 3 and 4. Exchange rates are compared in FIG. 5.

FIG. 16D depicts a graph showing mean (symbols) and standard deviations (shaded bands) of exchange signals, and mean (dotted lines) and standard deviations (dashed lines) of exchange rate model fits (post-70 min OGD). Data was compiled from the 1^{st} 25° C. condition in FIG. 1 and from FIGS. 3 and 4. Exchange rates are compared in FIG. 5.

FIG. 16E depicts a graph showing mean of data (symbols) and fits (lines) compared between treatment groups.

FIG. 16F depicts a graph showing a comparison of the initial (tm=0-40 ms) decay on a log-y axis. Data shows multi exponential behavior, with a faster initial decay and a slower final decay relative to the single exponential fits.

FIG. 17 depicts a series of graphs showing exchange rates (solid circles, left axis) and normalized ADCy changes (open triangles, right axis) measured under normal conditions for extended periods for n=4 samples. For three of the samples, exchange rates remained stable for over six hours with values near the average from all samples under live conditions (k=140 s⁻¹). The backgrounds for the plots of these samples are shaded lighter. On sample 1, an OGD perturbation was performed at 22.3 hours. The exchange rate and ADCy were stable over the entire period prior to OGD with mean±SD 153±17 s⁻¹ and 1.017±0.013 μm²/ms respectively. After switching to OGD, the exchange rate decreased continuously for 40 minutes and then plateaued at 45±5 s⁻¹, only slightly greater than the mean exchange rate of ouabain-treated samples (k=36 s⁻¹, red line). Exchange rates for the other two samples eventually ran down, after roughly 12 hours for sample 2 and 8 hours for sample 4, signifying an inevitable loss of viability. One sample (sample 3) started with four exchange rate values having a mean<130 s⁻¹. The background for the plot of this sample is shaded darker. If this sample was intended for an experiment, it would have been deemed unviable and discarded. Indeed, exchange rates for this sample continued to run down over the next 20 hours. Exchange rates during the last two hours of recording were 52±6 s⁻¹. Diffusion was measured for samples 1-3. For sample 1, ADCy values are stable until switching to OGD, at which point they decrease by 24%. For samples 2 and 3, ADCy values increase prior to exchange rate rundown, and eventually decrease during exchange rate rundown. This non-monotonic behavior provides additional evidence that the ADC is not a direct measure of viability.

FIG. 18 depicts a bar graph showing apparent diffusion coefficients compared between fixed, live (untreated), ouabain-treated, and post-70 min OGD. Bar graphs present mean (bar height) 95% CI of the mean (whiskers), and average values from each sample (circles). ADCy were compiled from the 1^{st} 25° C. condition in FIG. 2, and from FIGS. 3 and 4. The average values from each sample (open circles) are also shown. ADCy of live spinal cords (mean±SD 0.964±0.097 μm²/ms, n=27) is significantly greater than fixed spinal cords (0.703±0.031 μm²/ms, n=6) and spinal cords after 70 minutes of OGD (0.845±0.085 μm²/ms, n=9), (p<0.001), but not significantly different from ouabain-treated spinal cords (0.954±0.045 μm²/ms, n=3), (p=0.75). Further, the ADCy of ouabain-treated spinal cords is significantly greater than fixed spinal cords (p<0.001).

FIG. 19A depicts a graph showing individual rapid exchange experiments acquired on a live (squares) and a fixed (circles) sample. DEXSY signals were acquired as a function of mixing time with (τ₁, τ₂) combinations which make the signal (a and b) diffusion, τ₁, and exchange weighted. FIG. 19A shows a representative single exponential fits used to estimate diffusion weighted R₁ and biexponential fits used to remove spin lattice relaxation and isolate the “exchange signal.”

FIG. 19B depicts a graph showing individual rapid exchange experiments acquired on a live (squares) and a live sample after ouabain treatment (triangles). DEXSY signals were acquired as a function of mixing time with (τ₁, τ₂) combinations which make the signal diffusion and τ₁ weighted but minimally exchange weighted, and exchange weighted. FIG. 19B shows representative single exponential fits used to estimate diffusion weighted R₁ and biexponential fits used to remove spin lattice relaxation and isolate the “exchange signal”.

FIG. 19C depicts a graph showing individual rapid exchange experiments acquired on a live (squares) and a fixed (circles) sample. DEXSY signals were acquired as a function of mixing time with (τ₁, τ₂) combinations which make the signal diffusion, τ₁, and exchange weighted.

FIG. 19D depicts a graph showing individual rapid exchange experiments acquired on a live (squares) and a live sample after (triangles) ouabain treatment. DEXSY signals were acquired as a function of mixing time with (τ₁, τ₂) combinations which make the signal diffusion, T₁, and exchange weighted.

FIG. 19E depicts a graph showing exchange signals, isolated by subtracting the biexponential fits shown in FIGS. 19A and 19B from the signals in FIGS. 19C and 19D. The signal at the final mixing time was subtracted from all signals so that the signals roughly decay to 0. Exchange rates were estimated by fitting a single exponential model with a baseline term to exchange signals.

FIG. 19F depicts another graph showing exchange signals, isolated by subtracting the biexponential fits shown in FIGS. 19A and 19B from the signals in FIGS. 19C and 19D. The signal at the final mixing time was subtracted from all signals so that the signals roughly decay to 0. Exchange rates were estimated by fitting a single exponential model with a baseline term to exchange signals.

FIG. 20A depicts a series of graphs showing that the addition of 100 μM ouabain causes a 67% decrease in water exchange rate accompanied by a 27% increase in relative cell volume. The sample did not recover when washed back to normal media. Bar graphs present 95% CIs (whiskers) and mean values of measurements for the normal condition and after ouabain takes effect on each sample (circles) (n=3).

FIG. 20B depicts a series of graphs showing that low (1-10 μM) doses of ouabain reduce water exchange rate in an all-or-none fashion; either they have no effect, or they reduce exchange rate to the same level as 100 μM. The effect occurs after a delayed period. Real-time measurements show that the effect of a 1 μM dose of ouabain is delayed. Bar graphs show mean values and 95% CI from n=5 samples. Arrows (→) show where the exchange rate decreased after addition of ouabain. FIGS. 20A and 20B together show that the exchange rate is an all-or-none, dose-independent decrease when blocking the Na⁺/K⁺ pump.

FIG. 21 depicts a set of graphs showing that osmolytes recover exchange after blocking the Na⁺/K⁺ pump. Real-time measurements with perturbations normal→100 mM sucrose→normal→5 μM ouabain→5 μM ouabain+100 mM sucrose→5 μM ouabain show that sucrose affects the exchange rate more drastically after ouabain treatment. Arrows show where the exchange rate decreased after addition of ouabain (note the delay) and recovered after addition of sucrose respectively.

FIG. 22A depicts figures that show a contour plot of signals simulated from a two-component exchange model and describes the mechanisms of attenuation-diffusion, T₁ relaxation, and exchange—for four exemplar signal points with defined b₁ and b₂.

FIG. 22A depicts a diagram that shows the evolution of the signal contours and in particular the curvature which is indicative of exchange with increasing tₘ. Only point number three is sensitive to the attenuation caused by exchange. These characteristics of the signals are utilized to isolate exchange which is necessary for measuring exchange rates. FIGS. 22A and 22B together show that signals acquired with the DEXSY pulse sequence involving two gradient echoes with variable diffusion weightings defined by b₁ and b₂ separated by a variable mixing time tₘ.

FIG. 23 depicts a flow chart for acquiring and processing the DEXSY signals to estimate exchange rates. First, DEXSY signals are acquired with combinations of diffusion (b₁ and b₂) weighting and variable mixing times tₘ. This can involve using a SG-DEXSY sequence and associated hardware or a PG-DEXSY sequence and associated hardware. See FIG. 19 for examples of DEXSY signals. Second, signals are processed to isolate the exchange weighted signals. Third, the exchange rate is estimated from the exchange weighted signals. This can involve a fitting algorithm or it can involve a numerical interpolation.

FIG. 24 depicts a diagram showing the minimal equipment needed for performing the MR measurement of an exchange rate on an organism. Aspects utilizing the Static Gradient Diffusion Exchange Spectroscopy (SG-DEXSY) method involve a magnet producing a static gradient in the magnetic field and are darkly shaded. Aspects utilizing the Pulsed Gradient Diffusion Exchange Spectroscopy (PG-DEXSY) methods additionally involve a gradient amplifier and gradient coil and are lightly shaded. SG-DEXSY experiments can also be performed by using pulsed gradients to mimic a static gradient. The measurement can be of signals averaged over regions of the sample, or spatially localized as part of an MRI. The biological entity (e.g., sample, animal, or patient) is placed within the magnetic field, gradient field, and radiofrequency field. During the measurement, the computer sends commands to the spectrometer which are then sent to the radiofrequency probe and pulsed field gradient. The spectrometer acquires signals and sends them to the computer. The signals are then processed to estimate an exchange rate.

FIG. 25 depicts a Static Gradient Diffusion Exchange Spectroscopy (SG-DEXSY) pulse sequence and phase cycles in accordance with an aspect of the invention.

FIG. 26 depicts a Pulsed Gradient Diffusion Exchange Spectroscopy (PG-DEXSY) pulse sequence in accordance with an aspect of the invention. The phase of the 90° storage RF pulses are cycled together between + and − x.

FIG. 27A depicts a graph showing entire signal decay from diffusion measurements performed on isolated mitochondria (28 μg/μl measured by BCA) in isolation buffer (light grey) and on only isolation buffer (dark gray). Decay was plotted as a function of b×D (non-dimensionalized by D₀=2.15 μm²/ms measured from aCSF), showing signal from isolated mitochondria persists well beyond b-values which attenuate free water.

FIG. 27B depicts a graph showing initial signal decay from diffusion measurements performed on isolated mitochondria (28 μg/μl measured by BCA) in isolation buffer (light grey) and on only isolation buffer (dark gray). Decay was plotted as a function of b×D (non-dimensionalized by D₀=2.15 μm²/ms measured from aCSF), showing signal from isolated mitochondria persists well beyond b-values which attenuate free water.

FIG. 27C depicts a graph showing entire signal decay from diffusion measurements performed on isolated mitochondria (28 μg/μl measured by BCA) in isolation buffer (light grey) and on only isolation buffer (dark gray). Decay was plotted as a function of (b×D₀)^{1/3}. The persistent signal decays exponentially on this scale, consistent with water restricted on sub-micron length scales within mitochondria. The dotted line is a model for water restricted within spheres with exchange, incorporating the k=250 s⁻¹ measured from the curvature approach. The model was insensitive to restriction length scales below the dephasing length lg=800 nm, although 100 nm was used.

FIG. 27D depicts a graph showing distributions from diffusion measurements performed on isolated mitochondria (28 μg/μl measured by BCA) in isolation buffer (light grey) and on only isolation buffer (dark gray). Diffusion coefficient distribution of isolated mitochondria (solid black line) shows a major diffusion component consistent with the distribution measured on isolation buffer (dot-dashed line) near D/D₀=1 and components with D/D₀<<1 consistent with consistent water within mitochondria. The dot-dash line in is the distribution measured for buffer. In FIGS. 27A-27D, the shaded band shows the standard deviation from three repeated measurements.

FIG. 28 depicts a graph showing the exchange fractions from the curvature approach measurements on isolated mitochondria (28 μg/μl), fit by a first order rate model with estimated k=250±50 s⁻¹. Error bars are the standard deviations from three repeat measurements.

FIG. 29 depicts a series of graphs showing that fully blocking the Na⁺/K⁺ pump causes exchange rate to significantly decrease. Addition of 100 μM ouabain causes a 67% decrease in water exchange rate. The sample did not recover when washed back to normal media. Restricted volume increases, indicative of cell swelling. Mean apparent diffusion coefficient increases, and spin lattice relaxation rate decreases, but to a lesser degree, perhaps due to similar (exchange and restriction) effects occurring on various timescales. Middle column shows mean (points) and standard deviations from n=3 samples, and display the consistency of the timescale and magnitude of the effects. Bar graphs present 95% CIs (whiskers) and mean values of measurements for the normal condition and after ouabain takes effect on each sample (circles) (n=3). The bottom row shows raw b=3.3 ms/μm² diffusion (squares) non-exchange-weighted DEXSY signals (circles) and exchange-weighted DEXSY signals (diamonds) with T₁ relaxation effects removed, normalized by their values during the normal condition, and provides sub-minute resolution of the timescale of the effect. Normalized signals are presented for n=3 samples for the time region around the effect. Exchange-weighted DEXSY signals were omitted for clarity. 100 μM ouabain takes effect roughly 10 minutes after it hits the sample but appears more as a step-function, with the timescale from no effect to full effect being roughly 2 minutes.

FIG. 30 is a series of graphs showing that when the Na⁺/K⁺ pump is partially blocked, exchange rate decreases by a similar amount to when it is fully blocked but after a longer delay. Low (1-10 μM) doses of ouabain reduced water exchange rate in an all-or-none fashion; either they had no effect during the experiment, or they reduced the exchange rate to the same level as 100 μM. Increasing the dosage has no additional effect on the exchange rate. The normalized restricted volume is not affected by low doses of ouabain, indicative of no apparent cell swelling. Low doses of ouabain take effect>10 minutes after hitting the sample but still as a step function. Bar graphs show mean values and 95% CI from n=5 samples.

FIG. 31 is a series of graphs showing that the exchange rate decreases upon AMPA addition and recovers upon washout. Real-time measurements with perturbations normal→5 μM AMPA→normal→5 μM AMPA→10 μM AMPA→normal are shown for a representative sample and in the form of bar graphs showing the average effect for each condition (n=5). Bar graphs also show 95% confidence intervals (whiskers) and the mean value for each sample (open circles).

FIG. 32 is a schematic showing a depiction of steady-state transmembrane water exchange linked to active transport of ions.

FIG. 33 is a schematic showing an exemplary experimental setup for simultaneous NMR and optical microscopy, in accordance with an aspect of the invention. For simplicity, the microelectrode and stand for dye injection are not shown.

FIG. 34 is a set of graphs showing that simultaneous real-time NMR and microscopy reveals the connection between structural and functional changes during stroke. A representative experiment of high-temporal cellular structure (top) and function (bottom) measurements during perturbations from normal aCSF, 95% pO₂ to glucose-free aCSF, 1% pO₂ to normal. NMR measurements of apparent diffusion coefficient (ADC) and exchange rate (black lines) have values associated with the left-hand y-axis. Microscopy measurements of intrinsic optical signal (gray line), [Ca²⁺]ᵢ from Rhod3 AM fluorescence (gray line) and voltage from Fluovolt fluorescence (light gray line) are presented as % changes from baseline and have values associated with the right-hand y-axis. [Ca²⁺]ᵢ and voltage signals decrease during the baseline due to diffusion of dye out of the region of interest. Arrows show when cells begin to swell and when homeostasis is lost.

FIG. 35A is a series of graphs showing raw data from summed CPMG echoes at I_{mid} and I_{end}. Error bars=±1 SD from repeated measurements on a sample.

FIG. 35B is a series of graphs showing log-ratio of the signals with biexponential and monoexponential fits. Inset shows short tₘ.

FIG. 35C is a series of graphs showing the same data as FIG. 35B, but with a log tₘ axis and showing only mean values. Here, f_{∞}/C₁ and C₀ are visible as bounds that are well-fit with a biexponential. Fitted values are f_{∞}/C₁=[0.331, 0.418, 0.369] and C₀=[0.198, 0.213, 0.220], left to right. FIGS. 35A-35C show data processing and fitting for C₀, f_{∞}/C₁.

FIG. 36A is a series of graphs showing fully sampled data with 69 values of tₘ, taking only the mean log-ratio signal values. On the right is a combined log tₘ plot.

FIG. 36B is a series of graphs showing sub-sampled data over the same range at tₘ=[0.2, 1, 1, 2, 4, 7, 12, 18, 32, 50, 80, 120, 220, 340, 600, 1000] ms. Note that fits for f_{∞}/C₁ and C₀ were performed again with the sub-sampled data.

FIG. 37A is a graph showing distributions in the fully sampled case (FIG. 36A). Distributions are scaled by f_{∞}/C₁ for comparison in terms of the total exchange during tₘ. The center of the two peaks in live tissue are marked (2, 79 ms).

FIG. 37B is a graph showing P(τₖ) in the sub-sampled case. While less resolved, characteristics are broadly similar to FIG. 37A, suggesting the feasibility of data reduction. FIGS. 37A and 37B show inverted P(τₖ) distributions in the fully sampled and sub-sampled cases for fixed, live, and live with ouabain spinal cords.

### DETAILED DESCRIPTION

The disclosure contained herein provides a fast, accurate, non-invasive, quantitative, and contrast agent-free MR method to measure homeostasis (e.g., cellular homeostasis). More specifically, the disclosure provides use of non-invasive methods to measure steady-state transmembrane exchange rates of endogenous components in order to diagnose, identify, record, monitor, map, or image, normal and abnormal homeostatic states of organisms, tissues, cells, organs, or organelles in near-real-time.

Please note that the following description of the measurement techniques provided in this disclosure are discussed in terms of transmembrane water exchange, and more specifically discussed in terms of transmembrane water exchange related to SD within the CNS. However, the disclosed techniques are similarly applicable to many other biological processes and diseases. Indeed, any such process or disease related to disruptions in cellular homeostasis may be measured and analyzed using the aspects of the disclosure provided herein.

In certain aspects, the measurement of cellular homeostasis disclosed herein may detect a steady-state rate of transmembrane water exchange. For instance, aspects of the disclosure may be utilized to detect changes in the steady-state associated with SD and function. The disclosed method is performed in real time and may be used to evaluate the normal physiological state of the CNS and possible pathological changes occurring in disease, development, aging or SD that results from trauma. The disclosed method directly measures cellular activity in the tissue of the CNS by measuring a water exchange rate, which is an intrinsic parameter representing water homeostasis. Measuring water homeostasis that deviates from a normal value can indicate pathology prior to detection by other means. As such, the disclosed method can function as a useful imaging biomarker for normal and abnormal CNS activity from development, aging, degeneration, mild traumatic brain injury (mTBI), trauma, Alzheimer's disease, and physiological states such as sleep, wakefulness, arousal, and any CNS activity in general.

In developing various aspects of the disclosure contained herein, technical research and analysis were performed on ex vivo CNS tissue. Aspects of this research and analysis, including a measurement setup for ex vivo tissue, is described in Williamson et al., “Water exchange rates measure active transport and homeostasis in neural tissue,”______, 202X (hereinafter, “Williamson”), and in Williamson et al., “Diffusion Exchange MR Measures Water Exchange Linked to Cellular Homeostasis and Activity States in Central Nervous Tissue,” 202X (hereinafter, “Williamson II”), the disclosures of which are incorporated herein by reference. Building on the research and analysis of Williamson and Williamson II, aspects of the present disclosure provide devices and methods for measuring a steady-state rate of transmembrane water exchange for in vivo and ex vivo tissue.

Water homeostasis involves a steady-state exchange of H₂O inside [symbol] H₂O outside the cell (i.e., no net flux implying no cell volume change). In the past, steady-state transmembrane water exchange was believed to be a passive process solely defined by the permeability of the membrane to water and controlled largely by aquaporin expression. However, it can be shown that a number of membrane transport proteins are reported to actively cotransport hundreds of H₂O molecules per ion or metabolite. With a Na⁺/K⁺ pump consuming ˜20 μM ATP/g/min in CNS tissue this would lead to ˜2×10⁸ water molecules exchanging per second within a 1 μm³ tissue volume. For relatively few ions transported, many water molecules cotransport, and this water cotransport is measurable. Water cotransport is also seen to change under various conditions. MR analysis on organotypic CNS shows that the steady-state transmembrane water exchange rate decreases by 50% after blocking the Na⁺/K⁺ pump with ouabain. Based on this result, it is determined that a significant fraction of the exchange rate is non-passive and linked to ion transport, both directly through and downstream of the Na⁺/K⁺ pump.

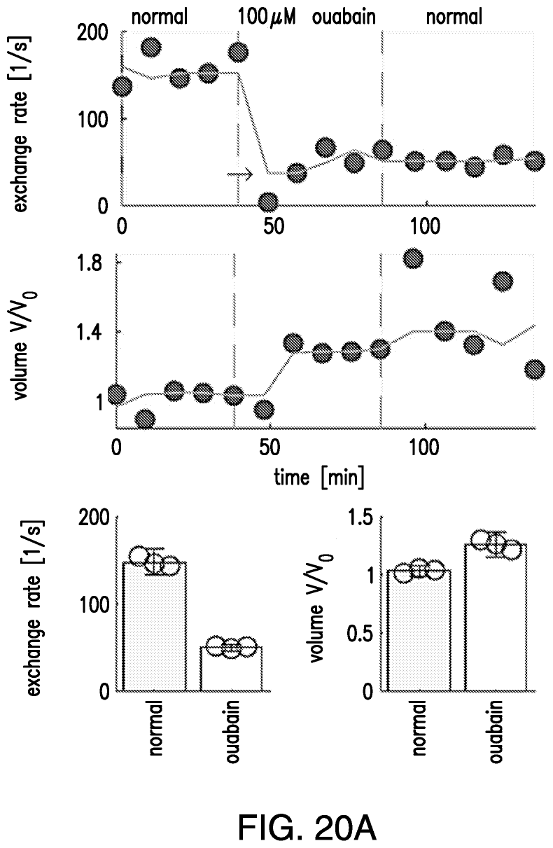

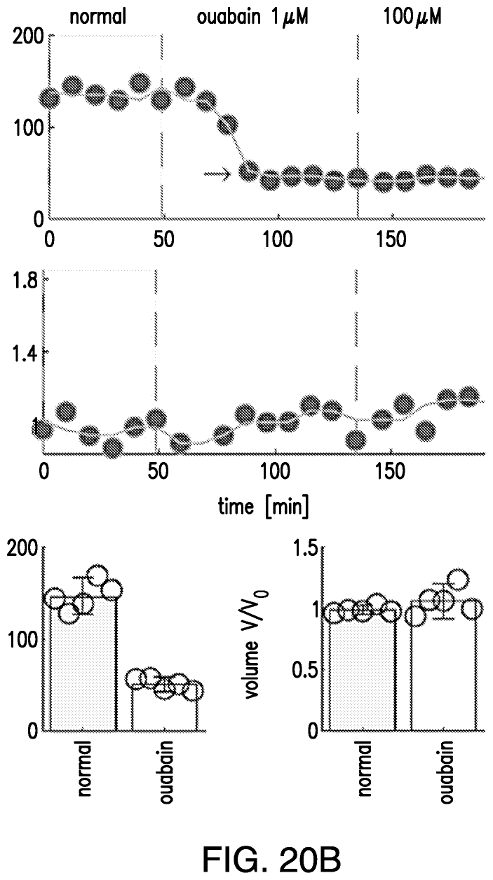

It is further determined that the ion transport linked to the exchange rate is linked to SD by measuring steady-state depolarization (ssD). Experimental results based on MR measurements of ex vivo tissue shown in FIGS. 20A and 20B show that completely blocking Na⁺/K⁺ pump activity with 100 μM ouabain causes the water exchange rate to abruptly decrease to 50 s⁻¹, in lab test samples (FIG. 20A). Partially blocking Na⁺/K⁺ pump activity with doses as low as 1 μM also caused the water exchange rate to decrease to 50 s⁻¹, but after a delayed period (FIG. 20B). As such, introduction of ouabain produced a dose-independent effect on the exchange rate consistent with SD's “all-or-none” character.

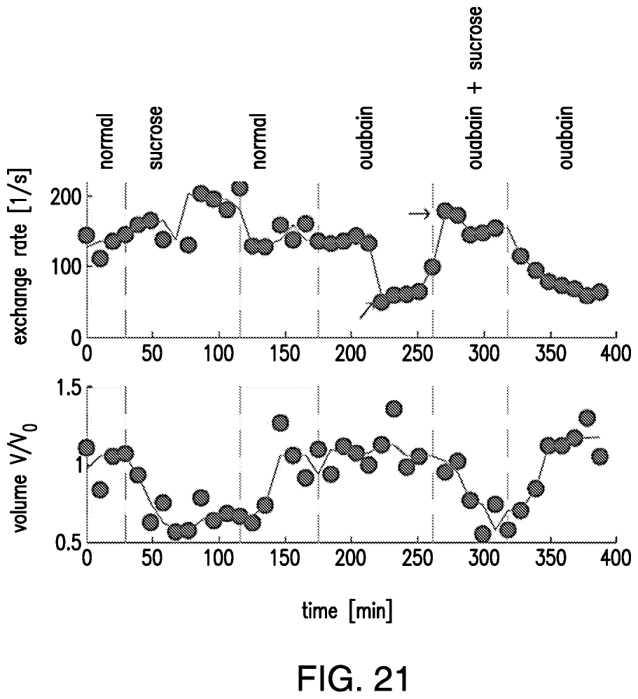

As shown in FIG. 21, shrinking cells with 100 mM sucrose (osmolyte) in normal conditions had a small effect on water exchange rate, but in ouabain-treated states addition of the osmolyte led to a drastic recovery from 50 s⁻¹ back to 150 s⁻¹, thereby showing that ouabain-induced SD can be abolished by addition of an osmolyte. Further, AMPA (α-amino-3-hydroxy-5-methyl-4-isoxazolepropionic acid) causes exchange rate to decrease, the effect of which is reversible when AMPA is washed out, and a second dose of AMPA has less of an effect, consistent with AMPA causing depolarization and recycling of receptors conditioning the cells to AMPA.

In view of the above, ouabain and AMPA substantially reduce the exchange rate and that osmolyte addition recovers the exchange rate from the ouabain-reduced state back to a value consistent with the normal state. As such, ssD is induced by ouabain and AMPA and that ouabain-induced ssD can be abolished by addition of an osmolyte. Accordingly, it is determined that exchange rate is connected to ssD and SD.

Water exchange rate is an absolute (as opposed to a relative) metric. Further, the water exchange rate lies within a well-defined range of about 150 s⁻¹ for normal conditions (see 95% confidence intervals in FIG. 20) in a system of the present invention. The water exchange rate's absolute nature along with its connection to ssD (and the loss of homeostasis associated with SD) indicate that a normal exchange rate is a vital sign for CNS homeostasis.

As such, aspects of an MR device and method are disclosed for measuring this water exchange rate that is indicative of CNS states such as SD. MR is particularly suited to measure this water exchange rate because a proton MR signal derives directly from magnetization of hydrogen atoms on naturally-abundant endogenous water molecules within a biological sample without a need for dyes or indicators. MR is completely non-invasive and safe for human use. Sensitivity to water, complete non-invasiveness, and a plethora of image contrast mechanisms sensitive to anatomy and pathology make MR ideal for imaging vital organs such as the brain and spinal cord. The proton magnetization holds a memory of how it was encoded, enabling the measurement of water motion and other processes. Such encoding methods form the basis of MR diffusion measurements and diffusion MRI. Membranes impart a difference in the diffusive mobility between water inside and outside the cell and in this way diffusion MR methods can detect the intracellular volume fraction and average changes in cell volume.

Building on diffusion measurements and utilizing the fact that magnetization holds a memory of its encoding, the exchange of water between regions of differing diffusive mobility with diffusion exchange spectroscopy (DEXSY) can be encoded. Traditional DEXSY requires many scans with different encoding combinations and greater than one hour measurement times to resolve exchanging components. Accordingly, to make DEXSY more suitable for biological applications, rapid techniques have been developed to reduce the number of scans, achieving exchange rate measurement times between one and ten minutes (i.e., about one, about two, about 3, about 4, about 5, about 6, about 7, about 8 about 9, about 10 minutes). Such techniques are discussed in Cai et al., Journal of Magnetic Resonance, 297: 17-22 (2018), the disclosure of which is incorporated herein in its entirety. By greatly reducing the measurement time, measuring water exchange disclosed herein is useable for real-time recording in biological samples as the basis of MR hydrophysiology.

Aspects of the disclosed method may be implemented in existing MRI scanners and other imaging devices. Using these MR devices, the method can detect normal conditions as well as pathological and physiological events as they occur in real-time. In certain aspects, MR pulse sequences may be used to measure and map a steady-state water exchange rate in the brain using existing conventional low-field and high-field MRI scanners. In other aspects, a low-field MR device may measure these pathological and physiological states in the CNS of human patients in vivo, for instance in cortical gray matter.

The following description provides an aspect of a method of measuring water exchange rate within in vivo or ex vivo CNS tissue in near-real time. The disclosed method measures a cellular-scale average of the complete exchange associated with all transmembrane water transport (inside-outside plus outside-inside), which is in contrast to all other measurements of transmembrane water transport that can only measure non-steady-state net flux (inside-outside minus outside-inside).

The following description describes an aspect of a non-invasive measurement of exchange for assessing the homeostatic state in living organisms. Aspects of the method can be performed using any non-invasive technique and method within a technique capable of tagging and separating signals from endogenous molecules in the intramembrane and extramembrane (e.g., intracellular and extracellular) spaces based on characteristics of their environment and recording the signals at different times as the molecules exchange between these spaces and impart distinct characteristics in the signal. Within the field of magnetic resonance (MR), this includes nuclear magnetic resonance (NMR) and electron paramagnetic resonance (EPR) techniques. Exchange methods within the field of NMR measure signal from non-zero spin-bearing nuclei. This includes molecules containing protons for which relevant endogenous molecules include water and metabolites such as lactate, pyruvate, creatinine, and N-acetylaspartate. It also includes other endogenous nuclei such as NMR-detectable isotopes of sodium, phosphorus, fluorine, etc.

A non-exhaustive list of relevant measurement techniques within NMR include relaxation exchange spectroscopy (REXSY), velocity exchange spectroscopy (VEXSY), exchange spectroscopy (EXSY), relaxation dispersion, single diffusion encoding with variable diffusion time, double diffusion encoding with variable mixing time, and multi-(n>2) diffusion encoding. Within the umbrella of single diffusion encoding with variable diffusion time there are several techniques to measure exchange which all show some commonality to the seminal Karger method (Karger et al., Adv. Magn. Reson., 21: 1-89 (1988)). Techniques to measure exchange with double diffusion encoding with variable mixing time are based off the original diffusion exchange spectroscopy (DEXSY) method (Callaghan & Fúro, J Chem. Phys., 120: 4032-4038 (2004)), and include the filter exchange spectroscopy (FEXSY) (Åslund, et al., J. Magn. Reson. 200(2): 291-295 (2009)) and Imaging (FEXI) (Lasič, et al., Magn. Reson. Med., 66(2): 356-365 (2011)) techniques, as well as a method herein referred to as the curvature approach (Cai, et al., Journal of Magnetic Resonance, 297: 17-22 (2018)). Measurements of exchange with multi-diffusion encoding can be based off repeated diffusion encodings such as with a Carr-Purcell-Meiboom-Gill (CPMG) echo train (Carr & Purcell, Phys. Rev., 94: 630 1954) including a technique termed static gradient time incremented echo train acquisition (SG-TIETA) (Cai, J. Chem. Phys., 154: 111105 (2021)). Further, combinations of signals acquired with single, double, or multiple diffusion encoding schemes can be analyzed together to measure exchange.

In general, NMR methods to measure exchange can be combined with other NMR modalities including magnetic resonance imaging (MRI) methods for exchange rate mapping and imaging, with spectroscopic techniques such as Fourier transform of the echo signal to spectrally resolve species based on their chemical shift, or with CPMG refocusing to increase signal. Exchange rates can also be analyzed as a distributed property, i.e., as a probability density function representing different components with distinct exchange rates. Exchange rate can be combined with other parameters as a multidimensional measurement, e.g., T₁-k, T₂-k, restricted diameter-k, and diffusion anisotropy-k.

NMR methods to measure exchange based on single, double, or multi-diffusion encoding can utilize any means of forming gradient echoes including radiofrequency modulation under a static gradient, pulsed field gradients, and combinations of radiofrequency pulses and gradient pulses (pulsed gradient spin echo), inter alia.

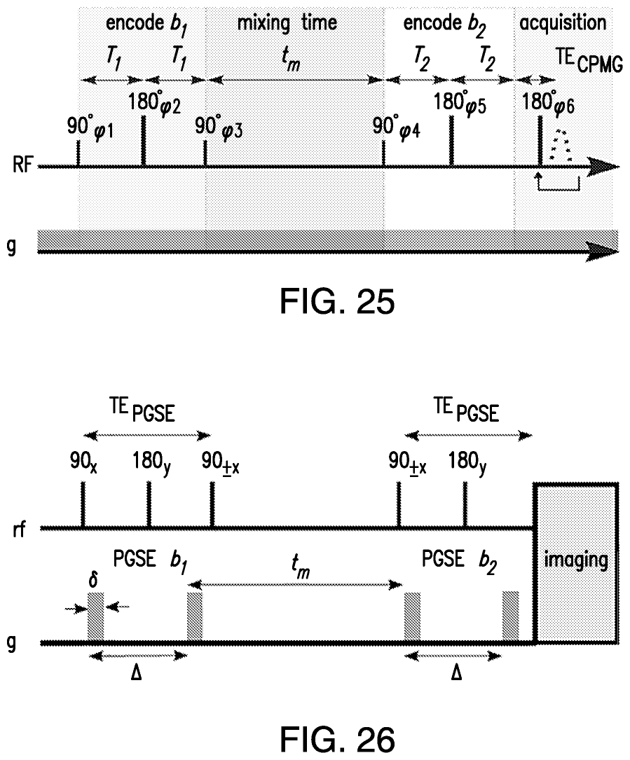

The following aspects of the disclosed method describe a method for measuring exchange based on the DEXSY method. This method involves acquiring signals with the DEXSY pulse sequence and fitting an exchange model to the signals. The DEXSY pulse sequence involves two diffusion encoding periods separated by a mixing time. The DEXSY pulse sequence can be performed with static gradients (SG) or pulsed gradients (PG) and these aspects are described in FIGS. 25 and 26. Each diffusion encoding period satisfies the condition that the integral under the effective gradient sums to zero, i.e., the gradient echo condition, which refocuses location-dependent phase shifts. Spins dephase based on their displacement along the direction of the applied gradient during the intervals. Signals hold the correlation between displacements of spins during each interval. Diffusion during each interval is probed by varying the gradient and/or timing characteristics of the diffusion encoding periods. During the mixing time, the magnetization is stored in the longitudinal axis and decays slowly due to spin-lattice relaxation. During this time, spins are able to exchange between different local environments within the sample. Exchange is probed by varying the mixing time. In certain aspects of the disclosed method, the signal may be processed in a certain way to quantify the exchanging fraction at each mixing time. An exchange model is fit to the signal data to estimate the exchange rate.

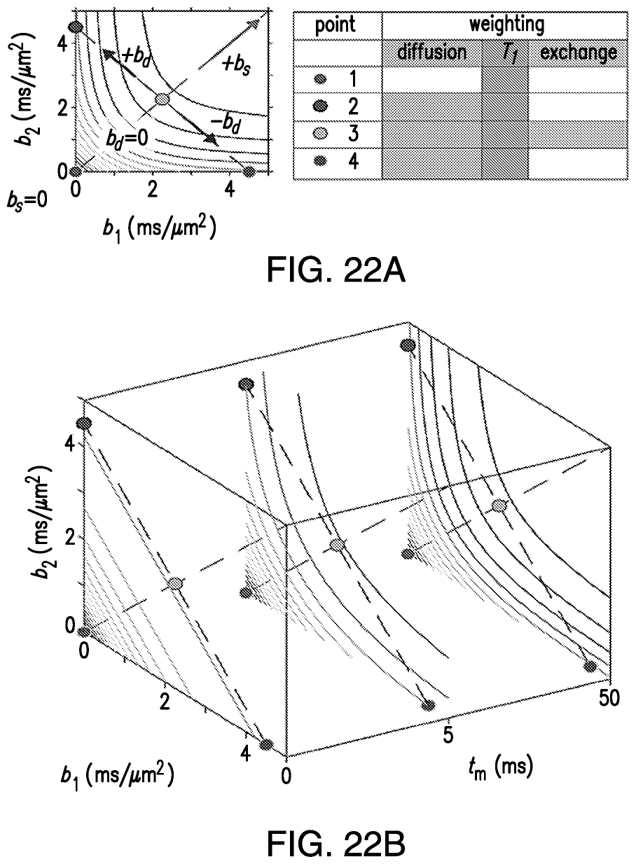

Acquisition of DEXSY signals with various weightings necessary for isolation of exchange and measurement of exchange rate is depicted in FIG. 22A-22B. In the DEXSY signal acquisition, the diffusion weightings of the two gradient echoes, b₁ and b₂, as well as the exchange weighting and T₁ weighting of the mixing time tₘ are varied independently. Signals are combined to isolate the exchange weighting, normalize for proton density, and cancel the diffusion and T₁ weighting. Signals acquired with b₁ and b₂≈0 have negligible diffusion weighting. Signals acquired with tₘ≈0 have insignificant T₁ and exchange weighting. Signals acquired with b₁≈0 and b₂>0 or b₂≈0 and b₁>0 are diffusion weighted but not exchange weighted. Exchange weighting is increased while diffusion weighting is held constant by decreasing b₂−b₁=b_{d} towards zero while keeping b₁+b₂=bₛ constant. Maximum exchange weighting is achieved with b_{d}=0 and minimum exchange weighting is achieved when b_{d}±bₛ. The diffusion weighting is canceled to isolate the exchange weighting by taking the difference between the minimally and maximally exchange-weighted signals acquired with the same bₛ and tₘ. The signal combination is then acquired at multiple tₘ spanning tₘ<<1/k to tₘ>>1/k where k is the exchange rate. The exchange rate is estimated by fitting a first-order rate model to the signals as a function of tₘ. The acquisition time per exchange rate is determined by the number of signals needed per measurement, the repetition time, and the number of scans per signal. The minimal number of scans per signal is defined by the phase cycles. The minimum repetition time is defined by the T₁ relaxation time. The minimum number of scans per measurement is reduced by fitting the minimally and maximally exchange weighted signals in two steps, assuming that both signals share similar R₁ relaxation. This involves separately fitting the minimally exchange weighted signal to separately estimate R₁, subtracting the model fit from the maximally exchange signal and then fitting the remaining signal decay to estimate the exchange rate. In order to further reduce the number of parameters fit, the signal at the largest tₘ can be baseline subtracted. This assumes that all exchange has occurred at the final mixing time (tₘ>>1/k) and does not account for uncertainty in the measurement. With these various options for data reduction, the minimum number of signals per exchange rate measurement can vary from 22 to as few as five. Data reduction methods are summarized in Table 1. Parameters are estimated by fitting models to the data using least squares minimization of error. It is additionally possible to interpolate between points acquired with exchange weighting at different mixing times to estimate an exchange rate. Such an interpolation can be performed with three tₘ, where one tₘ is much less than 1/k, a second is similar to 1/k and a third is much larger than 1/k. an example of an interpolation would be to divide the difference between point one and two by the difference between point one and three.

TABLE 1

| Method | Signal equation | tₘ [ms] | B [ms] |
|---|---|---|---|
| 1 | (Iₚₜ₂ − 2Iₚₜ₃ + Iₚₜ₄)/Iₚₜ₁ | 0.2-300 | |
| 2 | Iₚₜ₃/Iₚₜ₂ | 0.2-300 | |
| 3, step 1 | Iₚₜ₂ | 0.2-300 | |
| step 2 | Iₚₜ₃/exp(−tₘR₁) | 0.2-300 | |
| 4, step 1 | Iₚₜ₂ | 0.2-300 | |
| step 2 | Iₚₜ₃/exp(−tₘR₁) | 0.2-10 | 160, 300 |
| 5, step 1 | Iₚₜ₂ | 0.2, 300 | |
| step 2 | Iₚₜ₃/exp(−tₘR₁) | 0.2, 10 | 300 |

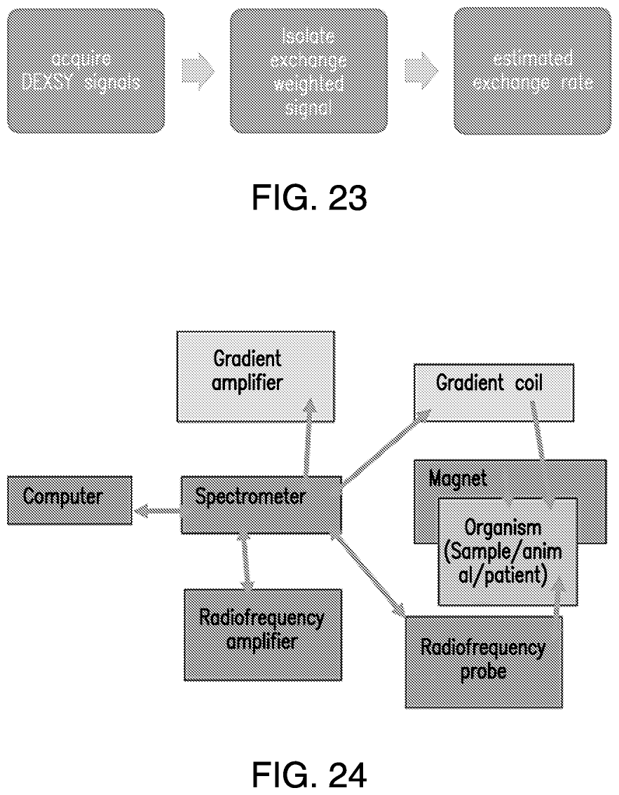

In a particular aspect, the above described aspects of the disclosed method of measuring water exchange may be performed with an MR system involving an inhomogeneous magnetic field that serves as a static gradient. FIG. 23 provides a depiction of a method for measuring exchange rate. FIG. 24 shows the exemplary hardware for performing the method of FIG. 23, including a magnet, an RF probe, N M spectrometer, RF amplifier, and computer. FIG. 25 and Table 2 show the Static Gradient Diffusion Exchange Spectroscopy (SG-DEXSY) pulse sequence and phase cycles. The echo signal following the second diffusion encoding is refocused and acquired many times in CPMG echo train. The echo train signal is summed together in order to increase the signal-to-noise ratio.

TABLE 2

| φ₁ | φ₂ | φ₃ | φ₄ | φ₅ | φ₆ | φ_{rec} |
|---|---|---|---|---|---|---|
| 0 | +π/2 | 0 | 0 | +π/2 | π/2 | π |
| π | −π/2 | 0 | 0 | +π/2 | π/2 | 0 |
| 0 | +π/2 | π | 0 | +π/2 | π/2 | 0 |
| π | −π/2 | π | 0 | +π/2 | π/2 | π |
| 0 | +π/2 | 0 | π | −π/2 | π/2 | 0 |
| π | −π/2 | 0 | π | −π/2 | π/2 | π |
| 0 | +π/2 | π | π | −π/2 | π/2 | π |
| π | −π/2 | π | π | −π/2 | π/2 | 0 |

In another aspect, the method of measuring water exchange discussed with respect to FIGS. 20-22 may be performed using a homogeneous magnetic field and pulsed field gradients. Such a device would include a homogeneous magnet, an RF probe, RF amplifier, pulsed magnetic field gradient coils and amplifiers, and a computer, as shown in FIG. 25. FIG. 26 shows the Pulsed Gradient Diffusion Exchange Spectroscopy (PG-DEXSY) pulse sequence and phase cycles. The echo signal following the second diffusion encoding is brought through an imaging or spectroscopy acquisition scheme including but not limited to Multi-Slice Multi-Echo (MSME), Echo Planar Imaging (EPI), and Single-Voxel Spectroscopy.

Although aspects of this disclosure entail measuring water protons exchanging between compartments or pools within a medium (i.e., cell of a biological system), in view of this disclosure, one can imagine following diffusion exchange of protons residing on biomolecules and metabolites, such as phosphocreatine, lactate, pyruvate, etc. by filtering with chemical spectroscopic methods. Moreover, using aspects of the disclosure provided herein, measurements of diffusion exchange in spin-labelled solvent species, such as D₂O, and measurements of exchange in various ions, such as ²³sodium (²³Na), ³¹phosphorus (³¹P) or ¹⁹fluorine (¹⁹F) may be obtained.

An aspect of the invention provides methods to determine a homeostatic steady-state of a biological entity. In another aspect, the invention provides methods to determine a loss of homeostatic steady-state of a biological entity. As used herein, a “homeostatic steady-state” refers to a state that is steady or maintained for a period of time. The homeostatis steady-state can be a healthy or normal state in the biological entity. There can be multiple ideal steady-states within a biological entity. Divergence from the ideal steady-states would be non-ideal steady states that can indicate a not-desirable state for the biological entity to be in (e.g., dying). Homeostatic steady-states include physiological states (e.g., sleeping, awake, stimulated, intense thinking, intensive activity). As used herein, “a loss of homeostatic steady-state” refers to state that is not steady. The “loss of homeostatic steady-state” can indicate a pathological state or unhealthy state in the biological entity, but can also indicate adjustment/movement to another physiological steady-state.

In an aspect, the invention further provides methods to determine a homeostatic steady-state of a biological entity, the method comprising a magnetic resonance (MR) system, the MR system comprising: a. a means to create a static or pulsed magnetic field gradient; b. a means to create a constant magnetic field; c. a means to hold a biological entity within the constant magnetic field and the static or pulsed magnetic field gradient; d. a radiofrequency transmitter; e. a radiofrequency receiver that measures radiofrequency electromagnetic fields; f. a radiofrequency transmit amplifier; g. a MR radiofrequency pulse sequence generator that sends signals to the radiofrequency transmit amplifier to acquire Diffusion Exchange Spectroscopy (DEXSY) data; h. a recording device to sample and store a MR magnetization signal detected by the radiofrequency receiver; and i. a mathematical modeling framework to transform the recorded magnetization signal DEXSY data, wherein interpretation of the DEXSY data provides a homeostatic steady-state of a biological entity. In a further aspect, a biological entity is placed in the means to hold the biological entity. In an aspect, the means to hold the biological entity can be determined by one of skill in the art. It should be an appropriate size to adequately contain the biological entity within the magnetic field, gradient field, and radiofrequency field. The MR system can be a Nuclear Magnetic Resonance (NMR) system or a Magnetic Resonance Imaging (MRI) system.

An aspect of the invention provides a MR system, the MR system comprising: a. a means to create a static or pulsed magnetic field gradient; b. a means to create a constant magnetic field; c. a means to hold a biological entity within the constant magnetic field and the static or pulsed magnetic field gradient; d. a radiofrequency transmitter; e. a radiofrequency receiver that measures radiofrequency electromagnetic fields; f a radiofrequency transmit amplifier; g. a MR radiofrequency pulse sequence generator that sends signals to the radiofrequency transmit amplifier to acquire Diffusion Exchange Spectroscopy (DEXSY) data; h. a recording device to sample and store a MR magnetization signal detected by the radiofrequency receiver; and i. a mathematical modeling framework to transform the recorded magnetization signal DEXSY data.

The pathological state can be from disease, development, aging, or trauma. Pathological states include infectious and non-infectious diseases. Infectious diseases include those caused by infectious organisms (e.g., bacteria, virus, protozoa). Non-infectious diseases include autoimmune disorders, allergies, cancers, Alzheimer's, Parkinson's, etc. In an aspect, the pathological state is a stroke, brain aneurysm, traumatic brain injury, migraine aura. In an aspect, the pathological state is caused by a spreading depolarization (SD). In a further aspect, the pathological state is characterized by a rapid and near-complete loss of transmembrane potential that depresses neuronal activity. In an aspect, the pathological state is a stroke.

In an aspect, the biological entity is a molecule, group of molecules, cell, tissue, or organ. In an aspect of the invention, the biological entity is a cell. The cell can be any cell, e.g., a plant, animal, bacteria, protozoa, etc. In an aspect, the cell is an animal cell. The cell can also be a mammal cell. As used herein, the term “mammal” refers to any mammal, including, but not limited to, mammals of the order Rodentia, including mice and hamsters, mammals of the order Logomorpha, including rabbits, mammals from the order Carnivora, including Felines (cats) and Canines (dogs), mammals from the order Artiodactyla, including Bovines (cows) and Swines (pigs), mammals from the order Perssodactyla, including Equines (horses), mammals of the order Primates, Ceboids, or Simoids (monkeys), and mammals of the order Anthropoids (humans and apes). An especially preferred mammal is the human.

In an aspect, the cell is part of a tissue or organ. The tissue can be epithelial tissue, connective tissue, muscle tissue, or nervous tissue. The organs can be cardiovascular (e.g., heart, blood, and blood vessels), lymphatic (e.g., lymph, lymph nodes, and lymph vessels), digestive (e.g., mouth, salivary glands, esophagus, stomach, liver, gallbladder, pancreas, intestines), endocrine (e.g., pituitary, pineal, thyroid, parathyroid, pancreas, adrenals, tests, ovaries), integumentary (e.g., skin, hair, and nails), muscular (e.g., skeletal, cardiac, and smooth muscle), nervous (e.g., brain, spinal cord, nerves, sensory organs—eyes, ears, tongue, skin, and nose), reproductive (e.g., fallopian tubes, uterus, ovaries, mammary glands, testes, vas deferens, etc.), respiratory (e.g., mouth, nose, pharynx, larynx, trachea, bronchi, lungs, and diaphragm), skeletal (e.g., bones, cartilage, joints, tendons, and ligaments), urinary (e.g., kidneys, ureters, bladder, and urethra), and immune (e.g., leukocytes, tonsils, adenoids, thymus, and spleen). In an aspect, cell is a cell of the central nervous system. In an aspect, the cell is a spinal cord cell. In a further aspect, the cell is white and/or grey matter.

In an aspect, the biological entity is an organelle. As used herein, an “organelle” is a specialized subunit of the cell that has a specific function. The organelle can be a space within the cell that is bound by lipid bilayers. In an aspect, the organelle is a chloroplast, endoplasmic reticulum, Golgi apparatus, mitochondria, nucleus, or vacuole. In an aspect, the organelle is a mitochondria.

In another aspect, the biological entity is living. In a further aspect, the biological entity is no longer living (e.g., fixed cells and tissues).

An aspect of the invention provides methods to determine a homeostatic steady-state of a biological entity, the method comprising: acquiring signals with Nuclear Magnetic Resonance (NMR) from the biological entity; and b. fitting an exchange model to the signals. In another aspect, the invention provides methods to determine a homeostatic steady-state of a biological entity, the method comprising: a. acquiring signals with Nuclear Magnetic Resonance (NMR) from the biological entity; and b. isolating exchange weighted signal; and c. estimating the exchange rate.

In another aspect, the invention provides methods to determine a loss of homeostatic steady-state of a biological entity, the method comprising: a. acquiring signals with Nuclear Magnetic Resonance (NMR) from the biological entity; and b. fitting an exchange model to the signals. In another aspect, the invention provides methods to determine a loss of homeostatic steady-state of a biological entity, the method comprising: a. acquiring signals with Nuclear Magnetic Resonance (NMR) from the biological entity; and b. isolating exchange weighted signal; and c. estimating the exchange rate.

Any of the NMR methods mentioned herein can be utilized. In an aspect, the NMR is diffusion exchange spectroscopy (DEXSY). In a further aspect, the NMR is low-field, high-gradient (DEXSY). Any of the NMR methods mentioned herein can be utilized.

In an aspect, the system is a NMR system. In a further aspect, the system is a one-sided NMR profiling system. In a NMR system, static magnetic fields are used. In a further aspect, the MR system is a MRI scanner system. In the MRI scanner system, pulsed magnetic gradients are used.

In an aspect, the radiofrequency receiver measures radiofrequency electromagnetic fields emanating from the biological entity. In a further aspect, the radiofrequency transmitter emits radiofrequency electromagnetic fields to excite magnetic spins in the biological entity.

In an aspect, the invention further provides a mathematical means to estimate the steady state water exchange rate of endogenous water from the DEXSY NMR data.

In a further aspect, methods of an aspect of the invention use steady state water exchange rate as a proxy for normal water homeostasis. In another aspect, steady-state water exchange rate is replaced by a steady-state exchange rate spectrum or distribution.

In an aspect, the biological entity is living human tissue. In a further aspect, the living human tissue is ischemic.

In another aspect, the invention provides methods to quantify an exchange rate between at least two compartments in a biological system. The two compartments can be separated by any suitable means, for example, by a biological membrane such as a lipid bilayer.

In an aspect, the exchange rate is used to determine neuroprotectant efficacy.

In a further aspect, the exchange rate is used to determine a homeostatic steady-state of the biological system. In an aspect, the exchange rate is used to determine a loss of homeostatic steady-state of the biological system. A loss of homeostatic steady-state of the biological system may indicate a homeostatic non-steady state. A homeostatic non-steady state may include a pathological state.

In an aspect, the invention provides methods to quantify an exchange rate between at least two compartments in a biological system, wherein the method comprises a MR system comprising: a. a means to create a static or pulsed magnetic field gradient, b. a. means to create a constant magnetic field; c. a means to hold a biological entity within the constant magnetic field and the static or pulsed magnetic field gradient; d, a radiofrequency transmitter; e, a radiofrequency receiver that measures radiofrequency electromagnetic fields; f a radiofrequency transmit amplifier; g. a SIR radiofrequency pulse sequence generator that sends signals to the radiofrequency transmit amplifier to acquire Diffusion Exchange Spectroscopy (DEXSY) data; h. a recording device to sample and store a MR magnetization signal detected by the radiofrequency receiver, and i. a mathematical modeling framework to transform the recorded magnetization signal DEXSY data. In a further aspect, the exchange rate is used to determine neuroprotectant efficacy. In another aspect, the exchange rate is used to determine a homeostatic steady-state of the biological entity. In an aspect, the homeostatic non-steady state is a pathological state.

The means to create a. static magnetic field gradient can be determined by one skilled in the art and any suitable means to create a static magnetic field gradient may be used. The means to create a pulsed magnetic field gradient can be determined by one skilled in the art and any suitable means to create a pulsed magnetic field gradient may be used. The means to create a constant magnetic field can be determined by one skilled in the art and any suitable means to create a constant magnetic field may be used.

In another aspect, the invention provides Nuclear Magnetic Resonance (NMR) methods to characterize physiological water transport.

In aspects of the invention, the methods do not require exogenous contrast agents in order to visualize homeostatic steady-state of a biological entity. In an aspect, the methods explicitly exclude exogenous contrast agents.

In another aspect, the invention provides methods for non-invasively measuring transmembrane exchange rates of endogenous water in biological systems under steady-state or non-steady-state conditions in near-real time, in accordance with embodiments of the disclosure provided herein. In an aspect, the method detects an exchange rate which is an intrinsic metric or an absolute value that is used as a quantitative imaging biomarker to measure the physiological or pathological state of the biological system.

As used herein, “real-time” refers to not having to wait more than 60 minutes for a scan result (e.g., less than about 55 minutes, 50 minutes, about 45 minutes, about 40 minutes, about 35 minutes, about 30 minutes, about 25 minutes, about 20 minutes, about 15 minutes, about 10 minutes, about 5 minutes, about 4 minutes, about 3 minutes, about 2 minutes, about 1 minute, or less than about 50 seconds, about 40 seconds, about 30 seconds, about 20 seconds, about 10 seconds, about 5 seconds, about 4 seconds, about 3 seconds, about 2 seconds, about 1 seconds).

In an aspect, the methods utilize existing MRI devices, existing NMR devices, or new devices that will be developed specifically for this approach to measure the physiological or pathological state in vivo. In an aspect, the method further comprises utilizing modification of existing NMR and MRI pulse sequences and associated methods.

In another aspect, the methods are used on any endogenous molecular species containing nuclei with non-zero spin.

An aspect of the invention provides methods to determine a homeostatic steady-state of a biological entity, the method comprising the use of a magnet, a gradient coil, a radiofrequency probe, a gradient amplifier, a spectrometer, a radiofrequency amplifier, and a computer.

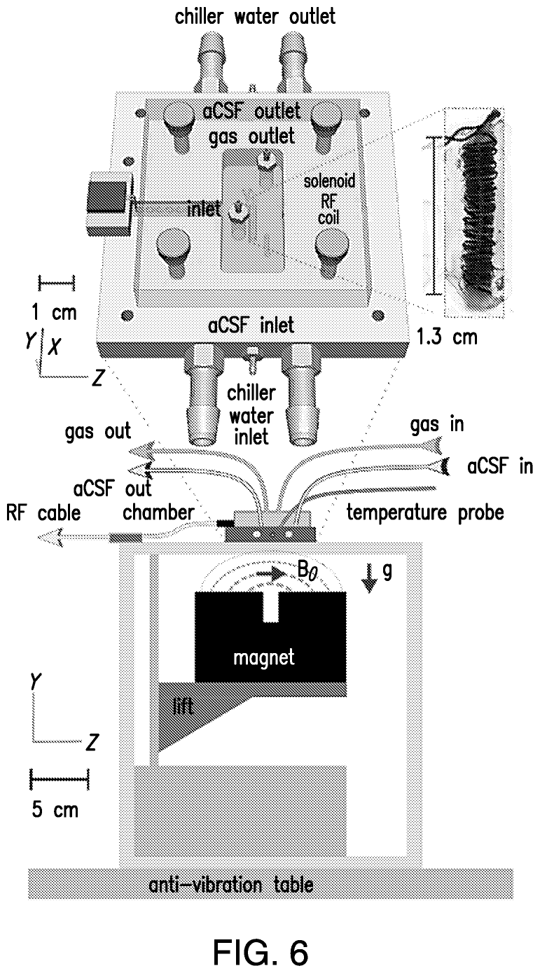

In an aspect, the invention further provides one of more of the following: an antivibration table, a microscope (e.g., an inverted microscope), an objective inverter, a lift, an inlet (e.g., for fluids or gases), an outlet (e.g., for fluids or gases), a temperature probe, radiofrequency cable, and an LED fiberoptic. An aspect of the invention provides an experimental set up according to FIG. 24, and/or FIG. 6, and/or FIG. 33.

In an aspect of the invention, the magnet is used to produce a static gradient in the magnetic field. In another aspect of the invention, the magnet is a single-sided permanent magnet. In a further embodiment, the magnet is a homogeneous magnet.

As used herein, “non-invasive” refers to not having to enter the biological entity with a physical object.

One skilled in the art will be able to determine a homeostatic steady-state of a biological entity by using the methods of an aspect of the invention on a sample size (n>1) of biological entities with a known steady-state. A relatively small range of values could then be used as a “control” to compare future unknown samples to. For example, one skilled in the art could test samples of normal, healthy spinal cord tissue to determine the range for a particular homeostatic steady-state of the normal, healthy tissue. When other samples are tested in the future, values above or below the homeostatic steady-state range of known values would indicate an unhealthy or pathological state of the same type of biological entity.

Aspects, including embodiments, of the subject matter described herein may be beneficial alone or in combination, with one or more other aspects or embodiments. Without limiting the foregoing description, certain non-limiting aspects of the disclosure numbered 1-17 are provided below. As will be apparent to those of skill in the art upon reading this disclosure, each of the individually numbered aspects may be used or combined with any of the preceding or following individually numbered aspects. This is intended to provide support for all such combinations of aspects and is not limited to combinations of aspects explicitly provided below:
(1) A method to determine a homeostatic steady-state of a biological entity.
(2) A method to determine a homeostatic steady-state of a biological entity, the method comprising a magnetic resonance (MR) system, the MR system comprising:
a. a means to create a static or pulsed magnetic field gradient;
b. a means to create a constant magnetic field;
c. a means to hold a biological entity within the constant magnetic field and the static or pulsed magnetic field gradient;
d. a radiofrequency transmitter;
e. a radiofrequency receiver that measures radiofrequency electromagnetic fields;
f. a radiofrequency transmit amplifier;
g. a MR radiofrequency pulse sequence generator that sends signals to the radiofrequency transmit amplifier to acquire Diffusion Exchange Spectroscopy (DEXSY) data;
h. a recording device to sample and store a MR. magnetization signal detected by the radiofrequency receiver; and
i. a mathematical modeling framework to transform the recorded magnetization signal DEXSY data,
wherein interpretation of the DEXSY data provides a homeostatic steady-state of a biological entity.
(3) The method of aspect 2, the method further comprising placing a biological entity in the means to hold the biological entity.
(4) The method of aspect 2 or 3, wherein the MR system is a Nuclear Magnetic Resonance (NMR) system or a Magnetic Resonance Imaging (MRI) system.
(5) The method of any of aspects 1-4, wherein the biological entity is a cell.
(6) The method of any of aspects 1-4, wherein the biological entity is an organelle.
(7) The method of any one of aspects 1-6, wherein the biological entity is living.
(8) A method to quantify an exchange rate between at least two compartments in a biological system.
(9) The method of aspect 8, further comprising a MR system comprising:
a. a means to create a static or pulsed magnetic field gradient;
b. a means to create a constant magnetic field;
c. a means to hold a biological entity within the constant magnetic field and the static or pulsed magnetic field gradient;
d. a radiofrequency transmitter,
e. a radiofrequency receiver that measures radiofrequency electromagnetic fields;
f. a radiofrequency transmit amplifier;
g. a MR radiofrequency pulse sequence generator that sends signals to the radiofrequency transmit amplifier to acquire Diffusion Exchange Spectroscopy (DEXSY) data;
h. a recording device to sample and store a MR magnetization signal detected by the radiofrequency receiver; and
i. a mathematical modeling framework to transform the recorded magnetization signal DEXSY data.
(10) The method of aspect 8 or 9, wherein the exchange rate is used to determine neuroprotectant efficacy.
(11) The method of any one of aspects 8-10, wherein the exchange rate is used to determine a homeostatic steady-state of the biological entity.
(12) The method of aspect 11, wherein the homeostatic non-steady state is a pathological state.
(13) A Nuclear Magnetic Resonance (NMR) method to characterize physiological water transport.
(14) The method of any one of aspects 1-13, wherein the method does not require exogenous contrast agents.
(15) A method for non-invasively measuring transmembrane exchange rates of endogenous water in a biological system under steady-state or non-steady-state conditions in near-real time, in accordance with aspects of the disclosure provided herein.
(16) The method of aspect 15, wherein the method detects an exchange rate which is an intrinsic metric or an absolute value that is used as a quantitative imaging biomarker to measure the physiological or pathological state of the biological system.
(17) The method of aspect 15 or 16, the method utilizing existing MRI devices, existing NMR devices, or new devices that will be developed specifically for this approach to measure the physiological or pathological state in vivo.

The following examples further illustrate the invention but, of course, should not be construed as in any way limiting its scope.

### EXAMPLES

### Example 1

This example demonstrates that the methods of an aspect of the invention noninvasively measure the steady-state exchange of water into and out of live tissue and cells (e.g., spinal cord cells and/or white and grey matter).

Details of the methods used herein can be found in Williamson, et al., Elife, 8: e51101 (2019) and Williamson, et al., Journal of Magnetic Resonance, 37: 106782 (2020), and are described briefly below.

### Sample Preparation and Materials

All experiments were performed on Swiss Webster wild type (Taconic Biosciences, Rensselaer, NY, USA) mice between postnatal day 1 to 4. The mouse spinal cords were isolated and placed in a dissecting chamber perfused with cold low-calcium high magnesium artificial cerebrospinal fluid (aCSF, concentrations in mM: 128.35 NaCl, 4 KCl, 0.5 CaCl₂·2H₂O, 6 MgSO₄·7H₂O, 0.58 NaH₂PO₄·H₂O, 21 NaHCO₃, 30 D-glucose) bubbled with 95% O₂ and 5% CO₂). Live spinal cords were transported in low-calcium, high-magnesium aCSF to the NMR experimental apparatus. Fixed spinal cords were kept overnight in 4% paraformaldehyde at 4° C. and then stored in phosphate buffered saline (PBS) at 4° C., and washed with aCSF three times over the course of two days to remove any residual paraformaldehyde prior to experiments. Experiments on fixed and live spinal cords were performed using normal aCSF (same concentrations as the low-calcium high-magnesium solution except for 1.5 mM CaCl₂·2H₂O and 1 mM MgSO₄·7H₂O).

### Hardware, Setup, and Experimental Conditions

A PM 10 NMR MOUSE single-sided permanent magnet (Eidmann, et al., Journal of Magnetic Resonance, 122: 104-109 (1996)) (Magritek, Aachen Germany) and a Kea 2 spectrometer (Magritek, Wellington, New Zealand) were used to perform NMR experiments at B₀=0.3239 T (proton ω₀=13.79 MHz) and g=5.3 T/m. A test chamber and RF probe were fabricated to maximize SNR and maintain live spinal cord viability. Diagrams of the experimental setup are shown in FIGS. 6 and 33.

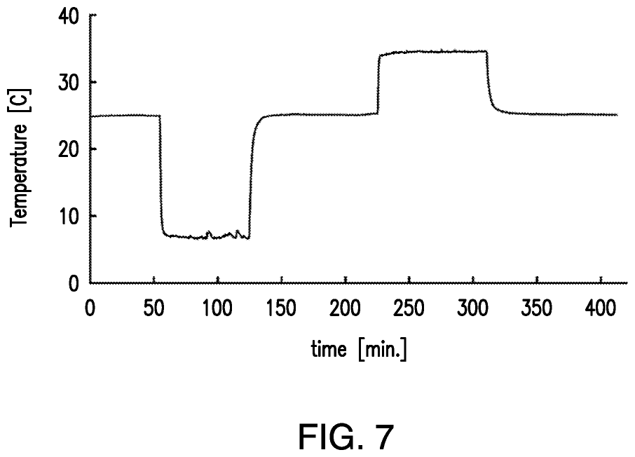

Sample temperature was controlled by heat exchange with one of two circulating water baths (Accel 250 LC, Thermo Scientific, USA, and WCR-P6 Precision Regulated Bath Circulator, Daihan Scientific, Lennox Laboratory supplies, Ireland). The chamber was made in-house out of aluminum to facilitate heat transfer with the water circulating through channels cut through the chamber. Three-way valves located upstream and downstream of the chamber were used to rapidly switch between water baths at different temperatures. While one chiller maintains the sample temperature at a. particular set point, the temperature of the other chiller can be changed and slowly equilibrated. Sample temperature was monitored by a fiber optic sensor (PicoM, Opsens Solutions Inc., Quebec, Canada). After switching temperatures via the three-way valves, the sample temperature equilibrated in roughly 5 minutes and then remained stable±0.5° C. there-after (see e.g., representative temperature log, FIG. 7). NMR measurements were started 10 minutes after the sample temperature stabilized. The temperature was set to 25° C. for experiments where temperature was not varied.

The same experimental conditions were used for live and fixed spinal cords. Humid 95% O₂ and 5% CO₂ gas flowed into the top of the sealed chamber. aCSF was bubbled with 95% O₂ and 5% CO₂. A peristaltic pump circulated aCSF media continuously through the chamber at 2 ml/min.

Oxygen glucose deprivation (OGD) studies involved switching the media inflow between normal aCSF to glucose-free aCSF (made with 30 mM sucrose to keep osmolarity constant) bubbled with 1% O₂, 5% CO₂, and 94% N₂. At the same time, gas flowing into the top of the sealed chamber was switched to humid 1% O₂, 5% CO₂, and 94% N₂.

### NMR Methods

Experimental protocols involved looping through sets of diffusion experiments and rapid DEXSY experiments to acquire repetitions of each. Noise and RF probe tuning were monitored at the beginning of each loop. Experiments used repetition time (TR)=2 s, 2 μs 90°/180° hard RF pulses with amplitudes=−22/−16 dB. Carr-Purcell-Meiboom-Gill (CPMG) acquisition blocks used 2000 or 8000 echoes with 25 μs echo time, 4 μs acquisition time and 0.5 us dwell time (Carr, et al., Physical Review. 94(3): 630 (1954), Meiboom, et al., Review of Scientific Instruments, 29(8): 688-691 (1958)), The static gradient was in the y direction (FIG. 22) and defined the slice and diffusion encoding directions. Signal was acquired from approximately a 400 μm slice through the length of the spinal cord.

Diffusion experiments were performed using a standard sequence involving a spin echo (SE) for diffusion encoding followed by a CPMG signal acquisition (Rata, et al., Journal of Magnetic Resonance, 180(2): 229-235 (2006). τ (defined as half the SE echo time) was varied linearly from 0.05 to 3.3 ms over 22 steps with 4 scans per τ. This corresponds to b-values ranging from 0.001 to 400 ms/μm² where b=2/3γ²g²τ³ (Carr, et al., Physical Review, 94(3): 630 (954), Hahn, Physical Review, 80(4): 580 (1950)). Points two through four (τ=0.2048 to 0.5143 ms, b=0.096 to 1.5 ms/μm²) of diffusion data were fit with I(b)=I₀ exp(−b ADC) to estimate the Apparent Diffusion Coefficient and I₀. For measurements on spinal cords, the term ADCy is used, acknowledging that diffusion may be anisotropic but was measured only in the y direction, perpendicular to the cord.

Points 12 through 22 were fit with a model for diffusion within cylindrical restrictions oriented perpendicular to the gradient direction with a constant gradient (Neuman, The Journal of Chemical Physics, 60(11): 4508-4511 (1974), Grebenkov, Reviews of Modern Physics, 79(3): 1077 (2007)) and incorporating exchange (Canton, et al., Journal of Magnetic Resonance, 143(1): 24-29 (2000),

$$I ( τ ) = f exp [ - ( \frac{7}{96} \frac{{r}^{4} {γ}^{2} {g}^{2}}{{D}_{0}} + k ) 2 τ ] , \qquad ( 1 )$$

to estimate the restriction radius r and the restricted fraction f. Each estimate incorporated k measured from the rapid exchange experiment during the same set. Rapid exchange experiments were performed using a DEXSY sequence involving two spin echoes separated by a mixing time tin and a CPMG acquisition (Williamson, et al., Elife, 8: e51101 (2019)) and following Method 3 in Williamson, et al., Journal of Magnetic Resonance, 317: 106782 (2020). The sequence used 8 phase cycle steps to avoid unwanted. coherence transfer pathways (Williamson, et al., Elife, 8: e51101 (2019). For experiments involving temperature perturbations, DEXSY data points were acquired with (τ₁, τ₂) combinations (0.200, 0.213), (0.200, 0735), (0.593, 0.580), and (0.735, 0.200) ms, corresponding to (b₁, b₂)=(0.089, 0.1080), (0.089, 4.417), (2.320, 2.170), and (4.417, 0.089) ms/μm². For all other experiments, combinations (0.200, 0.213) and (0.735, 0.200) were omitted due to the findings from Williamson, et al., Journal of Magnetic Resonance, 317: 106782 (2020) that these points are redundant. Each (τ₁, τ₂) combination was acquired with 8 scans and with tₘ=[0.2, 1, 2, 4, 7, 10, 20, 40, 80, 160, 300] ms. The signal from (τ₁, τ₂)=(0.200, 0.735) and (0.735, 0.200) was averaged and fit with I(tₘ)=I₀ exp(−tmR_{1 DW}) to estimate R_{1 DW}. The same signal was also tit with

$$I ( {t}_{m} ) = {I}_{0} ( {w}_{1} exp ( - {t}_{m} {R}_{1 DW}^{1} ) + ( 1 - {w}_{1} ) exp ( - {t}_{m} {R}_{1 DW}^{2} ) .$$

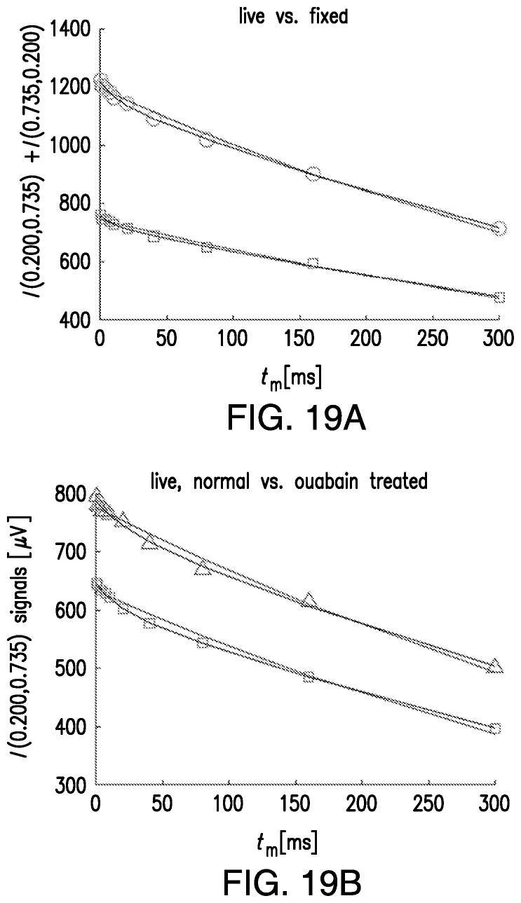

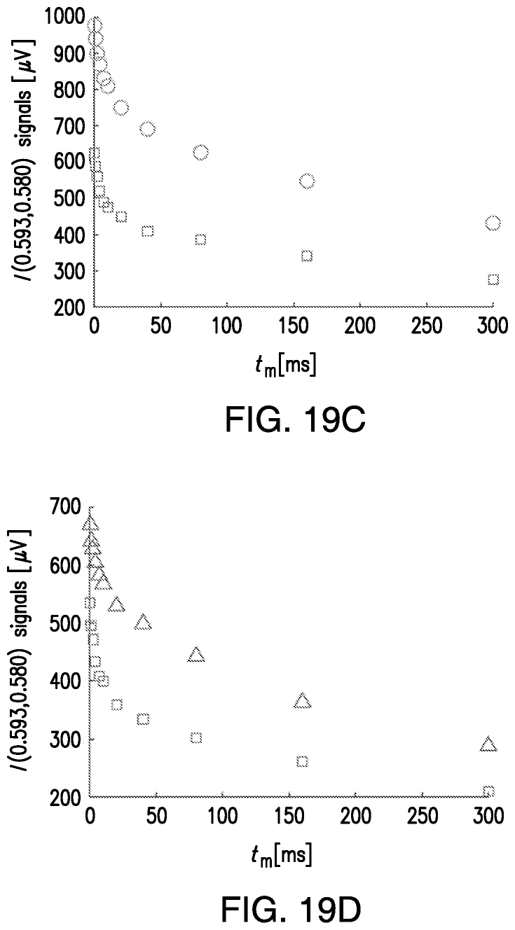

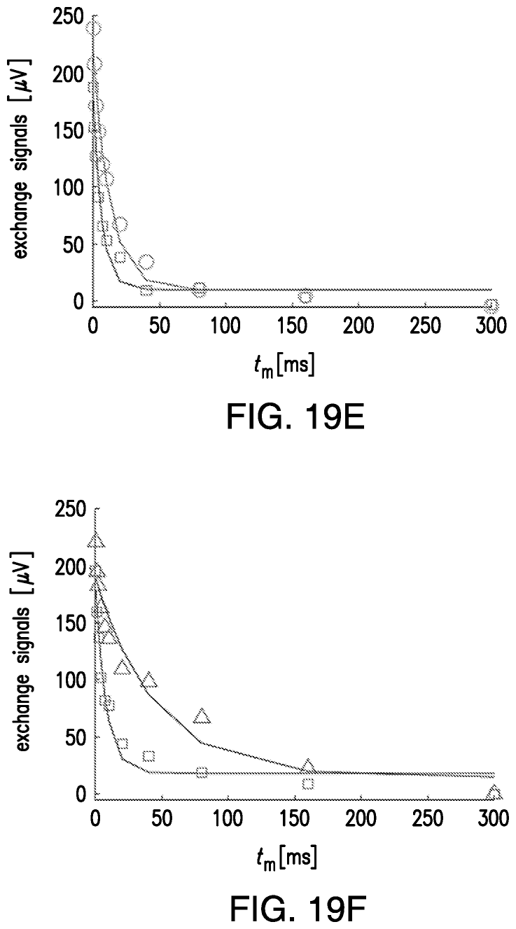

The resulting model was subtracted from the signal from (τ₁, τ₂)=(6.593; 0.580) and the signal was fit with I(tₘ)=I₀ exp(−tmk)+B to estimate k. Representative data and fits are shown in FIG. 19.

Saturation recovery experiments were performed during the OGD study to measure R₁ as a means of monitoring pO₂ changes. Experiments used 6 recovery times exponentially spaced between 0.067 and 6 ms. Sensitivity of R₁ to pO₂ was confirmed with measurements on pure aCSF, circulating through the chamber and bubbled with 1% or 95% O₂ gas, and was also used to determine the gas flow/bubbling rate sufficient to reach O₂ saturation.

An Arrhenius model of the form fₙ(T⁻¹)=A exp(−Ea/RT), where R=8.3145×10⁻³ kJ/(mol K) is the ideal gas constant, was fit to measurements of k, T₁, or ADCy as a function of the inverse of the absolute temperature T⁻¹ to estimate activation energies (Ea) associated with each metric for each sample.

### Statistical Methods

Data was analyzed using MATLAB R2020a. Experimental results involving many measurements are presented as box and whisker plots and violin plots in order to provide a full sense of the structure and variability of the measured data. Box plots show the median (middle line), the 25^{th} percentile (bottom line), and the 75^{th} percentile (top line). Notches in the box plot show the 95% confidence interval (CI) of the median. (Note that the notches sometimes extend further than the 25^{th} or 75^{th} percentiles.) Violin plots show a smooth probability density function (pdf) for the distribution of measured values. Means, standard deviations, and 95% CIs are used in other cases, as noted in figure captions. Both 95% CIs of the median and two-sample (unpaired) t-tests assuming equal variance (a=0.05) are used for hypothesis testing between sample groups. Pearson correlations were analyzed using the MATLAB corrcoef function to estimate correlation coefficients and p-values. Cross-correlations were analyzed using the MATLAB xcorr function to estimate the time lag between effects in simultaneously acquired real-time data.

### Exchange Rates are Linked to the Non-Equilibrium Metabolic Activity in Live Tissue

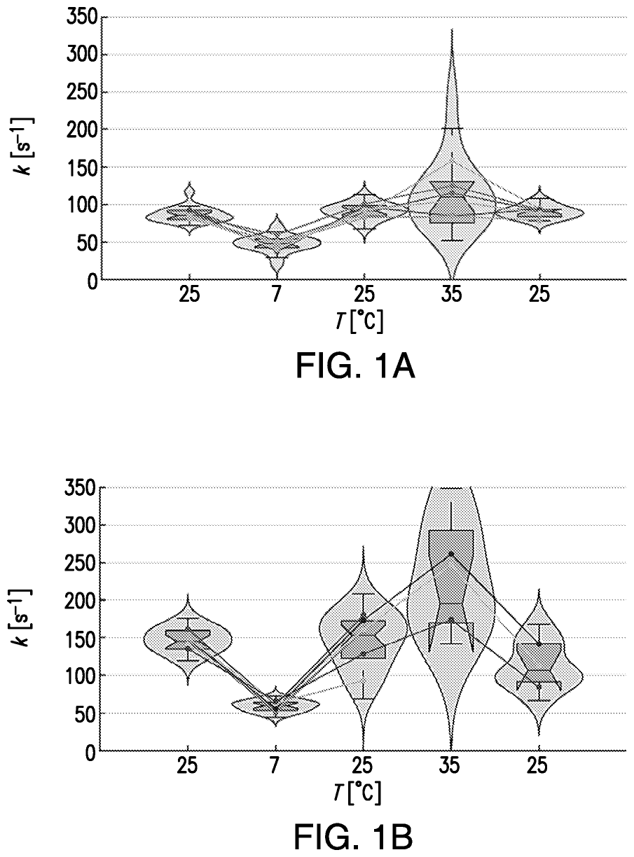

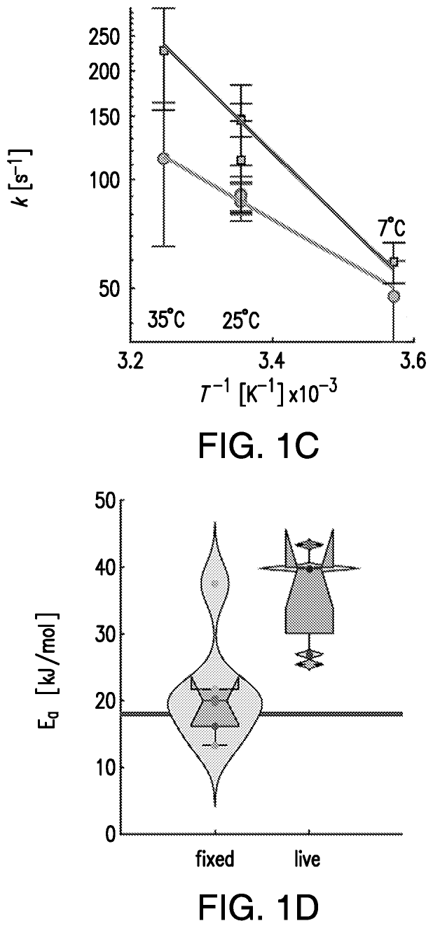

Exchange rates were measured in real-time on n=6 fixed and n=7 live ex viva neonatal mouse spinal cords undergoing step changes in temperature: 25→7→25→35→25° C. (FIGS. 1A and 1B). Four of the seven live samples only underwent the first 25→7→25° C. portion of the temperature variation protocol because holding the system at 35° C. for 40 minutes of measurements was challenging for the spinal cord specimen and caused the exchange rate to run down, indicative of reduced tissue viability. Temperature changes had a greater effect on the exchange rate for live samples than for fixed ones. At 7° C., exchange rates were similar between live and fixed samples whereas at 25° C. and 35° C., exchange rates were greater for live than for fixed samples.

The 25° C. condition was repeated in a “test/re-test” manner to check that samples recovered from being subjected to 7° C. and 35° C. Exchange rates for fixed samples consistently returned to the same values during the 2^{nd} and 3^{rd} 25° C. In contrast, live samples showed decreased exchange rates at the 3^{rd} 25° C. due to rundown during the 35° C. condition.

An Arrhenius plot of the exchange rates vs. the inverse absolute temperature is shown in FIG. 1C. The slope of the logarithm of k vs. T⁻¹ is proportional to the activation energy (Ea). The slope is steeper (i.e., Ea is greater) for live spinal cords than for fixed spinal cords. Ea values for each sample were estimated by fitting the data with an Arrhenius model, k=A exp(−Ea/RT) where A is a prefactor, R is the ideal gas constant, and Tis the absolute temperature. Ea estimates are compared between fixed and live samples in FIG. 1D. For fixed spinal cords, the Ea is similar to the La for self-diffusion of pure water (Mills, Journal of Physical Chemistry, 77(5): 685-688 (1973)). This affirms that exchange in fixed tissue is driven by equilibrium thermal energy and mediated by passive water permeability through openings, such as pores or channels in the membrane (Verkman, The Journal of Membrane Biology, 173(2): 73-87 (2000)). In comparison, Ea for live spinal cords is significantly greater than the value for fixed ones. Exchange rate rundown at 35° C. leads to Fa of live tissue being underestimated. Therefore, water exchange in live tissue is not only driven by thermal energy—it must also be driven by non-equilibrium active processes.

### Apparent Diffusion Coefficients are Sensitive to Tissue Microstructure but not Activity

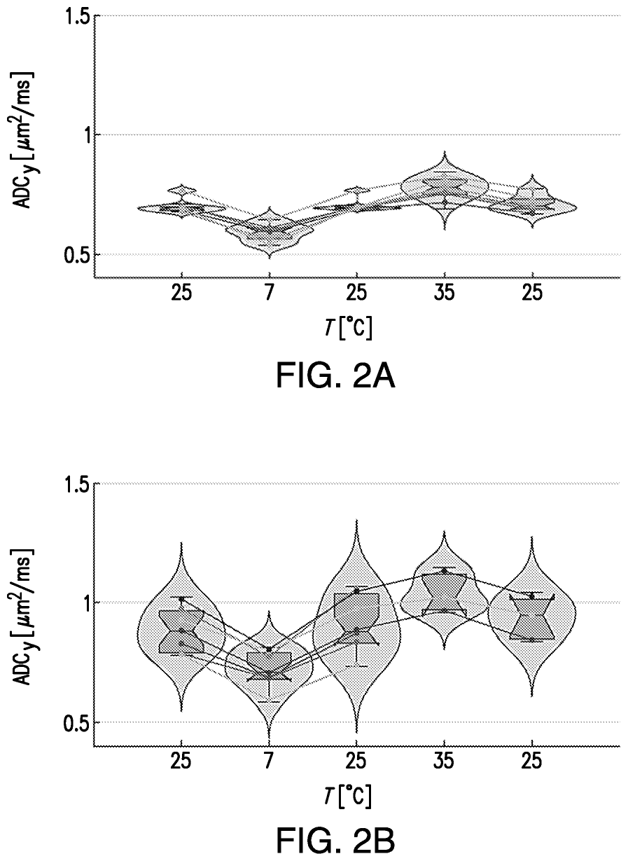

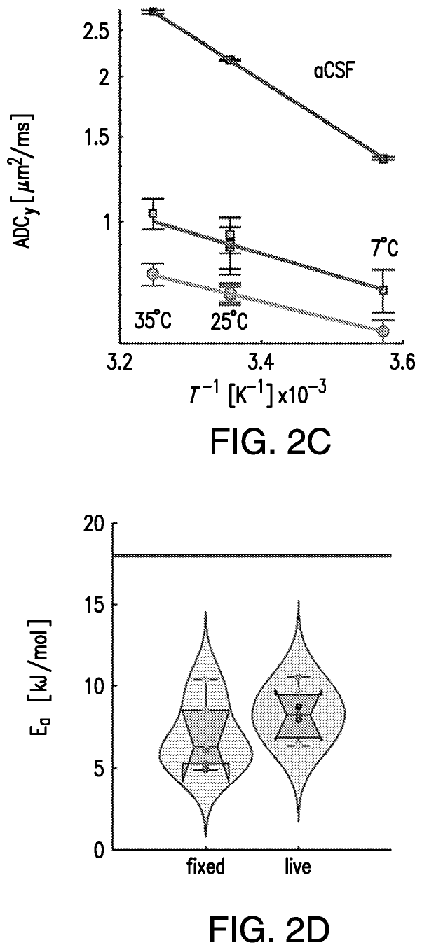

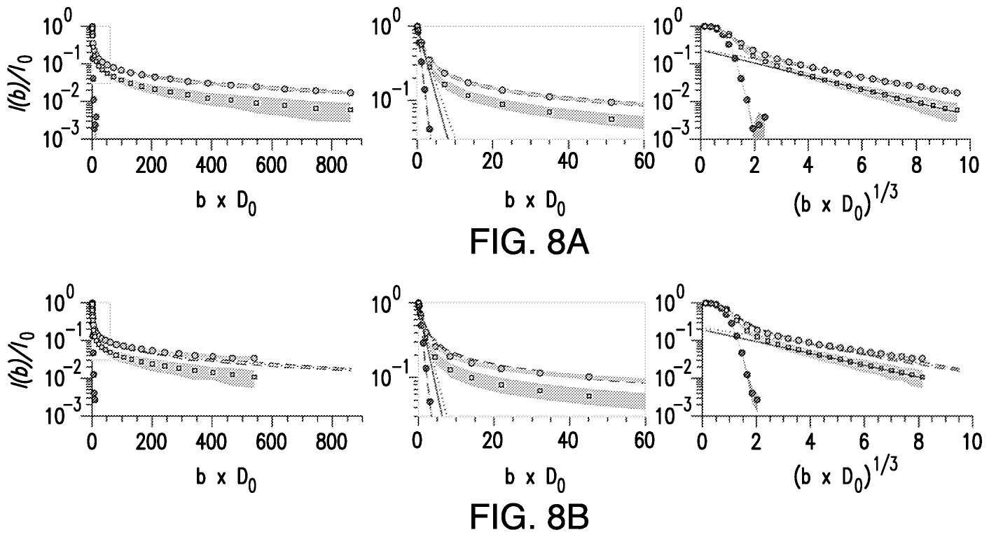

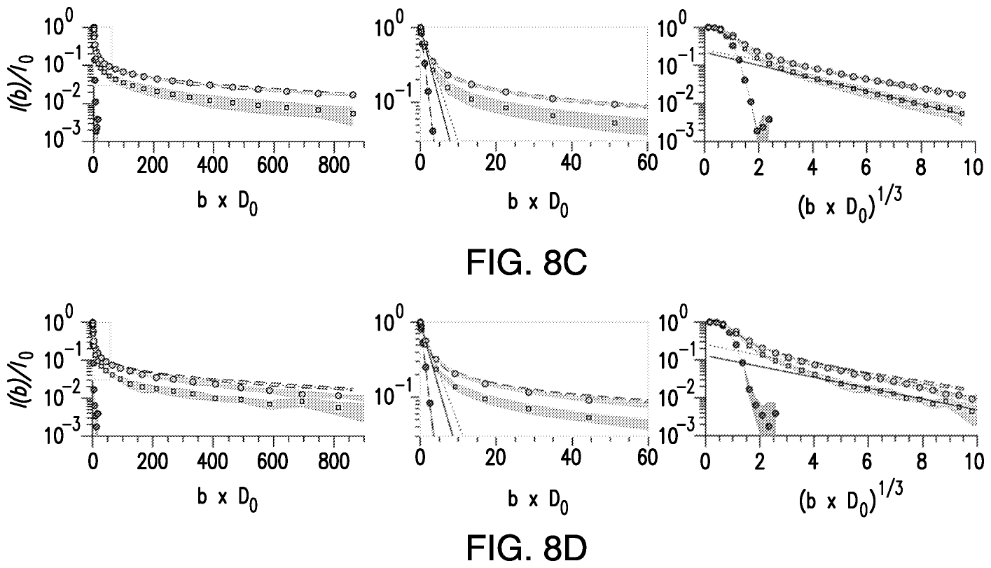

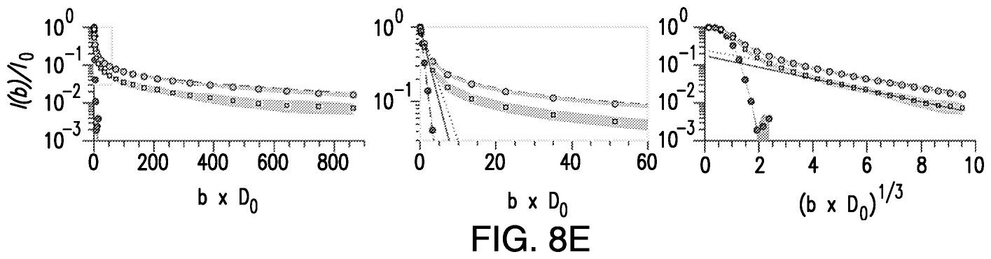

Water diffusion in the y-direction, perpendicular to the orientation of the spinal cord, was also measured in real-time on the n=6 fixed and n=7 live spinal cords at 25°, 7°, 25°, 35°, and 25° C. Raw signals are shown in FIG. 8. Apparent Diffusion Coefficients (ADCy) were estimated from the initial signal decay (b=0.096 to 1.5 ms/μm²). ADCy consistently recovered upon returning to 25° C. (FIGS. 2A and 2B), including for live spinal cords at the 3^{rd} 25° C. which showed decreased exchange rates due to rundown after the 35° C. condition. ADCy values for fixed spinal cords are significantly less than for live spinal cords (FIG. 2C).

Diffusion coefficients of pure artificial cerebrospinal fluid (aCSF show an Arrhenius temperature dependence consistent with literature reports for pure water (Mills, Journal of Physical Chemistry, 77(5): 685-688 (1973)) (FIGS. 2C and 2D). Water in aCSF diffuses freely (unimpeded by restriction of membranes) such that the thermal energy translates directly to increased mean-squared displacements. ADCy of fixed and live spinal cords were less affected by temperature. This is because water experiences more interactions with membranes as the temperature increases, retarding it and keeping the ADCy from increasing as much as it would if it were free. This affirms that ADCy probes hindrances and restrictions imposed by tissue microstructure. Ea of ADC_{y} for live and fixed spinal cords are not significantly different. Therefore, the measured ADC is insensitive to non-equilibrium metabolic activity.

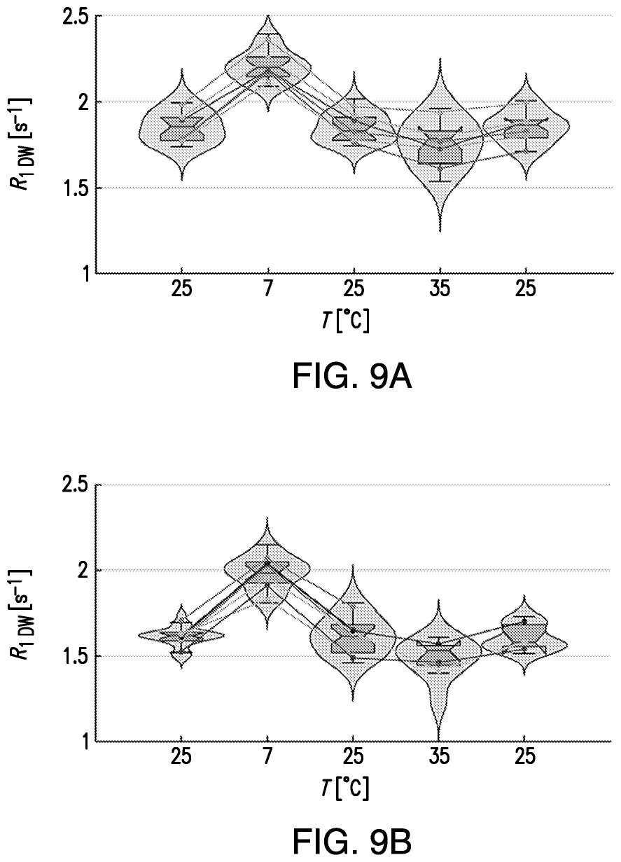

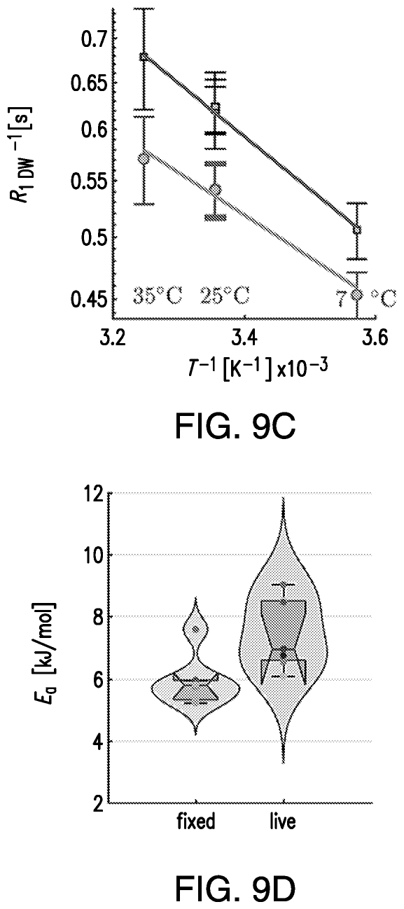

In addition to exchange rates, DEXSY experiments also provide diffusion-weighted spin-lattice relaxation rates (R_{1 DW}). R₁ is the reciprocal of T₁ and is inversely related to its rotational mobility (Hindman, et al., The Journal of Chemical Physics, 59(3): 1517-1522 (1973)). Higher temperature increases rotational mobility and decreases R₁. The strong diffusion weighting (b=4.5 ms/μm²) filters out signal based on translational mobility such that R_{1 DW} is associated with water which is more hindered and restricted by membranes within the tissue. R_{1 DW} for fixed spinal cords is higher than for live spinal cords (FIG. 9). R_{1 DW} recovered for fixed and live spinal cords when returned to 25° C. after 7° C. and 35° C. Ea of R_{1 DW}⁻¹ for live spinal cords are greater than for fixed spinal cords when based on a t-test (p<0.05) but are not significantly different when based on the 95% confidence interval (CI) of median values (FIGS. 9C and 9D).

### Active Water Exchange is Linked to Ion Transport

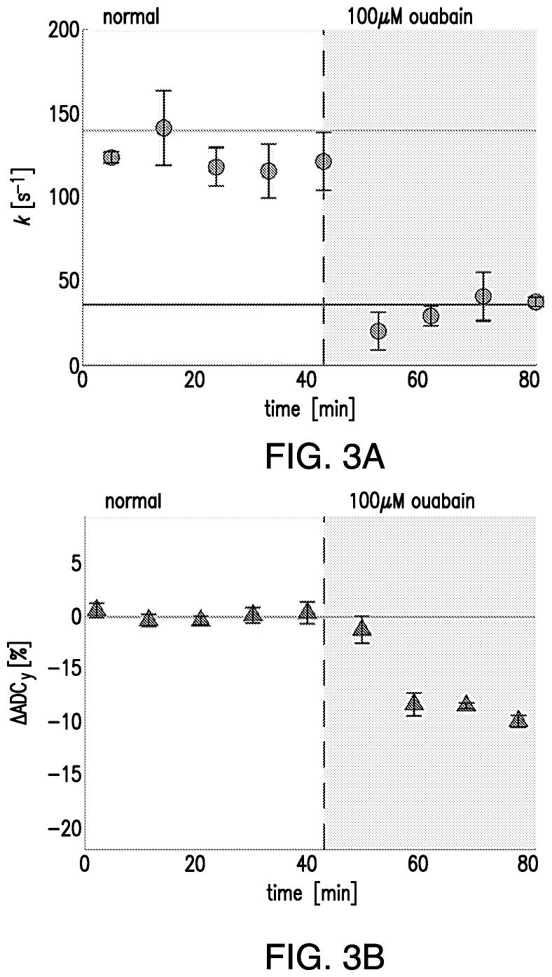

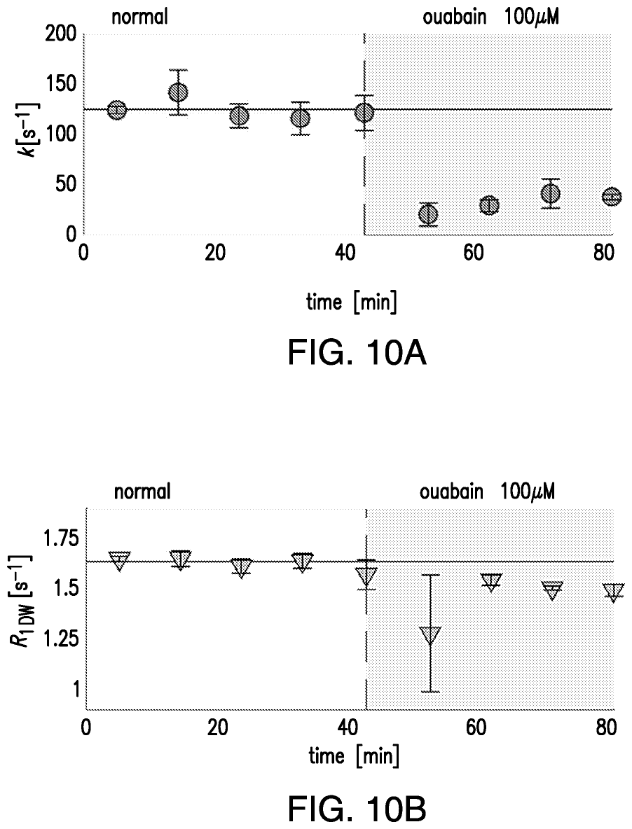

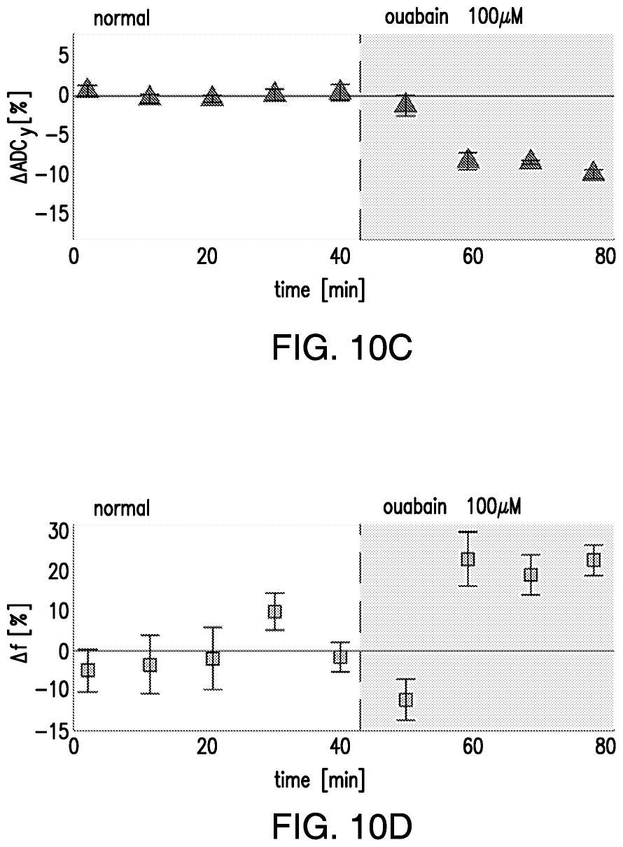

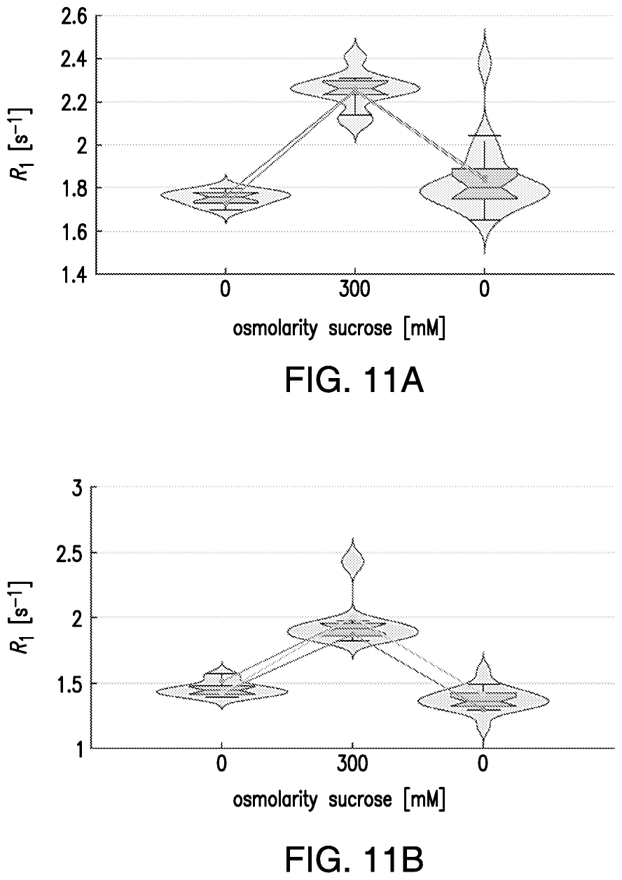

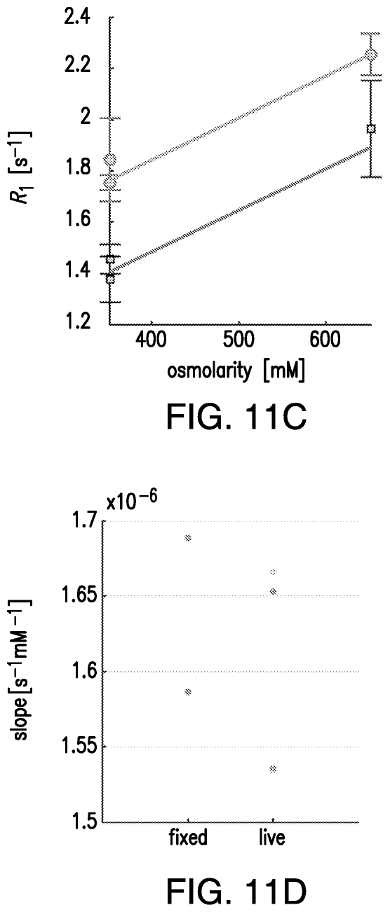

While a comparison of Ea values between live and fixed tissue indicates that water exchange is linked to active cellular processes, it does not reveal a link to specific enzymes or specific cellular processes. The role of Na⁺/K⁺-ATPase was tested by measuring water exchange in real-time during the addition of 100 μM ouabain on n=3 spinal cords (FIG. 3). 100 μM ouabain is expected to reduce Na⁺/K⁺-ATPase activity by 65% and the effect increases by only 6% at higher doses (Marks, et al., Life Sciences, 23(27-28): 2735-2744 (1978), Sweadner, Biochimica et Biophysica Acta (BB)-Reviews on Biomembranes, 988(2): 185-220 (1989)). 100 μM ouabain took effect roughly 10 minutes after treatment. The exchange rate dropped by 7±8%, indicating that the majority of water exchange is linked to ion transport. The apparent diffusion coefficient decreased by 9±1%, and restricted water fraction (f) increased by 22±6% (see FIG. 10), consistent with cells swelling due to a net influx of ions and water (Benveniste, et al., Stroke, 23(5): 746-754 (1992)).

### Stroke Model Suggests Water Exchange Rates Measure Tissue Viability

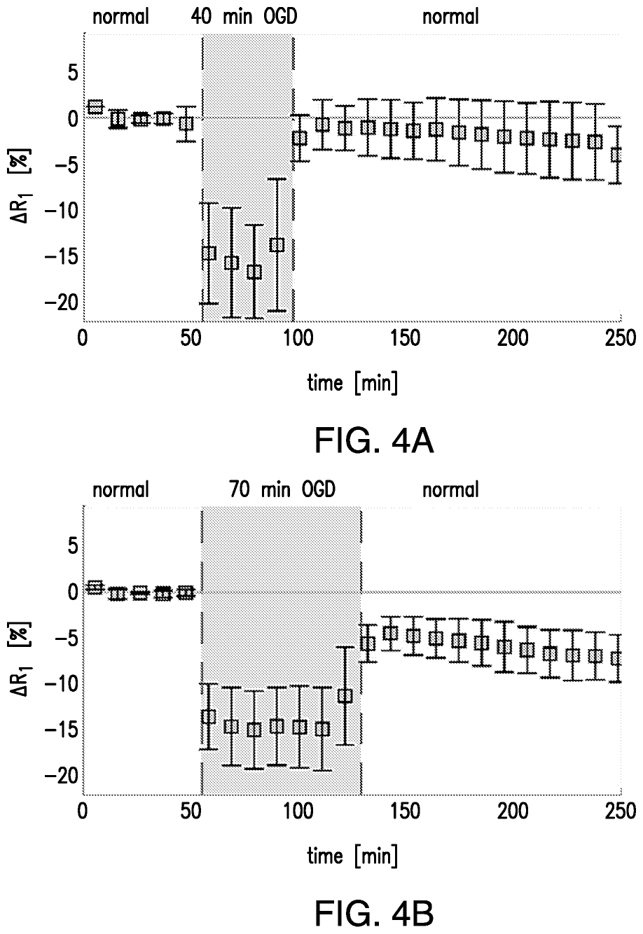

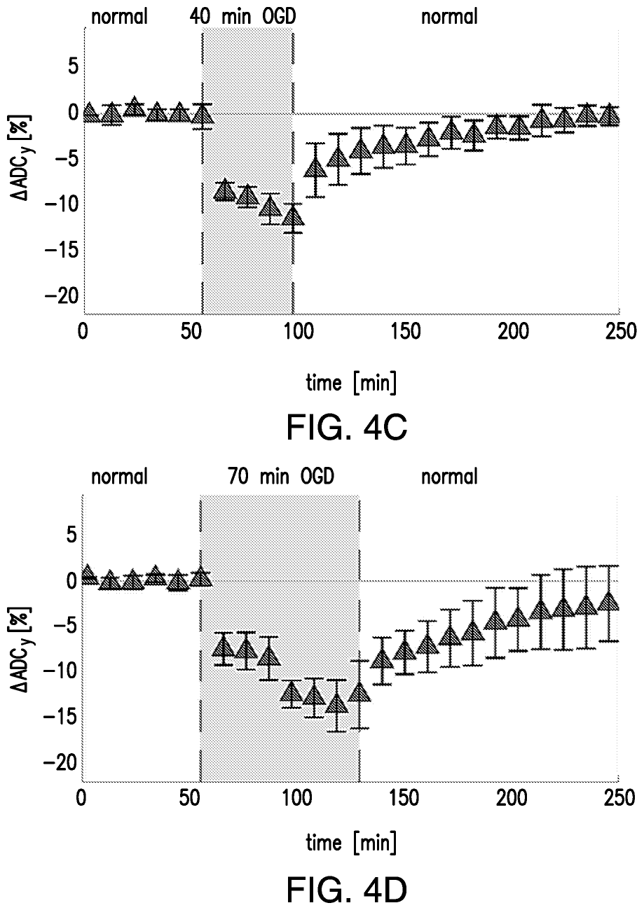

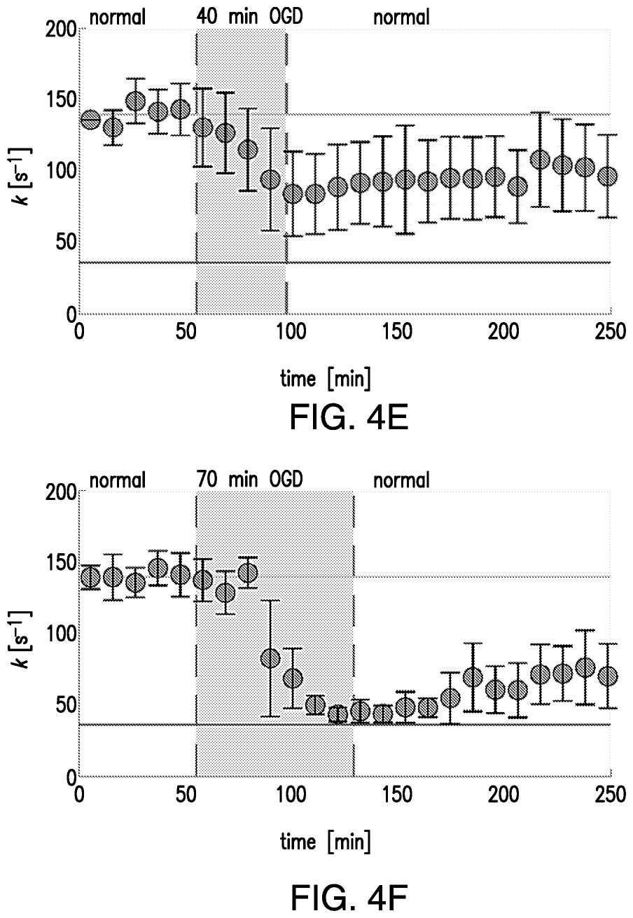

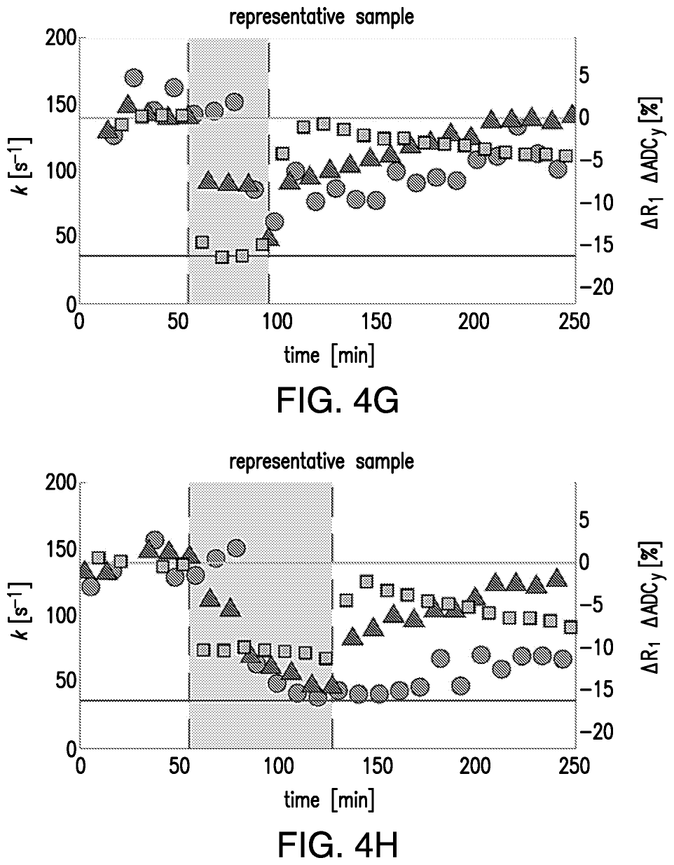

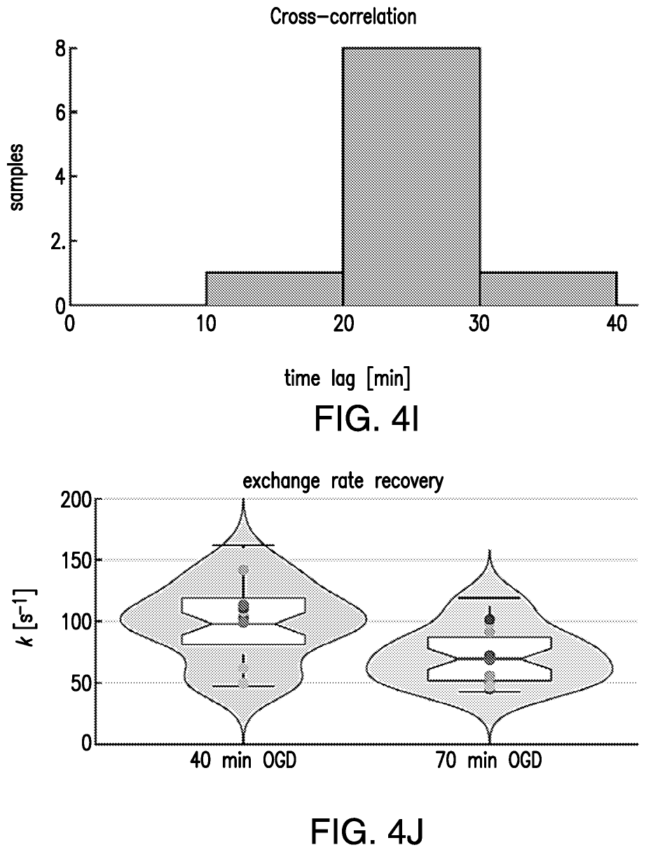

Cellular damage during stroke is linked to the duration of hypoxia or hypoglycemia. The potential that the exchange rate could be used to monitor reduced tissue viability as a result of stroke was investigated by comparing the effect of a shorter 40 min (n=8, FIGS. 4A, 4C, and 4E) and a longer 70 min (n=9, FIGS. 4B, 4D, and 4F) oxygen-glucose deprivation (OGD) model.

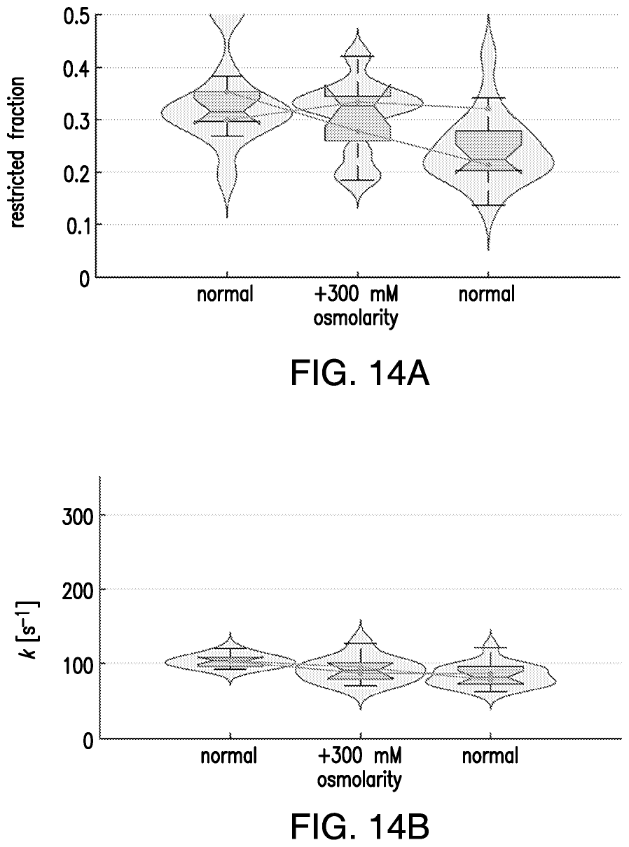

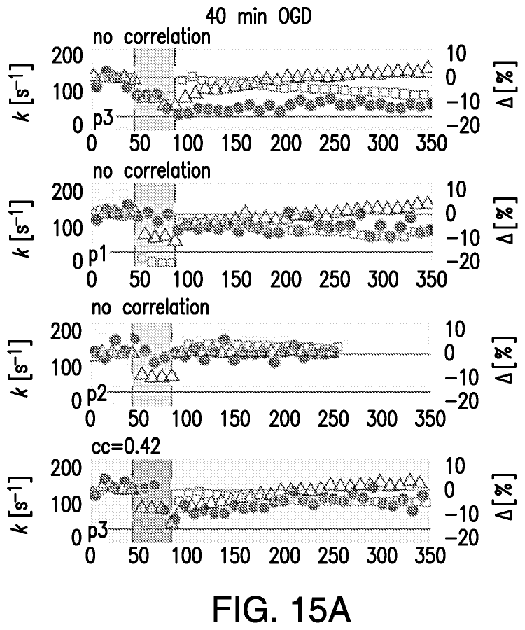

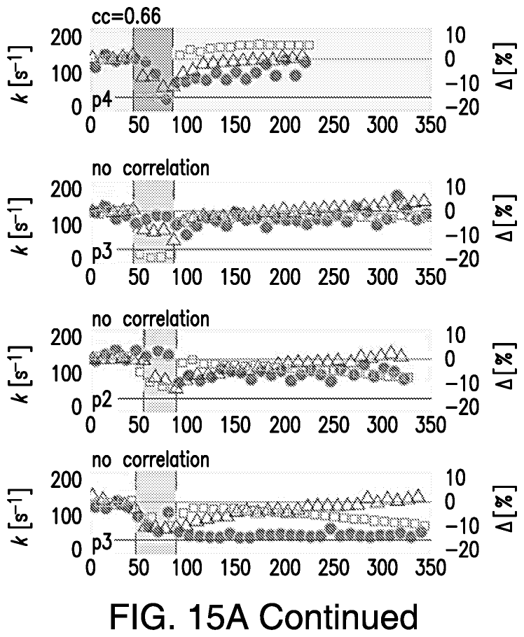

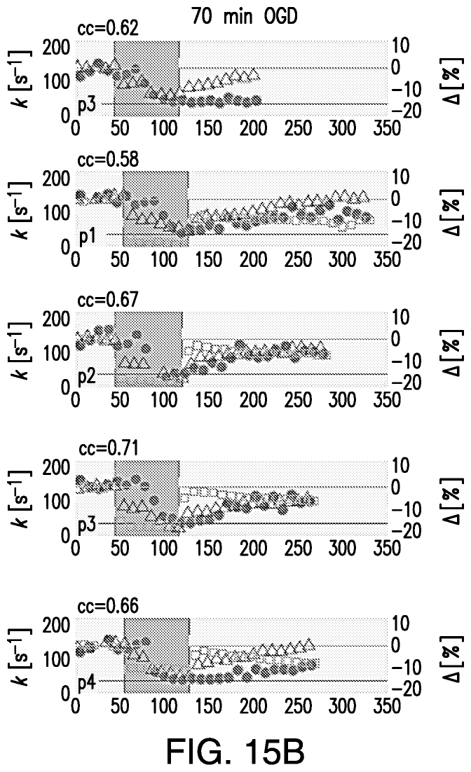

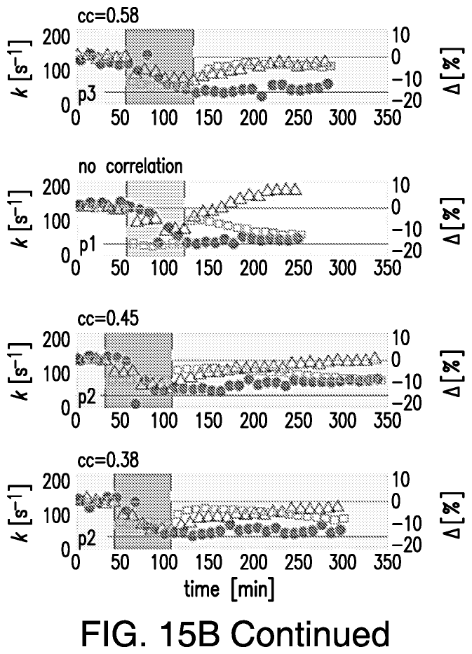

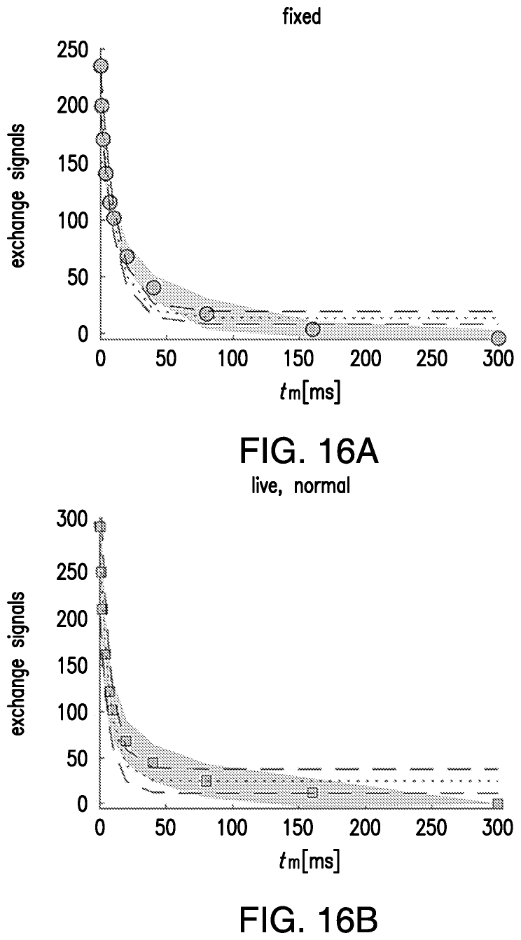

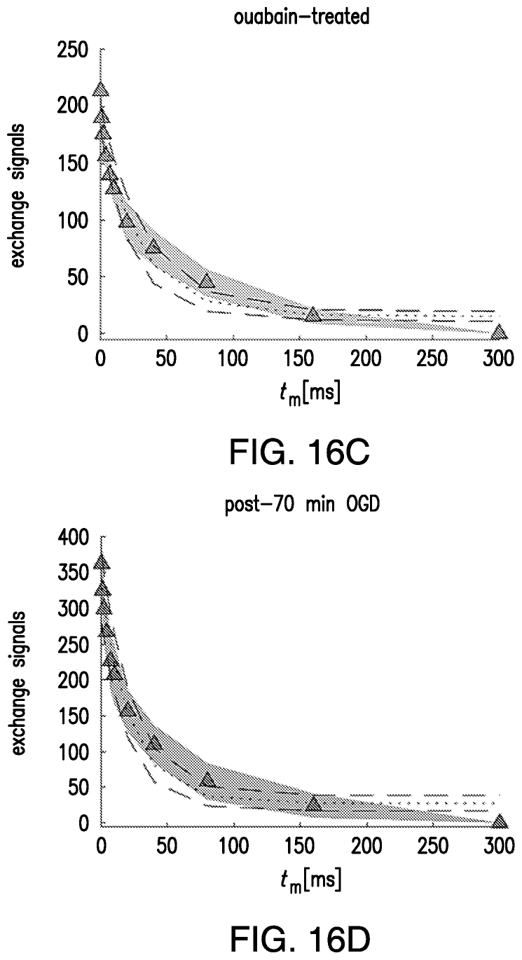

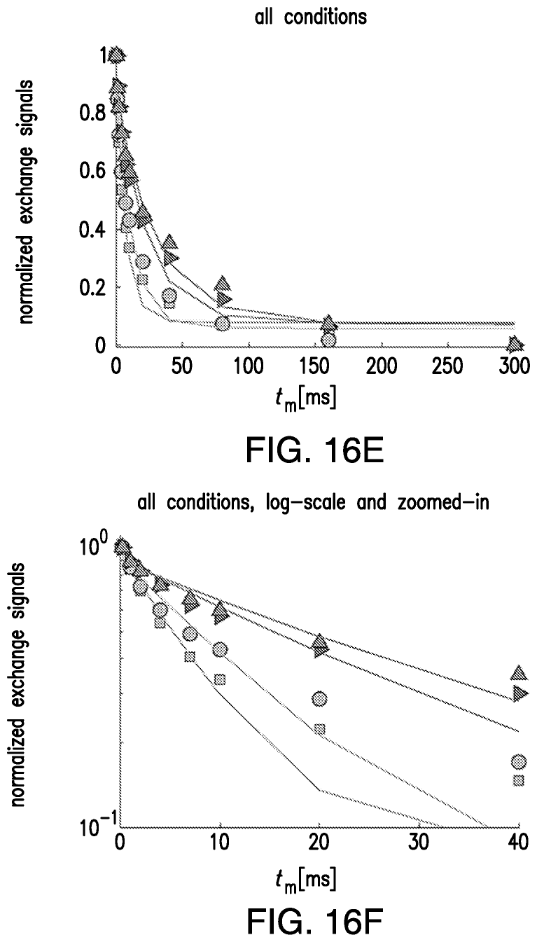

For all samples, pO₂ reduced quickly after the switch and recovered when washing back, confirmed by monitoring R₁ (FIGS. 4A and 4B). ADCy first dropped within 10 minutes of the switch to OGD and dropped a second time after roughly 30-40 minutes (FIGS. 4C and 4D). After switching back to normal aCSF, ADCy increased slightly within 10 minutes and slowly recovered to baseline over the next two to three hours. In some cases, the ADCy increased above baseline (see examples in FIG. 14). The exchange rate behaved differently from ADCy. After switching to OGD, the exchange rate first dropped after roughly 30-40 minutes (FIGS. 4E and 4F). In the 40 minute protocol, the samples were switched back to normal aCSF while the exchange rate was still dropping, rescuing some (but not all) of the samples and preventing their exchange rate from decreasing further. In the 70 minute protocol, the switch back to normal aCSF came after the exchange rate fully dropped. Exchange rates at the end of the 70 minute OGD condition were similar to exchange rates measured on ouabain-treated samples. The standard deviations are smallest at this point, perhaps because all samples were inactive, i.e., had reached complete energetic failure. After returning back to normal aCSF, samples recovered only slightly, if at all, and never back to baseline.

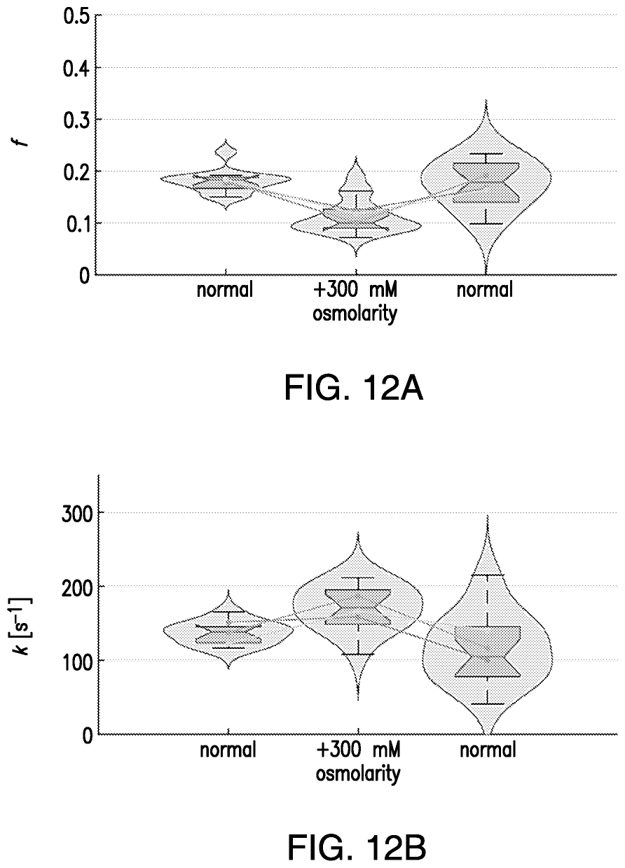

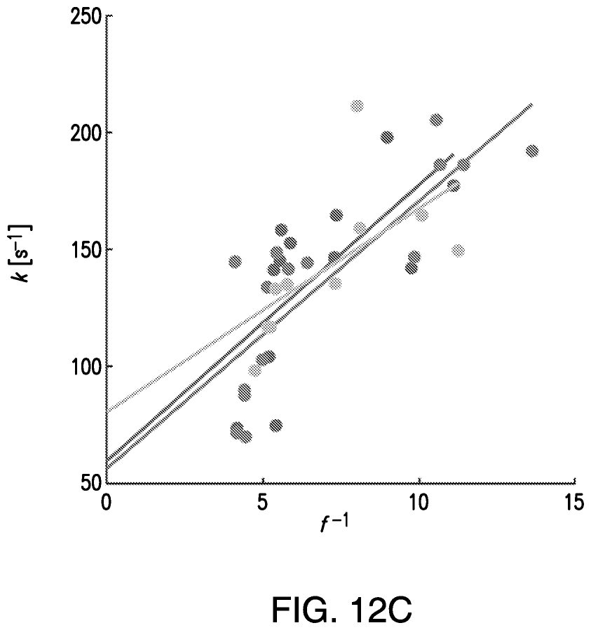

For a passive system it is expected that the ADC and exchange rate will be correlated through changes in cell volume (see FIG. 12). However, in light of active exchange, the ADC and the exchange rate may not necessarily be correlated and may be linked to system characteristics which are independently regulated. It was found that the ADCy and the exchange rate are significantly correlated for only 10 out of 17 samples (p<0.05, FIG. 14). The correlation originates from the second drop of ADCy aligning with the only drop of exchange rate. The first drop of ADCy occurs while exchange rate is unaffected. A cross-correlation analysis confirmed that the exchange rate was first affected 20 to 30 minutes after the ADCy first dropped (FIG. 4I). When washing back to normal aCSF, ADCy recovered to (or overshot) baseline whereas exchange rates did not. Therefore, ADC and exchange rate are not necessarily correlated and must provide independent information. Exchange rates averaged over the period 40-70 min after switching back to normal aCSF were significantly higher for the 40 min protocol than for the 70 minute protocol (FIG. 4J), suggesting that the exchange rate is a measure of tissue viability.

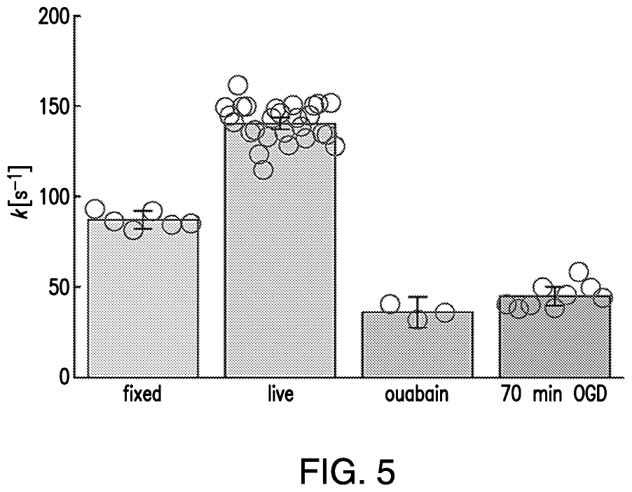

Fixed tissue is at equilibrium and exchange is entirely passive (ka=0). Live tissue maintains a non-equilibrium steady-state under which exchange is assumed to be a summation of parallel passive and active components k=kp+ka. Ouabain causes transmembrane ionic gradients to depolarize, bringing the live tissue closer to equilibrium and the overall active transport closer to zero. If ka is assumed to be zero in ouabain-treated spinal cords, after membranes have depolarized, and surface-to-volume ratios to be similar, then kp and ka can be assessed from comparisons between treatment groups (FIG. 5). It was found that fixation increases passive membrane permeability by 240% by comparing fixed to ouabain-treated spinal cords. It was found that the exchange rate under normal conditions is approximately 30% passive and 70% active by comparing normal (untreated) to ouabain-treated live spinal cords. OGD of sufficient duration causes energetic failure, akin to an equilibrium state. Exchange rates after 70 min OGD were similar to exchange rates after ouabain treatment. This is likely because both treatments bring the system to a steady-state activity level close to equilibrium.

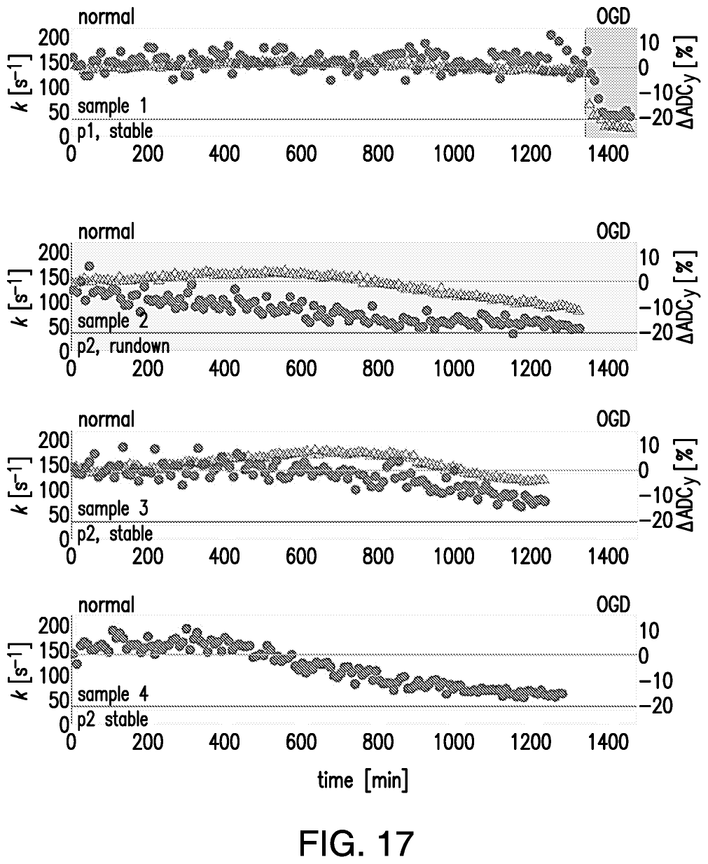

It is important to emphasize that the exchange rate is an absolute, intrinsic measurement. It was found across 27 samples that the normative exchange rate lies within a well-defined range: 140±16 s⁻¹ (FIG. 5). Similar variability is found from repeated measurements on individual samples, e.g, 153±17 s⁻¹ (FIG. 17). On n=4 samples, exchange rates were recorded for many hours under normal conditions. Three of the samples started with exchange rates within the normal range and showed stability for between 8 and 20 hours. One of the samples started with exchange rates below the normal range and continued to run down. In all cases, when exchange rates fell below the normal range, exchange rates ran down, plateauing at values just above the exchange rates measured on ouabain-treated samples. This further suggests that the exchange rate is a reliable measure of tissue viability.

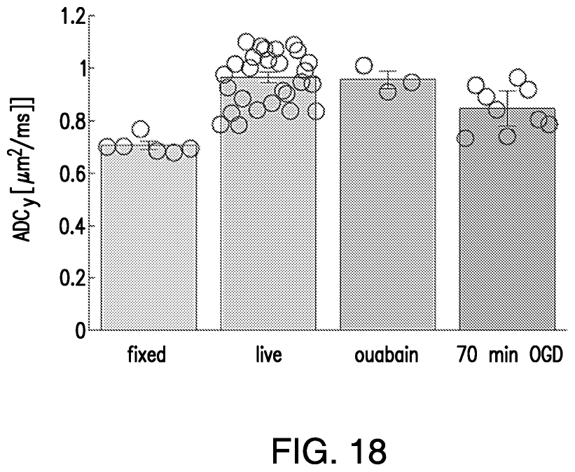

In contrast, ADC_{y} is a relative measurement (e.g., as a percent change from baseline), not an absolute measurement. Variability of normative ADC_{y} values is greater across samples than within individual samples (0.964±0.097,μm²/ms compared to, e.g., 1.0171±0.013 μm² ms from FIGS. 18 and 17, respectively), masking the relative effects of perturbations observed in real-time. It was found that ADC_{y live}≈ADC_{y ouabain}>ADC_{y 70 min OGD}>ADC_{y fixed} (FIG. 18, unlike FIG. 5). Unlike exchange rates, ADC_{y} values do not differentiate treatment groups based on activity and viability. Instead, results affirm that ADC_{y} values differentiate treatment groups based on shifts in extracellular to intracellular water (Benveniste, et al., Stroke, 23(5):746-754 (1992).

The method of an aspect of the invention measures intra- and extra-cellular water pools turning over faster than 100 times their volume per second in live CNS tissue. Prior to the finding on ex vivo fixed spinal cords (Williamson, et al., Elife, 8: e51101 (2019)), there were no reliable measurements of transcytolemmal exchange rates this fast in biological systems. Perhaps this is because low-field, high-gradient DEXSY is the first method capable of reliably measuring diffusive exchange in and out of water pools restricted on length scales smaller than a micron (Cai, et al., Frontiers in Physics, 10: 805793, doi: 10.3389/fphy.2022.805793 (2022)). Large membrane surface-to-volume (SV) ratios, in combination with high levels of active exchange, leads to the high turnover rates. The neonatal mouse spinal cord consists mostly of gray matter and little myelinated white matter (Henry, et al., Mammalian Genome, 23(9-10): 539-549 (2012), Sengul, et al., The Anatomical Record: Advances in Integrative Anatomy and Evolutionary Biology, 295(5): 837-845 (2012)). These sub-micron membrane structures are likely glial and neuronal processes (i.e., neurites), which make up 80-90% of the gray matter tissue by volume (Jelescu, et al., NeuroImage, 256: 119277 (2022)), and may also include organelles (Williamson, et al., Elife, 8: e51101 (2019). Discrepancy from previously reported values, e.g., reports of exchange rates between 1 and 10 s⁻¹ (Nilsson, et al., Magnetic Resonance in Medicine, 69(6): 1572-1580 (2013), Quirk, et al., Magnetic Resonance in Medicine: An Official Journal of the International Society for Magnetic Resonance in Medicine, 30(3): 493-499 (2003), Yang, et al., Magnetic Resonance in Medicine, 79(3): 1616-1627 (2018)), can be explained by other methods being sensitive to slowly exchanging water pools associated with larger or less permeable membrane structures, e.g., cell bodies (i.e., soma), and myelinated axons but insensitive to rapidly exchanging pools. Confirming this belief, recent effort to develop models for PFG diffusion MRI of gray matter have found it necessary to account for exchange occurring during the diffusion encoding time, and with rates≥100 s⁻¹ (Jelescu, et al., NeuroImage, 256: 119277 (2022), Lee, et al., Neuroimage, 222: 117054 (2020), Jelescu, et al., Journal of Neuroscience Methods, 344: 108861 (2020), Veraart, et al., Elife, 9: e49855 (2020), Olesen, et al., NeuroImage, 251: 118976 (2022)). The highest exchange rates measured were 228±72 s⁻¹ for normal samples at 35° C. Exchange rates could be even greater at 37° C. in viva as this is the most viable condition for the tissue. It was found that viability was difficult to maintain at 35° C. For this reason, electrophysiologists typically study the neonatal mouse spinal cord at room temperature around 25° C. (Wilson, et al., Neuroscience, 117(1): 183-196 (2003)). Live samples still showed signs of activity at 7° C.—in particular, fixed and live spinal cords had similar exchange rates even though fixation increases passive permeability. In contrast, Esmann & Skou measured activity of Na⁺/K⁺-ATPase isolated from ox brain to be near zero at 7° C. (Esmann, et al., Biochimica et Biophysica Acta (BBA)-Biomembranes, 944(3): 344-330 (1988)). This discrepancy warrants further research into the mechanisms of active water transport.

Active water exchange was found to be linked to ion transport (FIG. 5). One possible mechanism is that water cotransports with ions directly through Na⁺/K⁺-ATPase or other transport proteins. In this way, a number of transporters including KCC4 and NKCC1 have been shown to cotransport water against an osmotic gradient (Zeuthen, Journal of Membrane Biology, 234(2): 57-73 (2010)). Another similar mechanism is that ion transport creates a local osmotic gradient which drives water transport through nearby water channels (e.g., aquaporin), as shown for SGLT1 and EAAT1 (Zeuthen, Journal of Membrane Biology, 234(2): 57-73 (2010)). Both mechanisms transport up to hundreds of water molecules per ion or metabolite. Regardless of the actual mechanism, active water exchange was found to account for at least 70% of the total exchange rate, leaving only 30% as passive.

Most studies of water transport in biological systems consider it to be solely passive (Verkman, The Journal of Membrane Biology, 173(2): 73-87 (2000), Agre, et al., American Journal of Physiology Renal Physiology, 265(4): F463-F476 (1993)). Activation energies (Ea) of passive water permeability are independent of membrane SV ratio and are therefore often used for comparison (Verkrnan, The Journal of Membrane Biology, 173(2): 73-87 (2000)). These studies show La values trend with lipid bilayer composition and concentration of passive water channels such as aquaporins (Verkman, The Journal of Membrane Biology, 173(2): 73-87 (2000), Agre, et al., American Journal of Physiology-Renal Physiology, 265(4): F463-F476 (1993)). Lipid bilayers have Ea between 33 to 40 kJ/mol because permeability depends on membrane fluidity which varies strongly with temperature. Aquaporins increase permeability but reduce Ea towards the &a for self-diffusion of water (Ea=18−20 kJ/mol (Mills, The Journal of Physical Chemistry, 77(5): 685-688 (1973)). Exemplifying these extremes, Ea=40 kJ/mol was found for Baker's Yeast in which aquaporin channels were presumed to be closed (Åslund, et al., Journal of Magnetic Resonance, 200(2): 291-295 (2009)), and Ea values near 25 kJ/mol were consistently reported for red blood cells (Benga, Progress in Biophysics and Molecular Biology, 51(3): 193-245 (1988)) in which aquaporins are highly expressed (Heymann, et al., Journal of Structural Biology, 121(2): 191-206 (1998), Kuchel, et al., Biosystems, 82(2): 189-196 (2005)). Ea fixed was found to be equal to 21±8 kJ/mol, consistent with permeability by diffusion through pores opened during fixation (discussed below).

For passive water permeability, lower Ea values are associated with higher permeability. Active water transport alters this trend because enzymatic activity increases strongly with temperature. Isolated Na⁺/K⁺-ATPase (Esinann, et al., Biochimica et Biophysica Acta (BBA)-Biomembranes, 944(3): 344-330 (1988)) and water cotransport (Zeuthen, Journal of Membrane Biology, 234(2): 57-73 (2010)) both have La 100 kJ/mol at physiological temperatures (Esmann, et al., Biochimica et Biophysica Acta (BBA)-Biomembranes, 944(3): 344-350 (1988)). Ea live was found to be % Ea fixed and klive>kfixed indicating active water exchange exists. Values for Ea live=36±7 kJ/mol are between values for active water cotransport and passive water self-diffusion, consistent with exchange in live CNS tissue being both active and passive.

The Ea of ADCs in fixed and live spinal cords are less than values for pure aCSF and reported values for water (Mills, Journal of Physical Chemistry, 77(5): 685-688 (1973)). This was because the temperature dependence is dominated by hindered diffusion within the tissue. As the length scale of water diffusion increases with temperature, water experiences more interactions with membranes, causing the temperature dependence of diffusion to be less than that of pure water. The La of ADCy was found to be not significantly different between live and fixed spinal cords. This indicates that ADC is not directly sensitive to cellular activity, supporting evidence (Miller, et al., Proceedings of the National Academy of Sciences, 104(52): 20967-20972 (2007), Bai, et al., Proceedings of the National Academy of Sciences, 113(12): E1728-E 737 (2016)) which discredits the proposition that it directly detects neuronal activation (the premise of diffusion fMRI) (Le Bihan, et al., Proceedings of the National Academy of Sciences, 103(2): 8263-8268 (2006)).

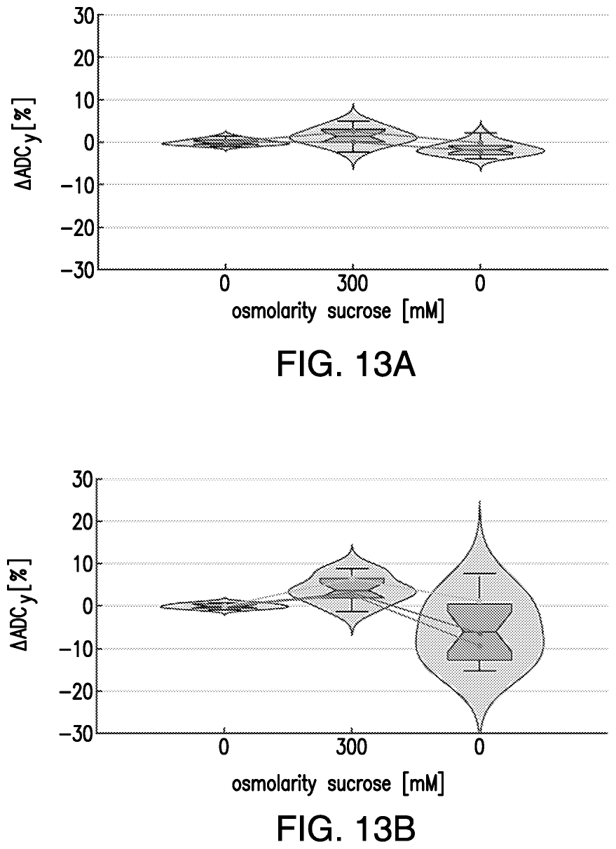

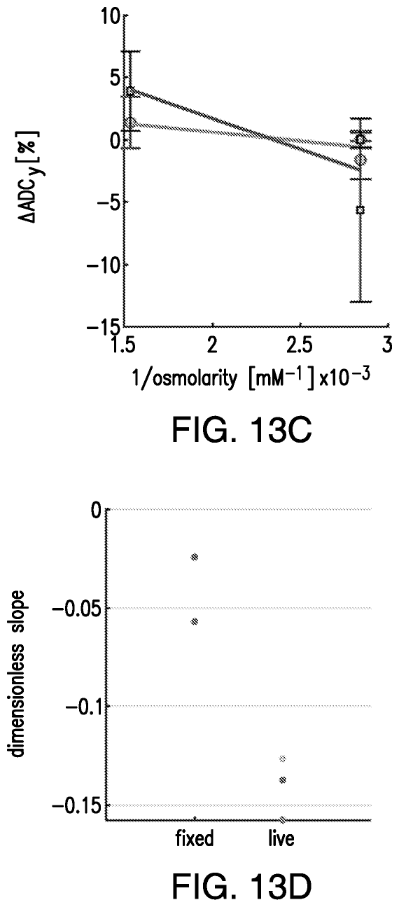

Fixed vs. live tissue was compared primarily to test whether NMR properties are linked to activity, the data also provides information about the effects of fixation. Shepherd et al. performed a similar study on fixed and perfused rat brain cortical slices (Shepherd, et al., Magnetic Resonance in Medicine: An Official Journal of the International Society for Magnetic Resonance in Medicine, 62(1): 26-34 (2009)). However, their methods involved stopping circulation during measurements, which could have affected tissue viability. The findings herein were compared with Shepherd et al., under the plausible assumption that their perfused tissue had limited viability and active exchange. It was found that fixation increased the passive exchange rate kp by 240% (FIG. 5), strikingly similar to 239% reported by Shepherd et al. (Shepherd, et al., Magnetic Resonance in Medicine: An Official Journal of the International Society for Magnetic Resonance in Medicine, 62(1): 26-34 (2009)). It was also found that fixation opened pores in the membrane large enough for sucrose molecules to penetrate (see FIGS. 12, 13, and 14). Together, these findings indicate that water permeability in fixed tissue is determined primarily by diffusion through pores opened during fixation. It was found that fixation decreased ADCy by 20%. Fixation shrinks the extracellular space from 20% to 5% (Shepherd, et al., Magnetic Resonance in Medicine: An Official Journal of the International Society for Magnetic Resonance in Medicine, 62(1): 26-34 (2009)), which reduces the fraction of more mobile extracellular water and increases the fraction of less mobile intracellular water. This re-partitioning of water during fixation reduces ADCy overall. Shepherd et al. reported that diffusivity increased upon fixation, however this discrepancy could be related to the longer diffusion encoding times used in their study (10 to 50 ms vs. 0.2 to 0.5 ms for the ADCy measurements), or to the perfused sample conditions. It was found that fixation caused a 15% increase in R_{1 DW} at 0.32 T. R_{1 DW} for fixed spinal cords was higher than for live spinal cords because formaldehyde crosslinks reduce the rotational mobility of proteins, which causes water to relax faster. While R₁ was field strength-dependent and a diffusion-weighted R₁ was reported, the results herein are consistent with Shepherd et al. who report that fixation increased R₁ by 21% at 17.6 T (Shepherd, et al., Magnetic Resonance in Medicine: An Official Journal of the International Society for Magnetic Resonance in Medicine, 62(1): 26-34 (2009)). These effects of fixation suggest that fixed tissue may not always be an appropriate sample when developing MRI methods intended for in vivo applications. Alternatively, viable CNS tissue has been shown to be a useful model for studying how pathologies affect MR parameters without in vivo confounds.

Diffusion-weighted imaging (DWI) is the gold-standard for identifying stroke because the ADC decreases significantly in affected areas minutes after stroke due to cytotoxic edema (Moseley, et al., Magnetic Resonance in Medicine, 14 (2): 330-346 (1990), Baird, et al., Journal of Cerebral Blood Flow & Metabolism, 18 (6): 583-609 (1998)). However, the diffusion coefficient alone cannot differentiate recoverable tissue from permanently damaged tissue (Pierpaoli, et al., Journal of Cerebral Blood Flow & Metabolism, 16 (5): 892-905 (1996), Beaulieu, et al., Annals of Neurology: Official Journal of the American Neurological Association and the Child Neurology Society, 46 (4): 568-578 (1999), Ueda, et al., American Journal of Neuroradiology, 20 (6): 983-989 (1999)). DWI shows similarly reduced diffusivities throughout an ischemic area, masking the heterogeneous effects on tissue metabolism (Nicoli, et al., Stroke, 34 (7): e82-e87 (2003), Guadagno, et al., Neurology, 67 (5): 824-829 (2006)). The ADC of a lesion begins to normalize during the first few days following a stroke, sometimes indicating tissue recovery (Baird, et al., Journal of Cerebral Blood Flow & Metabolism, 18 (6): 583-609 (1998)). However, in many cases that the tissue is actually damaged, the ADC will appear to recover or “pseudo-normalize” and will even increase to values higher than the surrounding normal tissue due to necrosis and loss of membrane integrity (Baird, et al., Journal of Cerebral Blood Flow & Metabolism, 18 (6): 583-609 (1998), Takahashi, et al., Magnetic Resonance in Medicine, 30 (4): 485-488 (1993), Pierpaoli, et al., Radiology, 189 (2): 439-448 (1993)). The time course of ADCy during OGD recapitulates in vivo findings—it decreases initially upon switching to OGD, and pseudo-normalizes and sometimes overshoots baseline values during recovery (FIGS. 4 and 14)—thus confirming that ADC is not specific to tissue damage.

In contrast, time courses of exchange rates during OGD (FIG. 4), stability tests (FIG. 17), and rundown show trends consistent with the exchange rate measuring viability. A potential mechanism is that the water exchange rate is linked to the cellular homeostatic state. The exchange rate is highly regulated, stable, and absolute because cellular processes compensate to maintain the homeostatic state. The exchange rate drops when homeostasis is lost and viability is compromised.

The methods of aspects of the present invention can translate low-field, high-gradient DEXSY to in vivo human brain MRI. Future directions could broadly involve development of static gradient methods or PFG methods. However, either direction may require compromising gradient strength, which with current technology is limited by the maximum bandwidth of radiofrequency (RF) probes (needed to excite a sizable volume of protons under a static gradient) or by the maximum gradient strength of PFG coils and amplifiers, as well as by biological constraints such as RF heating and peripheral nerve stimulation. Weaker gradients and longer diffusion encoding times may provide the same sensitivity to active exchange.

The exchange rate was established as an absolute, intrinsic measure of cellular function and viability, and these findings lay the groundwork for developing the exchange rate as a potential imaging biomarker more directly linked to cellular metabolic activity than current functional MRI (e.g., BOLD fMRI) and to permanent tissue damage than current structural MRI (e.g., diffusion MRI).

### Example 2

This example demonstrates that the methods of an aspect of the invention noninvasively measure the steady-state exchange of water into and out of live mitochondria.

Mitochondria were isolated by standard differential centrifugation procedures, as previously described (Pan, et al., Nature Cell Biology, 15(12): 1464 (2013), Liu, et al., Cell Reports, 16(6): 1561-1573 (2016)). Brain tissue was first minced in isolation buffer (225 mM mannitol, 75 mM sucrose, 5 mM MOPS, 0.5 mM EGTA, 2 mM taurine, pH adjusted to 7.25, with 0.2% BSA added freshly for each isolation) and then homogenized using a Glas-Col homogenizer for 5 strokes. Supernatants were collected after two centrifugation steps at 500 g, then mitochondria were pelleted by centrifugation at 11,000 g. The pellet was washed in isolation buffer and centrifuged again at 11,000 g, and the final mitochondrial pellet was resuspended in isolation buffer to achieve desired concentrations. Protein content was measured by BCA protein assay (ThermoScientific, PIERCE™ BCA Protein Assay Kit).

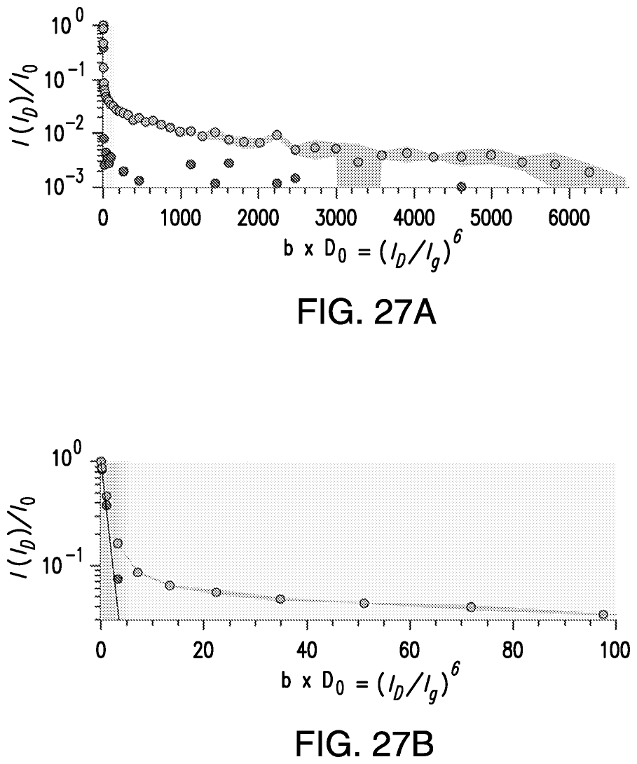

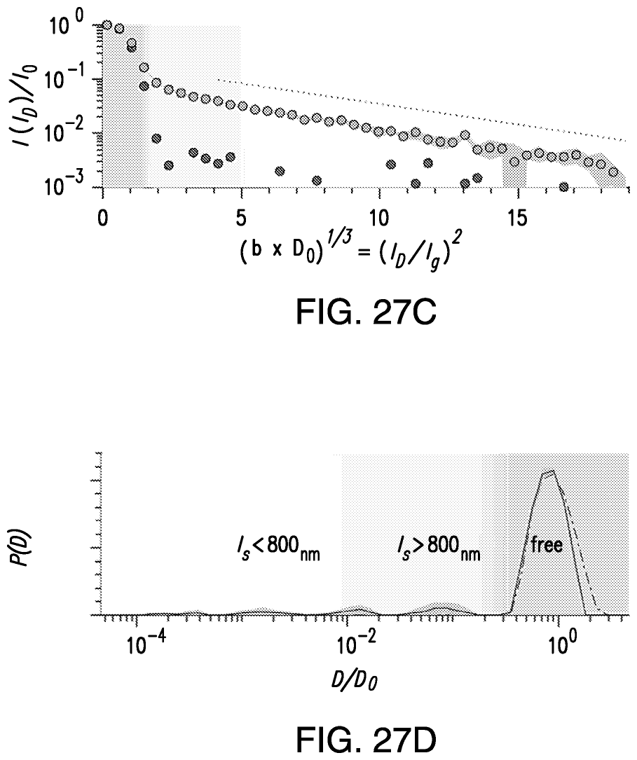

To prove that spin echo diffusion measurements with a large static gradient can provide nanoscale resolution, the measurements were performed on live mitochondria isolated from mouse brain. The diffusion data, shown in FIG. 27 shows signal attenuation and diffusion coefficient peaks consistent with the highly restricted components of the spinal cord tissue, confirming that these methods do achieve nanoscale resolution.

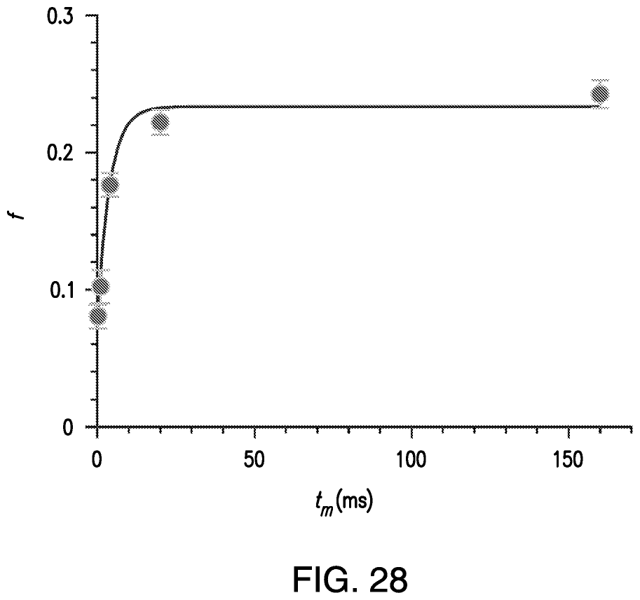

The DEXSY curvature approach was also tested on the live mitochondria (FIG. 28). Exchange fractions fit much better to a first order rate model than for the tissue, likely due to the mitochondria being a more homogeneous system. The measured exchange rate was used in FIG. 27 in a model for the signal decay for restricted water (Neuman, The Journal of Chemical Physics, 60(11): 4508-4511 (1974)), adapted to incorporate exchange (Carlton, et al., Journal of Magnetic Resonance, 143(1): 24-29 (2000)). The model uses a restriction length on 100 nm, due to the folded nature of the mitochondria, however it was roughly insensitive to any length less than 800 nm. The model fits the decay well, validating the AXR measurements.

Restricted diffusion and exchange of water in mitochondria was measured, proving sensitivity of an aspect of the invention to subcellular structures. Previous studies measured restricted diffusion in bacteria (Potter, et al., Journal of Magnetic Resonance, Series B, 113(1): 9-15 (1996), Carlton, et al., Journal of Magnetic Resonance, 143(1): 24-29 (2000)) which are of similar size to subcellular structures. No method has previously shown the capability to noninvasively measure the steady-state exchange of water into and out of live mitochondria. The implications are extensive, as a number of pathological changes are known to affect mitochondria. Mitochondria make up a substantial volume of the cell such that the methods disclosed herein can be sensitive to mitochondria within the tissue.

### Example 3

This example demonstrates that the exchange rate measurement of an aspect of the invention is a way to determine tissue viability and/or the loss of viability.

Membrane potential is like a battery being maintained at a steady charge by ATPase pumps while being used to drive various forms of cellular activity. The battery can drain faster than it is charged, leading to sustained, steady-state depolarization (ssD) of membrane potential. In the central nervous system (CNS), persistent reduction in Na+/K+-ATPase activity, such as through energy failure (hypoxia, hypoglycemia) e.g., during stroke, can cause spreading depolarization (SD), reducing the membrane potential from −70 mV to −10 mV in an “all-or-none” fashion. After the initial spreading depolarization has passed, steady state depolarization (ssD) remains until the tissue recovers. ssD can occur under physiological conditions as well, for instance ssD is a part of long-term potentiation and neural plasticity. Current measurements of ssD are either invasive (intracellular recording of membrane potential) or they only follow relative changes and require a baseline reading (electrocorticography or noninvasive electroencephalography and diffusion MRI). Although directly checking the “charge” of cells in tissue is difficult, perhaps the steady-state exchange of water, which is measurable with MR, can report the charge. Dynamic contrast enhanced (DCE) MR experiments have revealed steady-state transmembrane water transport linked to Na+/K+-ATPase pump activity in animal cells (Springer, Journal of Magnetic Resonance, 291: 110-126 (2018)).

Bai et al., reported steady-state transmembrane water exchange rates decreased by 50% after ouabain was used to block Na+/K+-ATPase pump activity in organotypic CNS (Bai, et al., Magnetic resonance in medicine, 79 (6): 3207-3217 (2018)). Real-time diffusion exchange spectroscopy (DEXSY) MR methods were used to study water homeostasis in ex vivo neonatal mouse spinal cords. Samples are kept viable during MR measurements, as confirmed by recordings of motoneuronal electrical activity after dorsal root stimulation at the end of the experiment.

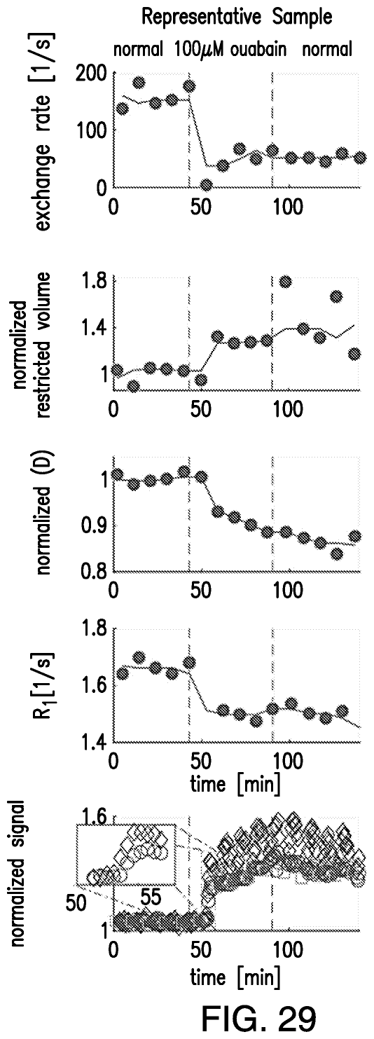

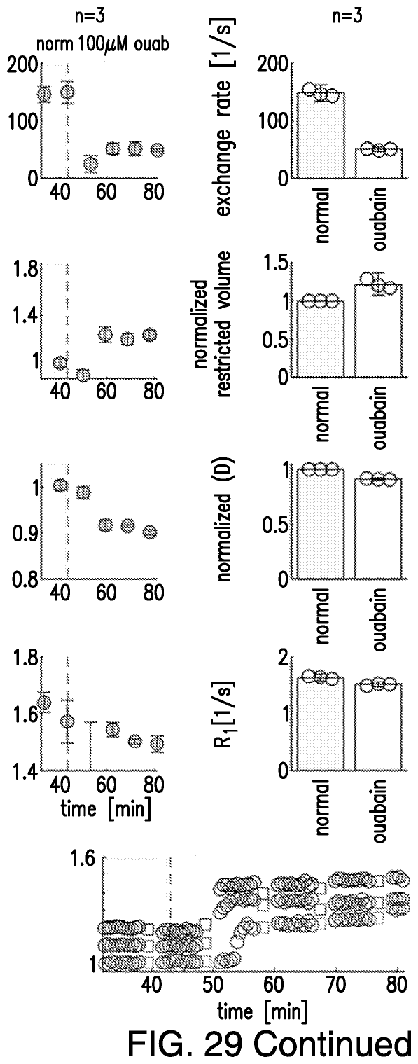

MR measurements were performed on viable “live” ex vivo neonatal mouse spinal cords at 13.79 MHz with a low-field single-sided magnet (PM-10 NMR MOUSE, Magritek) (Eidmann, et al., Journal of Magnetic Resonance, Series A, 122(1): 104-109 (1996)) and custom-made RF probe and solenoid coil (see FIG. 29). Diffusion was encoded on sub-micron length scales and sub-millisecond timescales with spin echoes in the presence of a g=15.3 T/m static gradient (SG) (Williamson, et al., Proceedings of the 28th annual International Society of Magnetic Resonance in Medicine (ISMRM) (2020)). SG diffusion measurements (Williamson, et al., Elife, 8: p. e51101 (2019)) and SG diffusion exchange spectroscopy (DEXY)-based exchange rate and spin-lattice relaxation rate measurements (as in Williamson, et al., Journal of Magnetic Resonance, 317: 106782 (2020)), with b₁+b₂=4.5 ms/μm²) were repeatedly acquired (11 minutes per set) to observe real-time changes. During measurements, samples were maintained in a constant circulation of artificial cerebrospinal fluid (ACF) and gas and at 25° C.

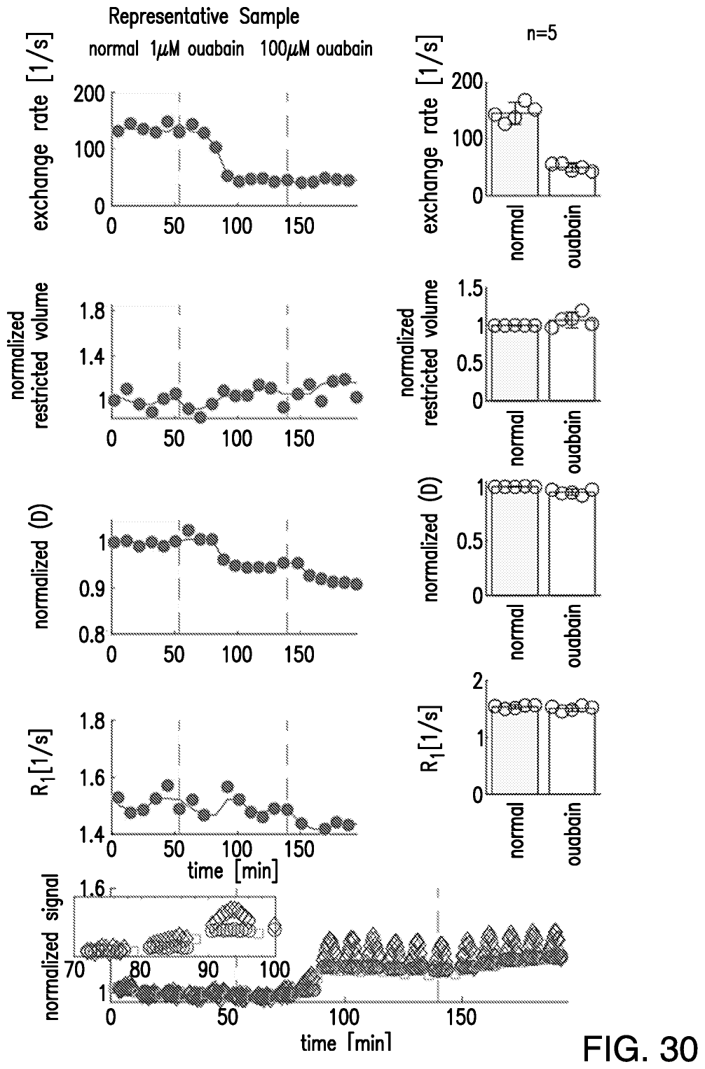

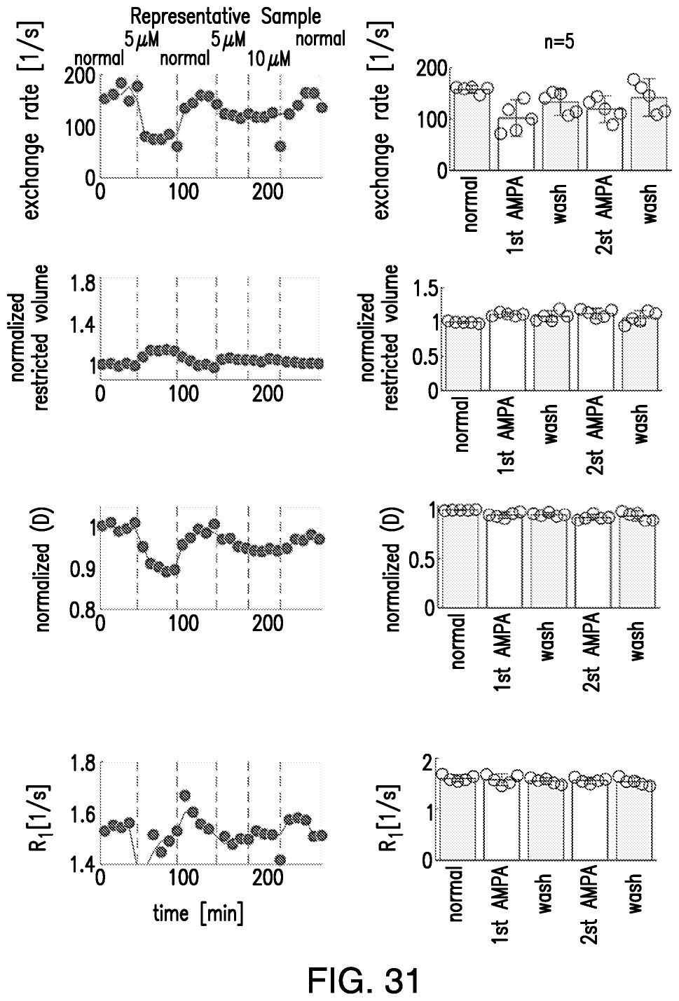

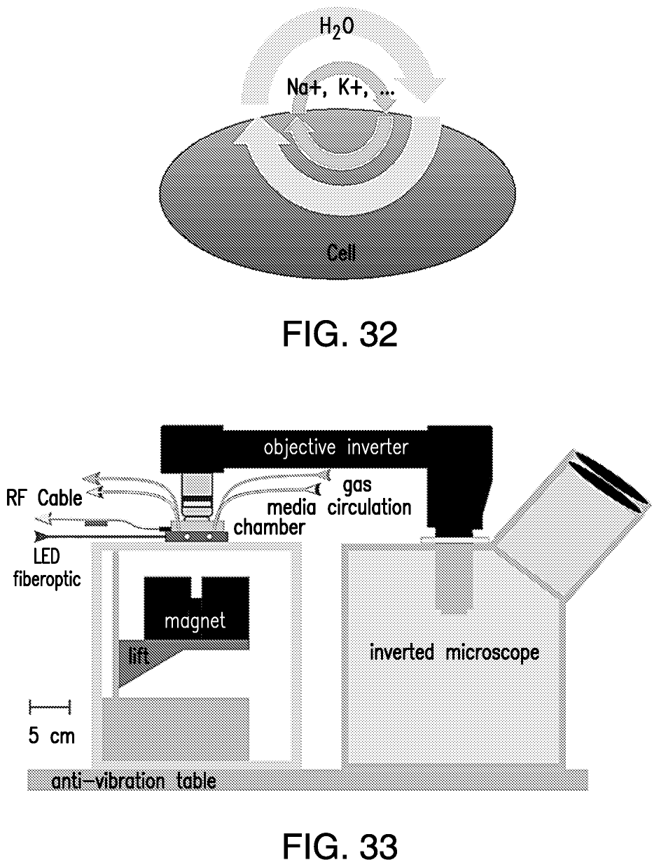

The data suggests that the exchange rate is linked to ssD. Completely blocking Na⁺/K⁺-ATPase pump activity with 100 μM ouabain caused exchange rate to swiftly decrease to 50 s⁻¹ (FIG. 29). Partially blocking Na⁺/K⁺-ATPase pump activity with doses as low as 1 μM also caused exchange rate to decrease to 50 s⁻¹, but after a longer delay (FIG. 30). Ouabain had an “all-or-none”, dose-independent effect on exchange rate. In comparison, Balestrino, et al. (1999), reported that blocking Na⁺/K⁺ pump activity with ouabain induced a sustained SD-like effect consistent with ssD in hippocampal slices (Balestrino, et al., Brain Research, 838(1-2): 37-44 (1999)). The SD-like effect showed an “all-or-none” response to ouabain—not a dose response. In FIG. 21 it shows that adding 100 mM sucrose (osmolyte) in normal conditions had a small effect on exchange rate, but in ouabain-treated states led to a drastic recovery from 50 back to 150 s⁻¹, consistent with the literature finding that ouabain-induced SD can be abolished by addition of an osmolyte (Balestrino, et al., Brain Research, 838(1-2): 37-44 (1999)). FIG. 31 shows that AMPA (α-amino-3-hydroxy-5-methyl-4-isoxazolepropionic acid) causes exchange rate to decrease, the effect is reversible when AMPA is washed out. In comparison, Falgairolle and O'Donovan (2015) showed that AMPA causes a sustained depolarization in the neonatal mouse spinal cord which is reversible upon washout (Falgairolle & O'Donovan, PloS one, 10(6): e0131430 (2015)). FIG. 31 also shows that a second dose of AMPA had less of an effect, consistent with recycling of receptors conditioning the cells to AMPA (Falgairolle & O'Donovan, PloS one, 10(6): e0131430 (2015)). In summary, it has been found that ouabain and AMPA substantially reduce the exchange rate and that osmolyte addition recovers the exchange rate from the ouabain-reduced state back to a value consistent with the normal state. The findings in the literature showing that ssD is induced by ouabain and AMPA are also recapitulated and that ouabain-induced ssD can be abolished by addition of an osmolyte. The consistency between the results herein and the literature supports the view that the water exchange rate is coupled to steady state depolarization (ssD).

Cellular activity may be non-invasively and absolutely measurable through a coupled process—water exchange—via DEXSY MR. It has been shown that the water exchange rate maintains a stable and repeatable value across samples under normal conditions, meaning it is an intrinsic or absolute measure of water exchange in these cells. Exchange rates decrease and recover predictably following known perturbations from steady state depolarization (ssD). DEXSY is sensitive and specific to endogenous water exchange and may find utility as a measurement of biological activity for both basic cell biology and medicine.

### Example 4

This example demonstrates that the exchange rate measurement of an aspect of the invention is a way to determine the effectiveness of clinically-relevant treatment protocols and neuroprotectants.

Surprisingly, doctors do not have a clear way to identify whether a patient's brain has been permanently damaged by stroke or if the affected tissue will recover over time. Apparent diffusion coefficient mapping with Diffusion MRI is the gold standard for stroke lesion delineation, however it is primarily sensitive to structural changes, in particular to cellular swelling, and not tissue viability. Diagnostic techniques to grade tissue viability would inform treatment plans and ultimately improve patient outcomes. While cells have mechanisms of maintaining homeostasis during brief periods of hypoxia and ischemia, eventually they can no longer hold on. This critical point defines when cells have been damaged permanently.

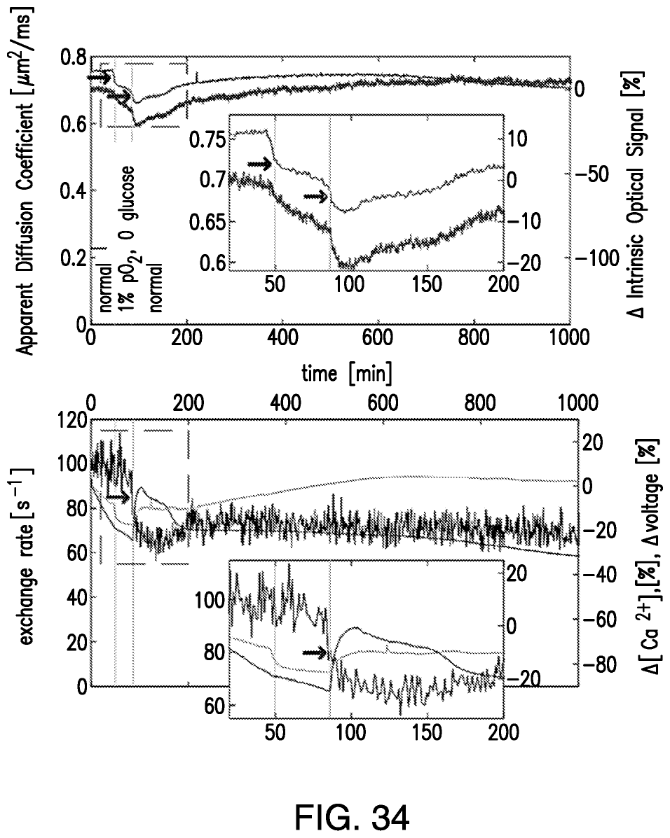

Many studies looking at different collective aspects of this energetic failure show that the critical point is when the cells lose homeostasis. This can be confirmed directly, by measuring many aspects of homeostasis at once (FIG. 34). When the ex vivo neonatal mouse spinal cord is perturbed from normal media bubbled with 95% O₂ to media made without glucose and bubbled with 1% O₂, both the intrinsic optical signal (IOS) and the apparent diffusion coefficient (ADC) show that cells begin to swell. At the same time, the exchange rate and [Ca²⁺]ᵢ signals show that homeostasis is maintained. It was not until roughly 40 minutes after the perturbation that the exchange rate drops, intracellular calcium goes up and cells depolarize, together with the ADC and IOS dropping further, indicating a loss of homeostasis. When normal media is washed back into the tissue compartment, the exchange rate recovers only slightly because the cells have been damaged permanently. Over time the ADC and IOS do approach baseline. Literature shows that this “pseudo-normalization” of the ADC is due to cellular necrosis and loss of membrane integrity rather than recovery, often confounding radiological evaluation of stroke and stroke recovery. These results provide a detailed look into cellular function and structure changes during stroke.

Ketamine and osmolytes (e.g., sucrose or mannitol) have been effective as neuroprotective treatments in ex vivo and animal models (Balestrino, et al., Brain Research, 838(1-2): 37-44 (1999), Hudetz & Pagel, Journal of cardiothoracic and vascular anesthesia, 24(1): 131-142 (2010)) but their mechanisms of action are not completely understood and their use clinically has shown mixed results (Bereczki, et al., Cochrane Database of Systematic Reviews, (3): 2007)). While ketamine has a known neuroprotective effect by blocking NMDA receptors, this may not be the entire story. Interestingly, both osmolytes and ketamine increase the fraction of extracellular water (Xie, et al., Science, 342(6156): 373-377 (2013)), which brings the system towards a more neuroprotective state. Restoring water homeostasis may be a critical aspect of osmolytes' and ketamine's neuroprotective mechanisms.

Accordingly, the capability to monitor tissue viability and loss of viability in real time using methods of an aspect of the invention provides a powerful means to test the effectiveness of neuroprotectants. For example, in real-time, it can be seen whether therapeutics can help maintain or perhaps recover viability during these perturbations, as well as at what timepoints they need to be administered.

### Example 5

This example demonstrates that multi exponential analysis of diffusion exchange times reveals a. distinct exchange process associated with metabolic activity. Specifically, a bimodal distribution of exchange times is found in live tissue using multi exponential analysis of DEXSY data. The faster peak is reduced by a sodium-potassium pump inhibitor, suggesting that fast exchange is an active process.

The exchange of water between biological microenvironments, namely between the intra- and extracellular space, is generally considered to be a passive process mediated by membrane permeability. Recent work, however, suggests that exchange (as measured by diffusion MR) is linked to active, i.e., ATP-driven metabolic processes. Specifically, the exchange rate, k, has been linked to the activity of the sodium-potassium pump. Quantifying k may provide functional information at the cellular level, representing, potentially, a direct, non-BOLD-based form of functional MR.

Whether exchange is adequately described by a single parameter was explored. Indeed, the existence of active exchange would imply, at the least, two distinct exchange processes—the passive permeability of the cell membrane, and exchange coupled to active processes like ion transport—for which there is no a priori reason to assume equal rates. Moreover, k should scale with the local surface-to-volume ratio.

The probability distribution functions of the exchange time were measured, P(τₖ)=P(1/k) by applying multi exponential analysis using numerical inverse Laplace transforms (ILTs) to data in which the effect of exchange has been isolated. Using a low-field, static gradient system, P(τₖ) data were acquired from ex vivo neonatal mouse spinal cords in three conditions: fixed, live, and live whilst treated with ouabain, a sodium-potassium pump inhibitor.

It has been demonstrated that the diffusion exchange spectroscopy (DEXSY) sequence, in which two parallel diffusion encodings with b-values b₁ and b₂ are separated by a mixing time, tₘ, can be leveraged to measure exchange whilst heavily sub-sampling the (b₁, b₂) domain. First, the signal variation is measured along an axis of constant total diffusion weighting bₛ=b₁+b₂, removing the effects of non-exchanging, Gaussian diffusion. Next, taking a ratio of signals at each tₘ normalizes T₁ relaxation. Finally, by varying tₘ, the effect of exchange (during tₘ) is isolated.

The apparent exchanging signal fraction f_{exch}(tₘ) is proportional to a log-ratio of the signal I(b₁, b₂, tₘ) at the midpoint

$${I}_{m i d} ( {t}_{m} ) = I ( \frac{{b}_{s}}{2} , \frac{{b}_{s}}{2} , {t}_{m} )$$

and endpoint I_{end}(tₘ)=I(bₛ, 0, tₘ) of the b_{d}=b₁−b₂ axis, normalizing to tₘ=0:

$$\begin{matrix}{f}_{e x c h} ( {t}_{m} ) = {C}_{1} [ ln ( \frac{{I}_{m i d} ( {t}_{m} )}{{I}_{e n d} ( {t}_{m} )} ) - {C}_{0} ] , & {C}_{0} = ln ( \frac{{I}_{m i d} ( 0 )}{{I}_{e n d} ( 0 )} ) ,\end{matrix} \qquad ( 1 )$$

with proportionality constant C₁. Note that C₀ encompasses restriction, exchange during encodings, and other effects invariant with tₘ. The exchange process is modelled as

$${f}_{e x c h} ( {t}_{m} ) = {f}_{∞} [ 1 - \int exp ( - {t}_{m} k ) P ( k ) dk ] , \qquad ( 2 )$$

where

$${f}_{∞} = {lim}_{{t}_{{m}^{\to ∞}}} {f}_{e x c h} ( {t}_{m} )$$

is the steady-state exchange fraction, corresponding to complete volume turnover between compartments. Rearranging and substituting Eq. (1), C₁ cancels and

$$1 - \frac{{f}_{e x c h} ( {t}_{m} )}{{f}_{∞}} = 1 - [ \frac{ln ( \frac{{I}_{m i d} ( {t}_{m} )}{{I}_{e n d} ( {t}_{m} )} ) - {C}_{0}}{{lim}_{{t}_{{m}^{\to ∞}}} ln ( \frac{{I}_{m i d} ( {t}_{m} )}{{I}_{e n d} ( {t}_{m} )} ) - {C}_{0}} ] = \int exp ( - \frac{{t}_{m}}{{τ}_{k}} ) P ( {τ}_{k} ) dk , \qquad ( 3 )$$

which is amenable to using an ILT to obtain P(τₖ).

The static gradient DEXSY (SG-DEXSY) pulse sequence was implemented on a PM-10 NMR MOUSE single-sided magnet at ω₀=13.79 MHz, B₀=0.3239 T, g=15.3 T/m with a home-built solenoid RF coil and test chamber. 90°/180° RF pulse lengths=2/2 μs, pulse powers=−22/−16 dB, TR=2 s, 8000 echo CPMG train with TE=25 μs, 8 points per echo, and 0.5 μs dwell time.

Live (i.e., viable) and fixed ex vivo neonatal (postnatal day 1-4) mouse spinal cords were studied. Spinal cords were bathed in artificial cerebrospinal fluid at 95% O₂/5% CO₂ and 25° C. For the ouabain treatment condition, ouabain was added at a saturating concentration of 100 μM.

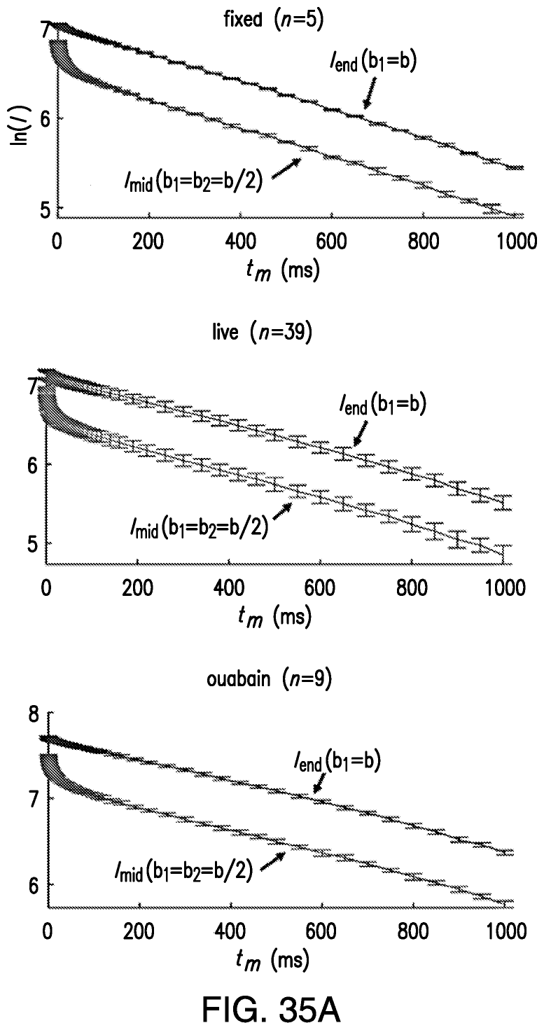

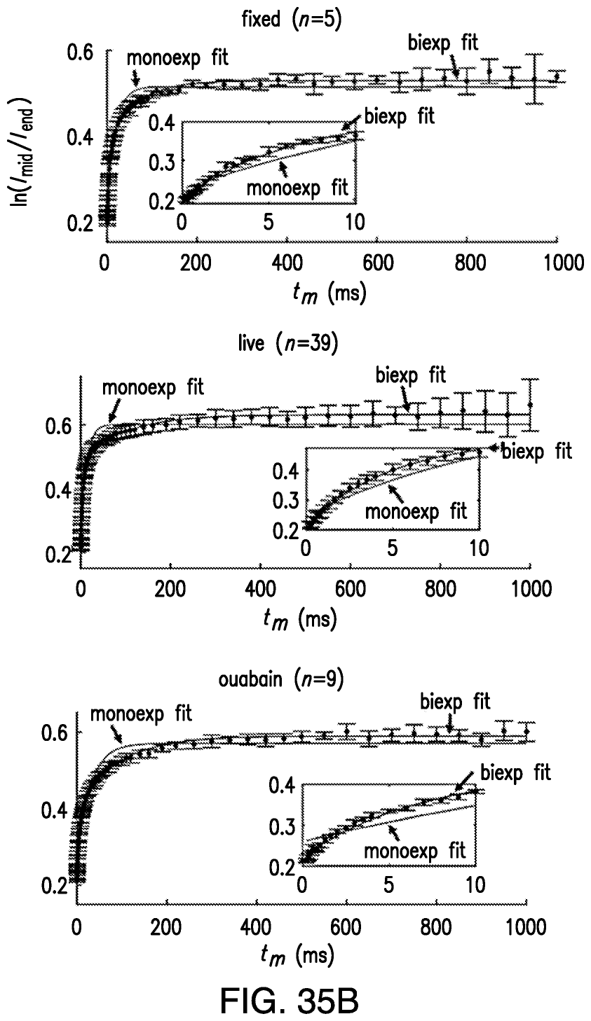

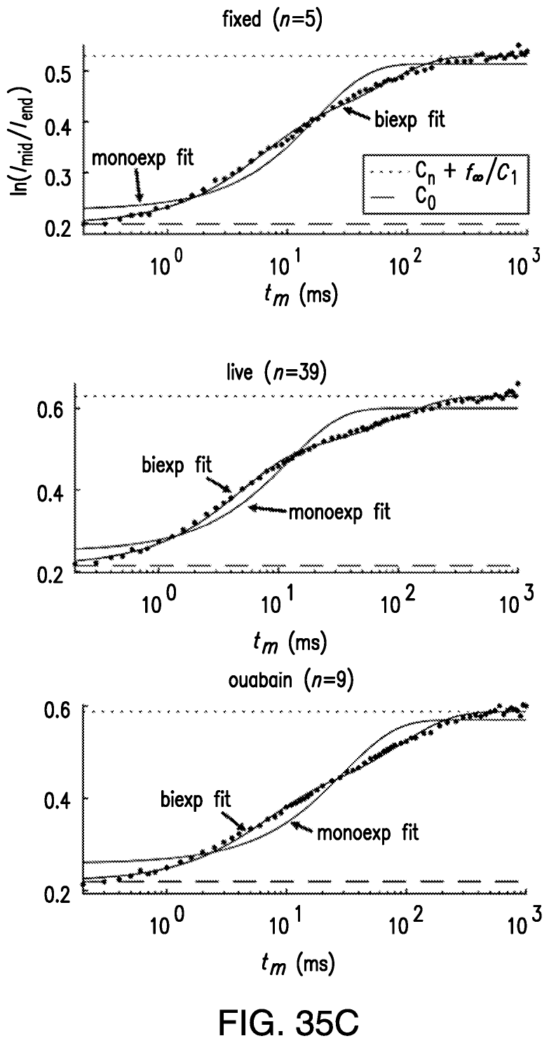

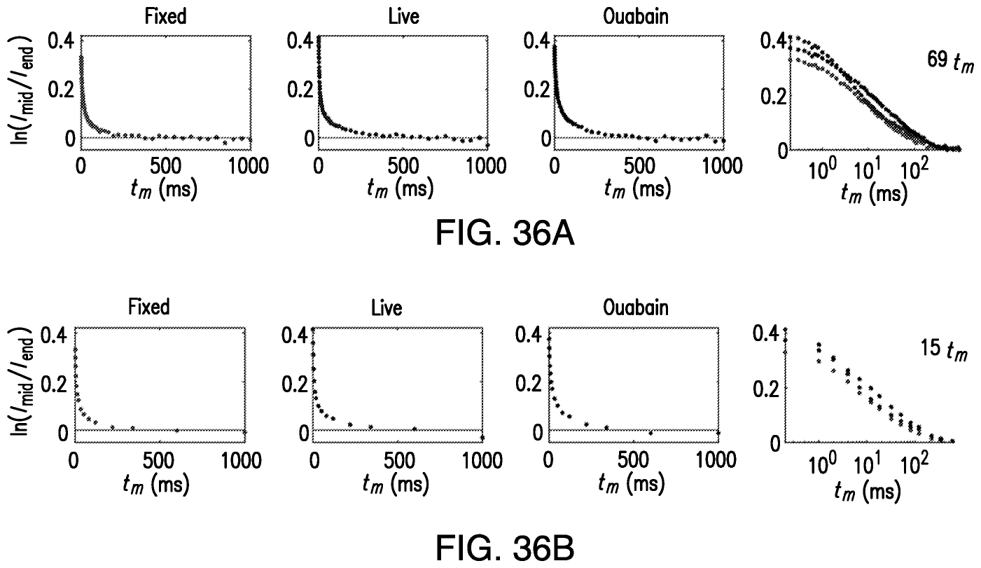

Data were acquired at bₛ=4.5 ms/μm² over 69 values of tₘ=0.2-1000 ms. A biexponential fit to the log-ratio of signals was first performed to yield robust estimates of the intercept C₀ and limit f_{∞}/C₁ (FIGS. 35A-35D). The data were then renormalized following Eq. (3) (FIGS. 36A-36B) before performing an ILT using the Butler-Reeds-Dawson algorithm with 200 points spaced log-linearly from τₖ=1×10⁻³ to 1×10⁴ ms. Data were also sub-sampled to 15 values of tₘ to assess the stability of the inversion with minimal data, inverting with 50 points from τₖ=1×10⁻² to 1×10³ ms.

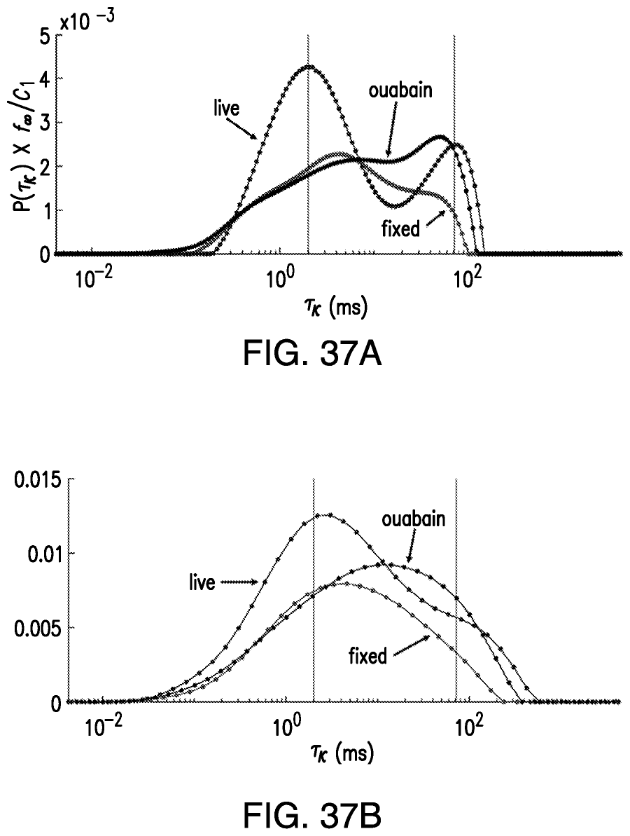

Inverted P(τₖ) distributions from fully sampled (FIG. 37A) and sub-sampled (FIG. 37B) data are presented for the live, fixed, and live with ouabain conditions. The distributions are scaled by f_{∞}/C₁ to facilitate comparison in absolute terms. The distributions are broad. Live tissue exhibits a bimodal distribution with peaks centered at 2 ms and 72 ms. In the ouabain case, the faster peak is reduced. Fixed tissue is approximately unimodal. The sub-sampled case shows similar trends, albeit less resolved. Importantly, the distinct, short τₖ peak in live tissue remains.

Our results support that active and passive exchange have well-separated exchange times. Of the two peaks in live tissue, only the faster peak is reduced with ouabain, suggesting that fast exchange, specifically, is an active process. Furthermore, it has been found that P(τₖ) is broadly distributed, consistent with a dependence on local microstructure. Pairing P(τₖ) estimation with other modalities, namely diffusion MR, may provide additional information about inter-compartment exchange.

The methods of an aspect of the present invention are uniquely suited to such analysis. Other time-efficient methods of measuring exchange (e.g., FEXSY, the Karger model, etc.), generally rely on multi-parametric fitting of the signal as exchange is not isolated. This greatly complicates the application of ILTs to study exchange. In contrast, the methods of an aspect of the invention reduce to a form in which the signal is dependent only on exchange. Remaining parameters are experimentally observable (C₀, f_{∞}/C₁), leaving a simple kernel.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and “at least one” and similar referents in the context of describing the invention (especially in the context of the following claims) are to be construed to cover both the singular and the plural, unless otherwise indicated herein or clearly contradicted by context. The use of the term “at least one” followed by a list of one or more items (for example, “at least one of A and B”) is to be construed to mean one item selected from the listed items (A or B) or any combination of two or more of the listed items (A and B), unless otherwise indicated herein or clearly contradicted by context. The terms “comprising,” “having,” “including,” and “containing” are to be construed as open-ended terms (i.e., meaning “including, but not limited to,”) unless otherwise noted. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred aspects of this invention are described herein, including the best mode known to the inventors for carrying out the invention. Variations of those preferred aspects may become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

1. A method to determine a homeostatic steady-state of a biological entity.

2. A method to determine a homeostatic steady-state of a biological entity, the method comprising a magnetic resonance (MR) system, the MR system comprising:
a. a means to create a static or pulsed magnetic field gradient;
b. a means to create a constant magnetic field;
c. a means to hold a biological entity within the constant magnetic field and the static or pulsed magnetic field gradient;
d. a radiofrequency transmitter;
e. a radiofrequency receiver that measures radiofrequency electromagnetic fields;
f. a radiofrequency transmit amplifier;
g. a MR radiofrequency pulse sequence generator that sends signals to the radiofrequency transmit amplifier to acquire Diffusion Exchange Spectroscopy (DEXSY) data;
h. a recording device to sample and store a MR magnetization signal detected by the radiofrequency receiver; and
i. a mathematical modeling framework to transform the recorded magnetization signal DEXSY data,
wherein interpretation of the DEXSY data provides a homeostatic steady-state of a biological entity.

3. The method of claim 2, the method further comprising placing a biological entity in the means to hold the biological entity.

4. The method of claim 2, wherein the MR system is a Nuclear Magnetic Resonance (NMR) system or a Magnetic Resonance Imaging (MRI) system.

5. The method of claim 3, wherein the biological entity is a cell.

6. The method of claim 3, wherein the biological entity is an organelle.

7. The method of claim 3, wherein the biological entity is living.

8. A method to quantify an exchange rate between at least two compartments in a biological system.

9. The method of claim 8, further comprising a MR system comprising:
a. a means to create a static or pulsed magnetic field gradient;
b. a means to create a constant magnetic field;
c. a means to hold a biological entity within the constant magnetic field and the static or pulsed magnetic field gradient;
d. a radiofrequency transmitter;
e. a radiofrequency receiver that measures radiofrequency electromagnetic fields;
f. a radiofrequency transmit amplifier;
g. a MR radiofrequency pulse sequence generator that sends signals to the radiofrequency transmit amplifier to acquire Diffusion Exchange Spectroscopy (DEXSY) data;
h. a recording device to sample and store a MR magnetization signal detected by the radiofrequency receiver; and
i. a mathematical modeling framework to transform the recorded magnetization signal DEXSY data.

10. The method of claim 8, wherein the exchange rate is used to determine neuroprotectant efficacy.

11. The method of claim 8, wherein the exchange rate is used to determine a homeostatic steady-state and a homeostatic non-steady state of the biological entity.

12. The method of claim 11, wherein the homeostatic non-steady state is a pathological state.

13. A Nuclear Magnetic Resonance (NMR) method to characterize physiological water transport.

14. The method of claim 2, wherein the method does not require exogenous contrast agents.

15. A method for non-invasively measuring transmembrane exchange rates of endogenous water in a biological system under steady-state or non-steady-state conditions in near-real time.

16. The method of claim 15, wherein the method detects an exchange rate which is an intrinsic metric or an absolute value that is used as a quantitative imaging biomarker to measure the physiological or pathological state of the biological system.

17. The method of claim 15, the method utilizing a MRI device or a NMR device to measure the physiological or pathological state in vivo.
